(19) United States
(12) Patent Application Publication
(10) Pub. No.: US 2026/0090057 A1
(43) Pub. Date: Mar. 26, 2026

(54) SEMICONDUCTOR DEVICE AND METHOD FOR MANUFACTURING SAME

(71) Applicant: ROHM CO., LTD., Kyoto-shi (JP)

(72) Inventor: Akihiro HIKASA, Kyoto-shi (JP)

(73) Assignee: ROHM CO., LTD., Kyoto-shi (JP)

(21) Appl. No.: 19/401,433

(22) Filed: Nov. 26, 2025

Related U.S. Application Data
(63) Continuation of application No. PCT/JP2024/019603, filed on May 28, 2024.

(30) Foreign Application Priority Data
May 30, 2023 (JP) 2023-089176

(51) Int. Cl. H10D 64/23; H10D 30/01; H10D 30/66; H10D 62/10; H10D 62/832; H10D 64/62

(52) U.S. Cl. CPC H10D 64/2527; H10D 30/0295; H10D 30/665; H10D 62/107; H10D 62/8325; H10D 64/62

(57) ABSTRACT

A semiconductor device includes a chip having a main surface; gate structures of a planar type each including a gate insulating film covering the main surface, a gate electrode arranged on the gate insulating film, and a side wall insulating film covering a side wall of the gate electrode, the gate structures being arranged at intervals on the main surface; an opening that is demarcated by the side wall insulating films in a region between the gate structures; and a main electrode that is mechanically connected to the side wall insulating films in the opening and is electrically connected to the main surface.

### CROSS-REFERENCE TO RELATED APPLICATIONS

The present application is a bypass continuation of International Patent Application No. PCT/JP2024/019603 filed on May 28, 2024, which claims priority to Japanese Patent Application No. 2023-089176 filed on May 30, 2023 in the Japan Patent Office, and the entire contents of these applications are hereby incorporated herein by reference.

### BACKGROUND

### 1. Field of the Disclosure

The present disclosure relates to a semiconductor device and a method for manufacturing a semiconductor device.

### 2. Description of the Related Art

US 2022/0093491A1 discloses a semiconductor device including a plurality of planar gate structures.

### BRIEF DESCRIPTION OF DRAWINGS

FIG. 1 is a plan view showing a semiconductor device according to a first embodiment.

FIG. 2 is a cross-sectional view taken along line II-II in FIG. 1.

FIG. 3 is a plan view showing a layout example of a first main surface.

FIG. 4 is an enlarged plan view showing a main portion of the first main surface.

FIG. 5 is an enlarged plan view showing an additional main portion of the first main surface.

FIG. 6 is a cross-sectional view taken along line VI-VI in FIG. 5.

FIG. 7 is an enlarged cross-sectional view showing a main portion of FIG. 6 together with a gate structure according to a first example.

FIG. 8 is a cross-sectional view taken along line VIII-VIII in FIG. 5.

FIG. 9 is an enlarged cross-sectional view showing a main portion of FIG. 8 together with a wiring structure according to the first example.

FIG. 10A is an enlarged cross-sectional view showing a gate structure according to a second example.

FIG. 10B is an enlarged cross-sectional view showing a gate structure according to a third example.

FIG. 10C is an enlarged cross-sectional view showing a gate structure according to a fourth example.

FIG. 10D is an enlarged cross-sectional view showing a gate structure according to a fifth example.

FIG. 10E is an enlarged cross-sectional view showing a gate structure according to a sixth example.

FIG. 10F is an enlarged cross-sectional view showing a gate structure according to a seventh example.

FIG. 10G is an enlarged cross-sectional view showing a gate structure according to an eighth example.

FIG. 10H is an enlarged cross-sectional view showing a gate structure according to a ninth example.

FIG. 10I is an enlarged cross-sectional view showing a gate structure according to a tenth example.

FIG. 10J is an enlarged cross-sectional view showing a gate structure according to an eleventh example.

FIG. 11A is an enlarged cross-sectional view showing a wiring structure according to a second example.

FIG. 11B is an enlarged cross-sectional view showing a wiring structure according to a third example.

FIG. 11C is an enlarged cross-sectional view showing a wiring structure according to a fourth example.

FIG. 11D is an enlarged cross-sectional view showing a wiring structure according to a fifth example.

FIG. 11E is an enlarged cross-sectional view showing a wiring structure according to a sixth example.

FIG. 11F is an enlarged cross-sectional view showing a wiring structure according to a seventh example.

FIG. 11G is an enlarged cross-sectional view showing a wiring structure according to an eighth example.

FIG. 11H is an enlarged cross-sectional view showing a wiring structure according to a ninth example.

FIG. 11I is an enlarged cross-sectional view showing a wiring structure according to a tenth example.

FIG. 12 is a schematic view showing a wafer used in manufacture of a semiconductor device.

FIGS. 13A to 13R are cross-sectional views showing a method for manufacturing a semiconductor device.

FIG. 14 is an enlarged cross-sectional view showing a gate structure of a semiconductor device according to a second embodiment.

FIG. 15 is an enlarged cross-sectional view showing a wiring structure of the semiconductor device shown in FIG. 14.

FIGS. 16A to 16C are cross-sectional views showing a method for manufacturing the semiconductor device shown in FIG. 14.

FIG. 17 is a cross-sectional view showing a semiconductor device according to a third embodiment.

FIG. 18 is a cross-sectional view showing a first modification example of a source main electrode.

FIG. 19 is a cross-sectional view showing a second modification example of the source main electrode.

### DETAILED DESCRIPTION OF THE PREFERRED EMBODIMENTS

Hereinafter, specific embodiments will be described in detail with reference to the accompanying drawings. All of the accompanying drawings are schematic views and thus are not precisely drawn and are not always matched in relative positional relationships, reduced scales, ratios, angles, etc. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially” is used in this Description, the wording includes a numerical value (shape) equal to a numerical value (shape) of a comparison target and also includes numerical errors (shape errors) in a range of 10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead. The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

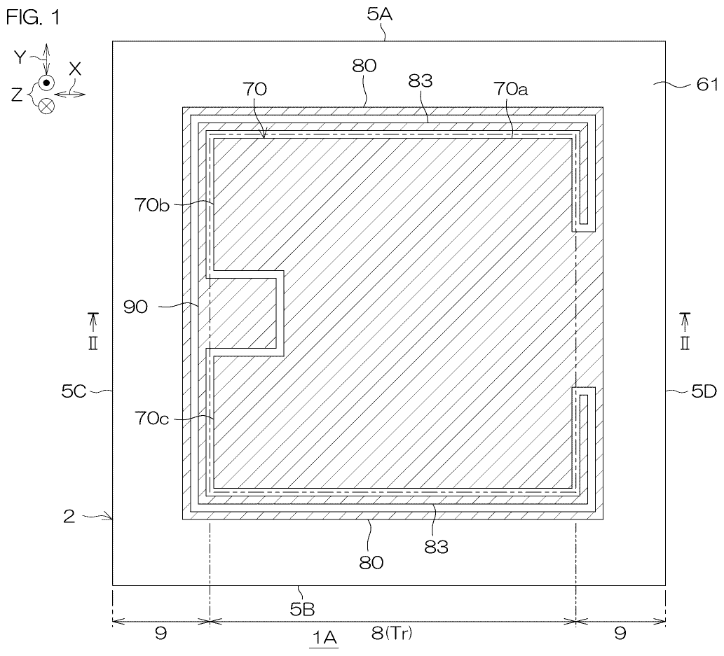

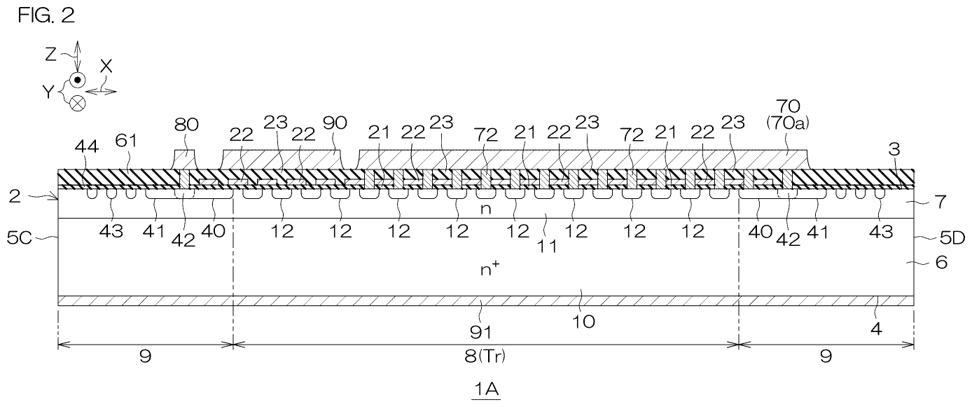

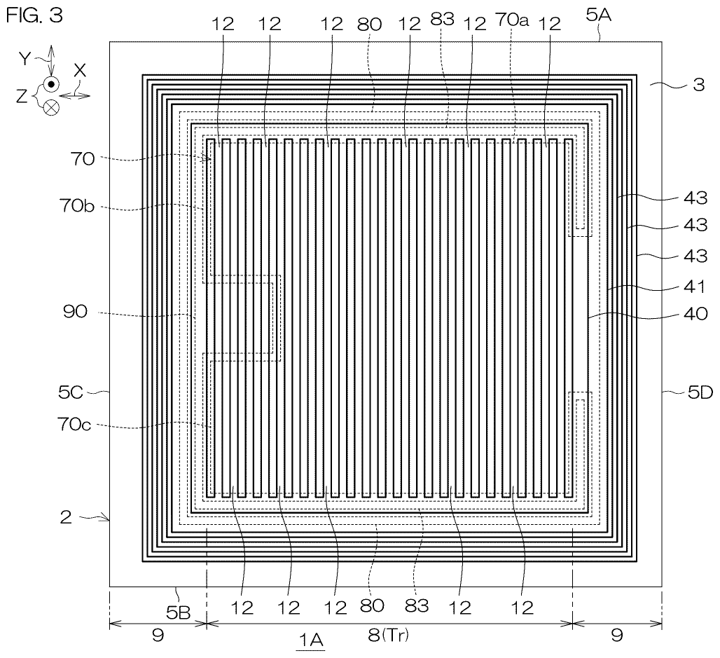

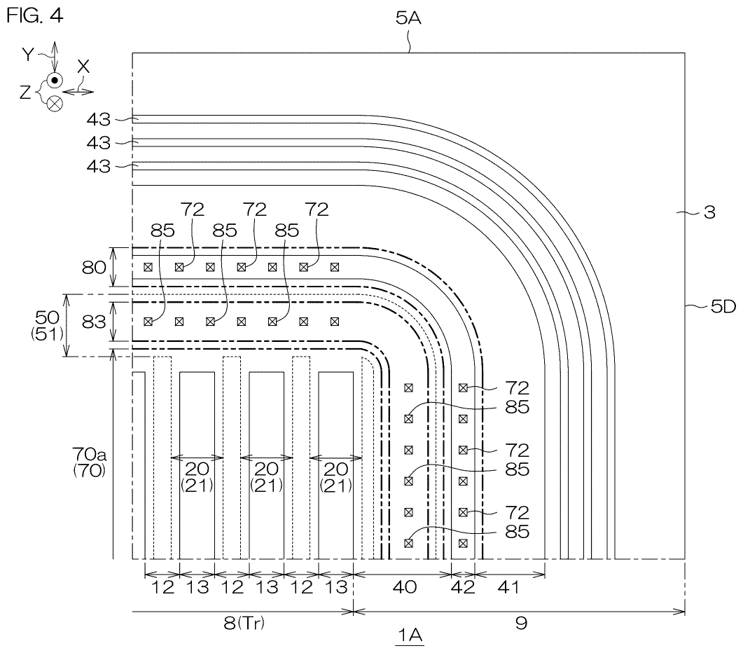

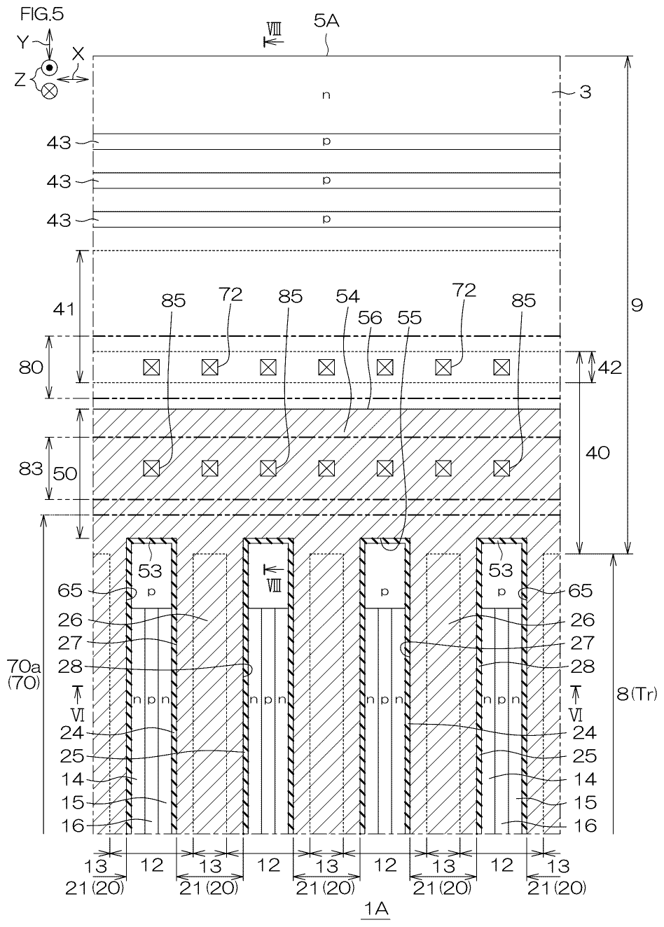

FIG. 1 is a plan view showing a semiconductor device 1A according to a first embodiment. FIG. 2 is a cross-sectional view taken along line II-II in FIG. 1. FIG. 3 is a plan view showing a layout example of a first main surface 3. FIG. 4 is an enlarged plan view showing a main portion of the first main surface 3. FIG. 5 is an enlarged plan view showing an additional main portion of the first main surface 3.

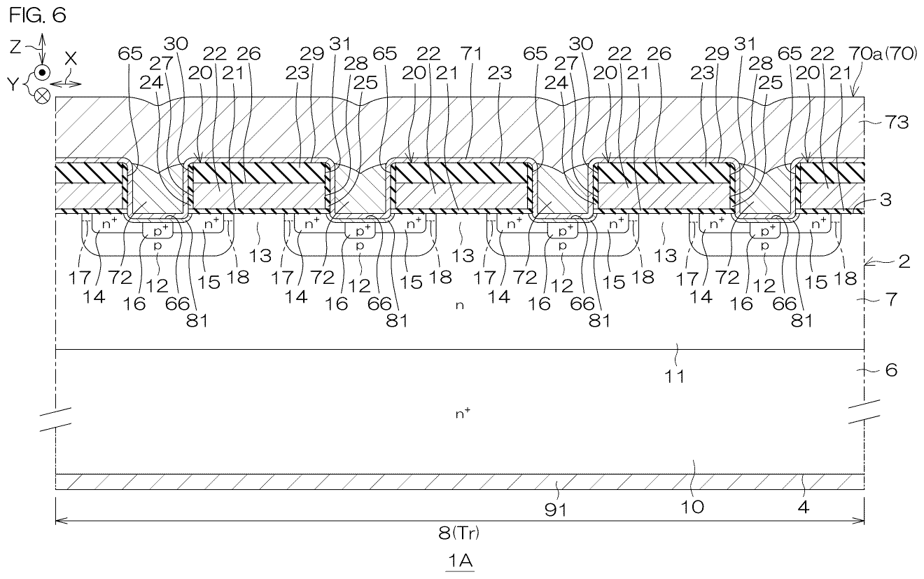

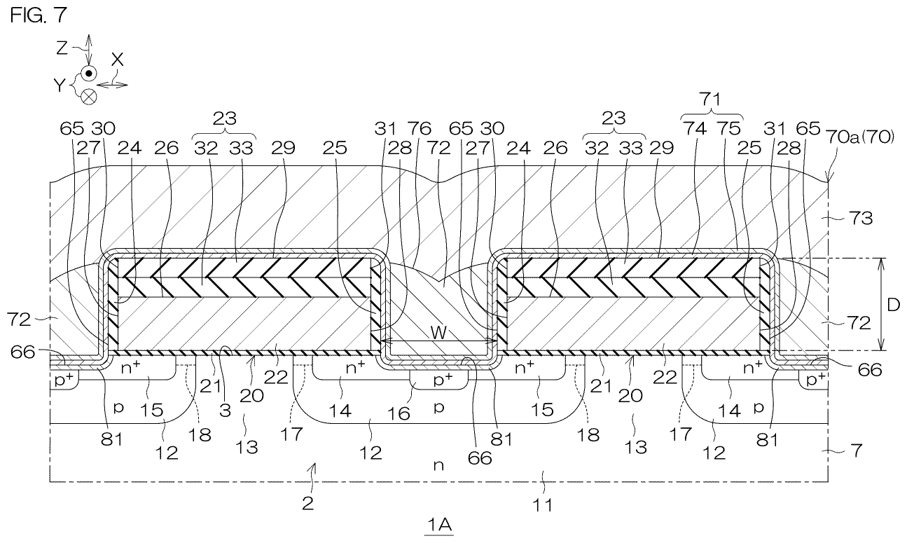

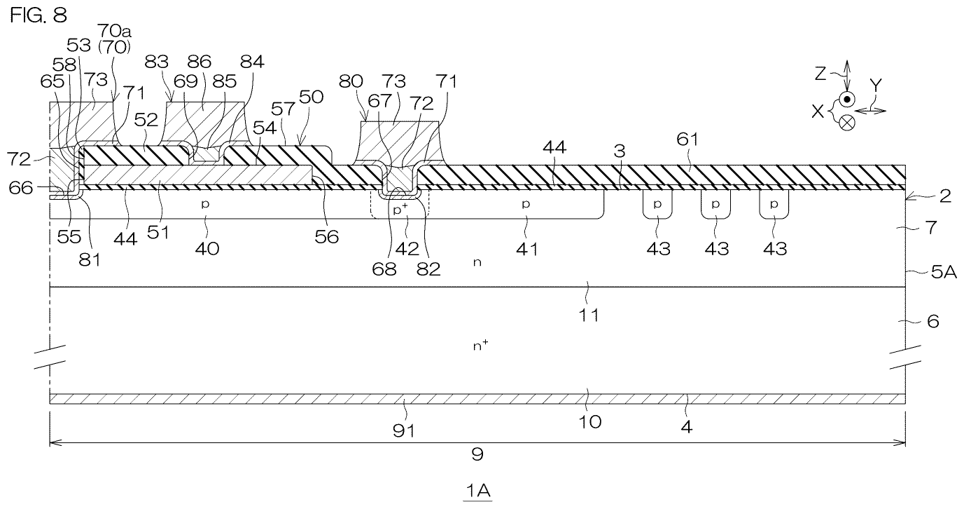

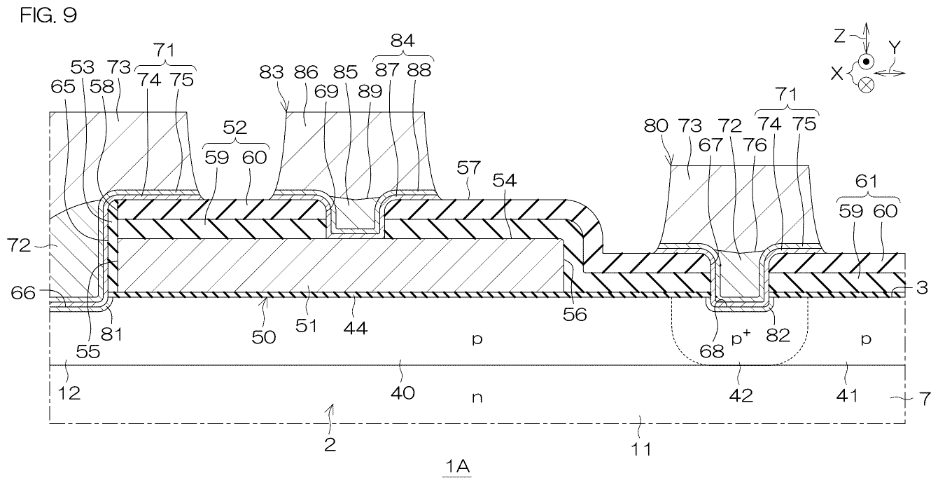

FIG. 6 is a cross-sectional view taken along line VI-VI in FIG. 5. FIG. 7 is an enlarged cross-sectional view showing a main portion of FIG. 6 together with a gate structure 20 according to a first example. FIG. 8 is a cross-sectional view taken along line VIII-VIII in FIG. 5. FIG. 9 is an enlarged cross-sectional view showing a main portion of FIG. 8 together with a wiring structure 50 according to the first example.

With reference to FIG. 1 to FIG. 9, the semiconductor device 1A is a semiconductor switching device having a transistor structure Tr of an insulated gate type as an example of a device structure. The transistor structure Tr has a vertical type structure. The semiconductor device 1A is an SiC semiconductor device having a chip 2 containing an SiC monocrystal. The chip 2 may be referred to as an “SiC chip” or as a “semiconductor chip.”

In this embodiment, the chip 2 is constituted of a hexagonal SiC monocrystal and is formed in a rectangular parallelepiped shape. The hexagonal SiC monocrystal has multiple polytypes including a 2H (hexagonal)-SiC monocrystal, a 4H—SiC monocrystal, a 6H—SiC monocrystal, etc. In this embodiment, an example in which the chip 2 is constituted of the 4H—SiC monocrystal is described, but the chip 2 may be constituted of another polytype.

The chip 2 has the first main surface 3 on one side, a second main surface 4 on the other side, and first to fourth side surfaces 5A to 5D connecting the first main surface 3 and the second main surface 4. In plan view from a vertical direction Z (hereinafter referred to simply as “plan view”), the first main surface 3 and the second main surface 4 are each formed in a quadrangular shape. The vertical direction Z is also a thickness direction of the chip 2 and a normal direction to the first main surface 3 (the second main surface 4). The first main surface 3 and the second main surface 4 may be formed in a square shape or a rectangular shape in plan view.

The first main surface 3 and the second main surface 4 are preferably formed by c-planes of the SiC monocrystal. In this case, preferably, the first main surface 3 is formed by a silicon plane ((0001) plane) of the SiC monocrystal, and the second main surface 4 is formed by a carbon plane ((000-1) plane) of the SiC monocrystal.

The first side surface 5A and the second side surface 5B extend in a first direction X along the first main surface 3 and oppose each other in a second direction Y intersecting the first direction X along the first main surface 3. Specifically, the second direction Y is orthogonal to the first direction X. The third side surface 5C and the fourth side surface 5D extend in the second direction Y and oppose each other in the first direction X.

In this embodiment, the first direction X is an m-axis direction ([1-100] direction) of the SiC monocrystal, and the second direction Y is an a-axis direction ([11-20] direction) of the SiC monocrystal. The first direction X may be the a-axis direction of the SiC monocrystal, and the second direction Y may be the m-axis direction of the SiC monocrystal. In the following, a direction extending along the first main surface 3 may be referred to as a “horizontal direction.” The horizontal direction is also an XY plane (a horizontal plane) formed by the first direction X and the second direction Y and is orthogonal to the vertical direction Z.

The chip 2 (the first main surface 3 and the second main surface 4) has an off angle inclined at a predetermined angle in a predetermined off direction with respect to the c-planes of the SiC monocrystal. That is, a c-axis ((0001) axis) of the SiC monocrystal is inclined by just the off angle toward the off direction from the vertical axis. Also, the c-planes of the SiC monocrystal are inclined by just the off angle with respect to the horizontal plane.

The off direction is preferably an a-axis direction (that is, the second direction Y) of the SiC monocrystal. The off angle may exceed 0° and be not more than 10°. The off angle may have a value falling within at least one of ranges of exceeding 0° and not more than 10, not less than 10 and not more than 2.5°, not less than 2.5° and not more than 5°, not less than 5° and not more than 7.5°, and not less than 7.5° and not more than 10°.

The off angle is preferably not more than 5°. The off angle is particularly preferably not less than 2° and not more than 4.5°. The off angle is typically set in a range of 4°±0.1°. This Description does not exclude an embodiment in which the off angle is 0° (that is, an embodiment in which the first main surface 3 is a just surface with respect to the c-plane).

In this embodiment, the chip 2 has a laminated structure including a first semiconductor layer 6 and a second semiconductor layer 7. The first semiconductor layer 6 is constituted of a substrate (an SiC substrate) containing an SiC monocrystal (a semiconductor monocrystal) and has the off direction and the off angle described above. The first semiconductor layer 6 forms the second main surface 4 and forms portions of the first to fourth side surfaces 5A to 5D.

The first semiconductor layer 6 may have a thickness of not less than 10 μm and not more than 500 μm. The thickness of the first semiconductor layer 6 may have a value falling within at least one of ranges of not less than 10 μm and not more than 50 μm, not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, and not less than 400 μm and not more than 500 μm.

The second semiconductor layer 7 is constituted of an epitaxial layer (an SiC epitaxial layer) containing an SiC monocrystal (a semiconductor monocrystal) and is laminated on the first semiconductor layer 6. The second semiconductor layer 7 has the off direction and the off angle described above. The second semiconductor layer 7 forms the first main surface 3 and forms portions of the first to fourth side surfaces 5A to 5D. The second semiconductor layer 7 preferably has a thickness less than the thickness of the first semiconductor layer 6. The thickness of the second semiconductor layer 7 may be larger than the thickness of the first semiconductor layer 6.

The thickness of the second semiconductor layer 7 may be not less than 5 μm and not more than 50 μm. The thickness of the second semiconductor layer 7 may have a value falling within at least one of ranges of not less than 5 μm and not more than 10 μm, not less than 10 μm and not more than 15 μm, not less than 15 μm and not more than 20 μm, not less than 20 μm and not more than 25 μm, not less than 25 μm and not more than 30 μm, not less than 30 μm and not more than m, not less than 35 μm and not more than 40 μm, not less than 40 μm and not more than 45 μm, and not less than 45 μm and not more than 50 μm.

The semiconductor device 1A includes an active region 8 set in an inner portion of the chip 2 (the first main surface 3). The active region 8 is a region which includes the transistor structure Tr (the device structure) and in which an output current (a drain current) is generated.

The active region 8 is set in the inner portion of the chip 2 at intervals from peripheral edges (the first to fourth side surfaces 5A to 5D) of the chip 2 in plan view. The active region 8 is set in a polygonal shape (a quadrangular shape in this embodiment) having four sides parallel to the peripheral edges of the chip 2 in plan view. A plane area of the active region 8 is preferably not less than 50% and not more than 90% of a plane area of the first main surface 3.

The semiconductor device 1A includes an outer peripheral region 9 that, in the chip 2, is set outside the active region 8. The outer peripheral region 9 is a region which does not include the device structure (the transistor structure Tr). The outer peripheral region 9 is set in a peripheral edge portion of the chip 2 (the first main surface 3). That is, the outer peripheral region 9 is provided in a region between the peripheral edges of the chip 2 and the active region 8 in plan view. The outer peripheral region 9 extends as a band along the active region 8 and is set in a polygonal annular shape (a quadrangular annular shape in this embodiment) that surrounds the active region 8 in plan view.

The semiconductor device 1A includes a first semiconductor region 10 of the n-type formed in a surface layer portion of the second main surface 4 in the active region 8. A drain potential as a first potential (a high potential) is applied to the first semiconductor region 10. The first semiconductor region 10 may be referred to as a “drain region,” a “first region,” etc.

The first semiconductor region 10 extends in a layer shape along the second main surface 4. The first semiconductor region 10 is formed over the entire active region 8. The first semiconductor region 10 is led out from the active region 8 to the outer peripheral region 9 and has a portion positioned in the surface layer portion of the second main surface 4 in the outer peripheral region 9. The first semiconductor region 10 is led out from the active region 8 to the outer peripheral region 9 along the entire periphery thereof. The first semiconductor region 10 is exposed from at least one of the first to fourth side surfaces 5A to 5D. In this embodiment, the first semiconductor region 10 is exposed from the entire periphery of the first to fourth side surfaces 5A to 5D.

The first semiconductor region 10 is formed in the first semiconductor layer 6. The first semiconductor region 10 is formed in an entire thickness range between a lower end (the second main surface 4) of the first semiconductor layer 6 and an upper end (the second semiconductor layer 7) of the first semiconductor layer 6 and is connected to the second semiconductor layer 7. The first semiconductor region 10 is formed using the first semiconductor layer 6 of the n-type and has a thickness corresponding to the thickness of the first semiconductor layer 6. The first semiconductor region 10 may be formed by introducing an n-type impurity into the surface layer portion of the second main surface 4.

The semiconductor device 1A includes a second semiconductor region 11 of the n-type formed in a surface layer portion of the first main surface 3 in the active region 8. The second semiconductor region 11 may be referred to as a “drift region,” a “second region,” etc. The second semiconductor region 11 has an impurity concentration lower than an impurity concentration of the first semiconductor region 10.

The second semiconductor region 11 extends in a layer shape along the first main surface 3 and is electrically connected to the first semiconductor region 10 inside the chip 2. The second semiconductor region 11 is formed over the entire active region 8. In this embodiment, the second semiconductor region 11 is led out from the active region 8 to the outer peripheral region 9 and has a portion positioned in the surface layer portion of the first main surface 3 in the outer peripheral region 9.

The second semiconductor region 11 is led out from the active region 8 to the outer peripheral region 9 along the entire periphery thereof. The second semiconductor region 11 is preferably exposed from at least one of the first to fourth side surfaces 5A to 5D. In this embodiment, the second semiconductor region 11 is exposed from the entire periphery of the first to fourth side surfaces 5A to 5D.

The second semiconductor region 11 is formed in the second semiconductor layer 7. The second semiconductor region 11 is formed in an entire thickness range between the upper end (the first semiconductor region 10) of the first semiconductor layer 6 and an upper end (the first main surface 3) of the second semiconductor layer 7 and is connected to the first semiconductor layer 6 (the first semiconductor region 10). In this embodiment, the second semiconductor region 11 is formed using the second semiconductor layer 7 of the n-type and has a thickness corresponding to the thickness of the second semiconductor layer 7. The second semiconductor region 11 may be formed by introducing an n-type impurity into the surface layer portion of the first main surface 3.

The semiconductor device 1A includes a plurality of body regions 12 of the p-type formed at intervals in the surface layer portion of the first main surface 3 in the active region 8. The plurality of body regions 12 are respectively formed in a surface layer portion of the second semiconductor region 11. The plurality of body regions 12 have a p-type impurity concentration higher than an n-type impurity concentration of the second semiconductor region 11. A source potential as a second potential (a low potential) different from the first potential (the high potential) is applied to the body regions 12.

The plurality of body regions 12 are aligned at intervals in the first direction X and are each formed as a band extending in the second direction Y. That is, the plurality of body regions 12 are aligned as stripes extending in the second direction Y. Also, an extension direction of the plurality of body regions 12 coincides with the off direction of the SiC monocrystal.

The plurality of body regions 12 are formed at an interval to the first main surface 3 side from a bottom portion of the second semiconductor region 11 and face the first semiconductor region 10 with portions of the second semiconductor region 11 interposed therebetween. The plurality of body regions 12 are preferably formed at an interval to the first main surface 3 side from an intermediate portion of the second semiconductor region 11.

The plurality of body regions 12 may cross a depth position of the intermediate portion of the second semiconductor region 11 in the thickness direction. The plurality of body regions 12 are exposed from the first main surface 3. The plurality of body regions 12 respectively form pn junction portions (pn junction diodes: body diodes) with the second semiconductor region 11 and expand a depletion layer into the second semiconductor region 11 when a reverse bias voltage is applied.

Each of the plurality of body regions 12 may have a width of not less than 1 μm and not more than 10 μm. The width of the body region 12 may have a value falling within at least one of ranges of not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm. The width of the body region 12 is preferably not less than 1.5 μm and not more than 2.5 μm.

Each of the plurality of body regions 12 may have a thickness (a depth) of not less than 0.1 μm and not more than 2.5 μm. The thickness of the body region 12 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, and not less than 2 μm and not more than 2.5 μm. The thickness of the body region 12 is preferably not less than 0.5 μm and not more than 1.5 μm.

The semiconductor device 1A includes a plurality of surface layer drift regions 13 of the n-type formed in the surface layer portion of the first main surface 3. In this embodiment, each of the plurality of surface layer drift regions 13 are constituted of a portion of the second semiconductor region 11. The plurality of surface layer drift regions 13 may have an n-type impurity concentration higher than the n-type impurity concentration of the second semiconductor region 11 or may have an n-type impurity concentration lower than the n-type impurity concentration of the second semiconductor region 11.

The plurality of surface layer drift regions 13 are respectively demarcated in regions between the plurality of body regions 12 adjacent in the first direction X in the surface layer portion of the second semiconductor region 11. That is, the plurality of surface layer drift regions 13 are aligned at intervals in the first direction X and are each formed as a band extending in the second direction Y. Also, the plurality of surface layer drift regions 13 are formed as stripes extending in the second direction Y. The surface layer drift regions 13 form a JFET structure of a pnp-type with the plurality of body regions 12 positioned on both sides thereof.

A width the surface layer drift region 13 is preferably less than the width of body region 12. The width of surface layer drift region 13 may be larger than the width of body region 12. The surface layer drift region 13 has a width of not less than 0.1 μm and not more than 5 μm in the horizontal direction (the first direction X in this embodiment).

The width of the surface layer drift region 13 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the surface layer drift region 13 is preferably not less than 0.5 μm and not more than 2 μm.

The SiC semiconductor device 1A includes a plurality of source regions 14 and 15 of the n-type that are respectively formed in surface layer portions of the plurality of body regions 12. The plurality of source regions 14 and 15 have an n-type impurity concentration higher than the n-type impurity concentration of the second semiconductor region 11. A source potential is applied to the plurality of source regions 14 and 15.

The plurality of source regions 14 and 15 include, in the surface layer portion of each of the body regions 12, the first source region 14 positioned on one side (the third side surface 5C side) in the first direction X and the second source region 15 positioned on the other side (the fourth side surface 5D side) in the first direction X. In this embodiment, the single first source region 14 is formed on one end side of the body region 12, and the single second source region 15 is formed on the other end side of the body region 12.

The first source region 14 is formed at an interval to the other end side from one end of the body region 12. The second source region 15 is formed at an interval to the other end of the body region 12 side from the first source region 14. The second source region 15 is formed at an interval to the one end side from the other end of the body region 12.

The plurality of source regions 14 and 15 extend as bands along the extension direction of the body region 12. The plurality of source regions 14 and 15 are formed at intervals inward from both end portions of the body region 12 in the second direction Y, and the both end portions of the body region 12 are exposed from the first main surface 3 (see FIG. 5).

The plurality of source regions 14 and 15 are formed at an interval to the first main surface 3 side from a bottom portion of the body region 12 and face the second semiconductor region 11 with portions of the body region 12 interposed therebetween. The plurality of source regions 14 and 15 are preferably formed at an interval to the first main surface 3 side from an intermediate portion of the body region 12.

In a case where a plurality of the first source regions 14 are formed in the single body regions 12, the plurality of first source regions 14 may be formed at intervals in the extension direction of the body region 12. In this case, each of the first source regions 14 may be formed as a band extending in the second direction Y. In a case where a plurality of the second source regions 15 are formed in one of the body regions 12, the plurality of second source regions 15 may be formed at intervals in the extension direction of the body region 12. In this case, each of the second source regions 15 may be formed as a band extending in the second direction Y.

The semiconductor device 1A includes a plurality of contact regions 16 of the p-type formed in regions different from the plurality of source regions 14 and 15 in the surface layer portions of the body regions 12. The contact region 16 may be referred to as a “back gate region.” The plurality of contact regions 16 have a p-type impurity concentration higher than the p-type impurity concentration of the body regions 12. A source potential is applied to the plurality of contact regions 16.

In this embodiment, one of the contact regions 16 is interposed in a region between the first source region 14 and the second source region 15 in the surface layer portion of one of the body regions 12 and is electrically connected to the body region 12. The contact region 16 extends as a band along the extension direction of the body region 12 (the source regions 14 and 15). The contact region 16 is formed at intervals inward from the both end portions of the body region 12 in the second direction Y, and the both end portions of the body region 12 are exposed from the first main surface 3 (see FIG. 5).

In this embodiment, the contact region 16 has a width smaller than the widths of the source regions 14 and 15. The width of the contact region 16 may be larger than the widths of the source regions 14 and 15. The contact region 16 is formed at an interval to the first main surface 3 side from the bottom portion of the body region 12 and face the second semiconductor region 11 with a portion of the body region 12 interposed therebetween.

The contact region 16 is preferably formed at an interval to the first main surface 3 side from the intermediate portion of the body region 12. The contact region 16, in this embodiment, has a thickness (a depth) larger than thicknesses (depths) of the source regions 14 and 15 and has a bottom portion that is positioned further to the bottom portion side of the body region 12 than bottom portions of the source regions 14 and 15.

In a case where the plurality of contact regions 16 are formed in one of the body regions 12, the plurality of contact regions 16 may be formed at intervals in the extension direction of the body region 12. In this case, each of the contact regions 16 may be formed as a band extending in the second direction Y.

The semiconductor device 1A includes a plurality of channel regions 17 and 18 of the p-type formed in the surface layer portion of the first main surface 3. The plurality of channel regions 17 and 18 are respectively formed in the surface layer portions of the plurality of body regions 12. The plurality of channel regions 17 and 18 include the first channel region 17 on one side in the first direction X and the second channel region 18 on the other side in the first direction X.

The first channel region 17 is formed in a region between the second semiconductor region 11 (the surface layer drift region 13) and the first source region 14 in the surface layer portion of the body region 12. The second channel region 18 is formed in a region between the second semiconductor region 11 (the surface layer drift region 13) and the second source region 15 in the surface layer portion of the body region 12.

In this embodiment, the plurality of channel regions 17 and 18 are aligned at intervals in the first direction X and are each formed as a band extending in the second direction Y. That is, the plurality of channel regions 17 and 18 are aligned as stripes extending in the second direction Y.

The semiconductor device 1A includes a plurality of gate structures 20 of a planar electrode type arranged on the first main surface 3 in the active region 8. The plurality of gate structures 20 constitute gates of the transistor structure Tr of the vertical type.

The plurality of gate structures 20 are aligned at intervals in the first direction X and are each formed as a band extending in the second direction Y. That is, the plurality of gate structures 20 are aligned as stripes extending in the second direction Y. Also, an extension direction of the plurality of gate structures 20 coincides with the off direction of the SiC monocrystal.

Each of the plurality of gate structures 20 includes a gate insulating film 21, a gate electrode 22, a first planar insulating film 23, and a plurality of side wall insulating films 24 and 25. Hereinafter, an arrangement of one of the gate structures 20 shall be described.

The gate insulating film 21 may include at least one among a silicon oxide film, a silicon nitride film, and a silicon oxynitride film. In this embodiment, the gate insulating film 21 has a single layer structure constituted of the silicon oxide film. The gate insulating film 21 preferably includes the silicon oxide film constituted of an oxide of the chip 2.

The gate insulating film 21 covers the first main surface 3 in a film shape. The gate insulating film 21 extends as a band in the second direction Y in plan view. The gate insulating film 21 covers at least one of the channel regions 17 and 18. In this embodiment, the gate insulating film 21 straddles the two adjacent body regions 12 across one of the surface layer drift regions 13 and covers the surface layer drift region 13 and the plurality of channel regions 17 and 18.

Specifically, the gate insulating film 21 straddles the first source region 14 on the one body region 12 side and the second source region 15 on the other body region 12 side and covers the surface layer drift region 13, the first source region 14, the second source region 15, the first channel region 17, and the second channel region 18.

The gate insulating film 21 partially covers the first source region 14 at an interval from the contact region 16 and exposes a portion of the first source region 14 and the contact region 16 from the first main surface 3. The gate insulating film 21 partially covers the second source region 15 at an interval from the contact region 16 and exposes a portion of the second source region 15 and the contact region 16 from the first main surface 3.

The gate insulating film 21 may have a thickness of not less than 10 nm and not more than 150 nm. The thickness of the gate insulating film 21 may have a value falling within at least one of ranges of not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm. The thickness of the gate insulating film 21 is preferably not less than 25 nm and not more than 75 nm.

The gate electrode 22 is arranged on the gate insulating film 21. A gate potential as a control potential is applied to the gate electrode 22. The gate electrode 22 may contain either or both of a conductive polysilicon of the p-type and a conductive polysilicon of the n-type. The conductivity type of the gate electrode 22 is adjusted in accordance with a gate threshold voltage to be achieved.

The gate electrode 22 extends as a band in the second direction Y in plan view. In this embodiment, the gate electrode 22 is formed at intervals inward from both ends of the gate insulating film 21 in the first direction X and exposes both end portions of the gate insulating film 21. That is, the gate electrode 22 exposes the plurality of source regions 14 and 15 and the plurality of contact regions 16.

The gate electrode 22 is arranged on the gate insulating film 21 such as to face at least one of the channel regions 17 and 18. In this embodiment, the gate electrode 22 straddles the two adjacent body regions 12 across one of the surface layer drift regions 13 and faces the surface layer drift region 13 and the plurality of channel regions 17 and 18 with the gate insulating film 21 interposed therebetween.

Specifically, the gate electrode 22 straddles the first source region 14 on the one body region 12 side and the second source region 15 on the other body region 12 side and faces the surface layer drift region 13, the first source region 14, the second source region 15, the first channel region 17, and the second channel region 18 with the gate insulating film 21 interposed therebetween.

The gate electrode 22 has an electrode surface 26, a first side wall 27 on the one side in the first direction X, and a second side wall 28 on the other side in the first direction X. The electrode surface 26 extends flatly along the gate insulating film 21 (the first main surface 3). The electrode surface 26 may extend substantially parallel to the gate insulating film 21 (the first main surface 3).

The first side wall 27 is formed at an interval to the other end portion side from one end portion of the gate insulating film 21 in the first direction X and extends in the vertical direction Z. The second side wall 28 is formed at an interval to the one end portion side from the other end portion of the gate insulating film 21 in the first direction X and extends in the vertical direction Z.

The first side wall 27 and the second side wall 28 may extend substantially perpendicular to the gate insulating film 21. That is, the gate electrode 22 may be formed in a quadrangular shape (a flat rectangular shape) in cross-sectional view. The first side wall 27 and the second side wall 28 may be inclined obliquely toward the electrode surface 26. That is, the gate electrode 22 may be formed in a tapered shape (preferably, an isosceles trapezoidal shape) in cross-sectional view.

The gate electrode 22 may have a width of not less than 1 μm and not more than 10 μm. The width of the gate electrode 22 is a width in a direction (that is, the first direction X) orthogonal to the extension direction. The width of the gate electrode 22 may have a value falling within at least one of ranges of not less than 1 μm and not more than 2.5 μm, not less than 2.5 μm and not more than 5 μm, not less than 5 μm and not more than 7.5 μm, and not less than 7.5 μm and not more than 10 μm. The width of the gate electrode 22 is preferably not less than 1.5 μm and not more than 2.5 μm.

The gate electrode 22 may have a thickness of not less than 0.1 μm and not more than 2 μm. The thickness of the gate electrode 22 may have a value falling within at least one of ranges of not less than 0.1 μm and not more than 0.5 μm, not less than 0.5 μm and not more than 1 μm, not less than 1 μm and not more than 1.5 μm, and not less than 1.5 μm and not more than 2 μm. The thickness of the gate electrode 22 is preferably not less than 0.2 μm and not more than 1 μm.

The first planar insulating film 23 is arranged on the gate electrode 22. Specifically, the first planar insulating film 23 covers the electrode surface 26 in a film shape and exposes both the first side wall 27 and the second side wall 28. The first planar insulating film 23 does not have a portion covering the gate insulating film 21. The first planar insulating film 23 extends as a band in the second direction Y in plan view.

The first planar insulating film 23 has a first insulating surface 29, a first insulating side wall 30 on the one side in the first direction X, and a second insulating side wall 31 on the other side in the first direction X. The first insulating surface 29 extends flatly along the electrode surface 26. The first insulating surface 29 may extend substantially parallel to the electrode surface 26.

The first insulating side wall 30 extends in the vertical direction Z on the gate electrode 22 and is connected to the first side wall 27 of the gate electrode 22. The first insulating side wall 30 may be formed to be flush with the first side wall 27.

The first insulating side wall 30 may be positioned further outward than the first side wall 27 and may face the gate insulating film 21 in a lamination direction. The first insulating side wall 30 may be positioned on the electrode surface 26 at an interval from the first side wall 27 and may expose a peripheral edge portion of the electrode surface 26. In this case, the first insulating side wall 30 may be connected to the first side wall 27 via the peripheral edge portion of the electrode surface 26.

The second insulating side wall 31 extends in the vertical direction Z on the gate electrode 22 and is connected to the second side wall 28 of the gate electrode 22. The second insulating side wall 31 may be formed to be flush with the second side wall 28.

The second insulating side wall 31 may be positioned further outward than the second side wall 28 and may face the gate insulating film 21 in the lamination direction. The second insulating side wall 31 may be positioned on the electrode surface 26 at an interval from the second side wall 28 and may expose a peripheral edge portion of the electrode surface 26. In this case, the second insulating side wall 31 may be connected to the second side wall 28 via the peripheral edge portion of the electrode surface 26.

The first insulating side wall 30 and the second insulating side wall 31 may extend substantially perpendicular to the gate insulating film 21. That is, the first planar insulating film 23 may be formed in a quadrangular shape (a flat rectangular shape) in cross-sectional view. The first insulating side wall 30 and the second insulating side wall 31 may be inclined obliquely toward the first insulating surface 29. That is, the first planar insulating film 23 may be formed in a tapered shape (preferably, an isosceles trapezoidal shape) in cross-sectional view.

The first planar insulating film 23 may have a thickness of not less than 0.1 μm and not more than 2 μm. The thickness of the first planar insulating film 23 may have a value falling within at least one of ranges of not less than 0.1 μm and not more than 0.5 μm, not less than 0.5 μm and not more than 1 μm, not less than 1 μm and not more than 1.5 μm, and not less than 1.5 μm and not more than 2 μm. The thickness of the first planar insulating film 23 is preferably not less than 0.2 μm.

The first planar insulating film 23 may include at least one among a silicon oxide film, a silicon nitride film, and a silicon oxynitride film. The first planar insulating film 23 may have a single layer structure constituted of a single insulating film. The first planar insulating film 23 may have a laminated structure including a plurality of insulating films. In this embodiment, the first planar insulating film 23 has the laminated structure including a first oxide film 32 (a first insulating film) and a second oxide film 33 (a second insulating film) laminated in that order from the gate electrode 22 side.

The first oxide film 32 has a single layer structure constituted of an undoped silicon oxide film. The undoped silicon oxide film may be referred to as an NSG film (a nondoped silicate glass film). The first oxide film 32 directly covers the electrode surface 26 in a film shape and exposes both the first side wall 27 and the second side wall 28. The first oxide film 32 extends as a band in the second direction Y in plan view and forms a portion of the first insulating side wall 30 and a portion of the second insulating side wall 31.

The first oxide film 32 may have a thickness of not less than 0.01 μm and not more than 0.2 μm. The thickness of the first oxide film 32 may have a value falling within at least one of ranges of not less than 0.01 μm and not more than 0.05 μm, not less than 0.05 μm and not more than 0.1 μm, not less than 0.1 μm and not more than 0.15 μm, and not less than 0.15 μm and not more than 0.2 μm. The thickness of the first oxide film 32 is preferably not less than 0.05 μm.

The second oxide film 33 may have a single layer structure constituted of a silicon oxide film containing phosphorus or a laminated structure constituted of the silicon oxide film containing phosphorus. The silicon oxide film containing phosphorus may contain boron. The silicon oxide film containing phosphorus may be referred to as a PSG film (a phosphorus silicon glass film). The silicon oxide film containing both phosphorus and boron may be referred to as a BPSG film (a boron phosphorus silicon glass film).

The second oxide film 33 may have a single layer structure constituted of the PSG film or the BPSG film laminated on the first oxide film 32. The second oxide film 33 may have a laminated structure including the PSG film laminated on the first oxide film 32, and the BPSG film laminated on the PSG film. The second oxide film 33 may have a laminated structure including the BPSG film laminated on the first oxide film 32, and the PSG film laminated on the BPSG film. In this embodiment, the second oxide film 33 has, as an example, a single layer structure constituted of the PSG film.

The second oxide film 33 directly covers the first oxide film 32 in a film shape and exposes both the first side wall 27 and the second side wall 28. The second oxide film 33 extends as a band in the second direction Y in plan view and forms the first insulating surface 29, a portion of the first insulating side wall 30, and a portion of the second insulating side wall 31.

The second oxide film 33 preferably has a thickness larger than the thickness of the first oxide film 32. The thickness of the second oxide film 33 may be less than the thickness of the first oxide film 32. The thickness of the second oxide film 33 may be not less than 0.05 μm and not more than 1.8 μm.

The thickness of the second oxide film 33 may have a value falling within at least one of ranges of not less than 0.05 μm and not more than 0.1 μm, not less than 0.1 μm and not more than 0.5 μm, not less than 0.5 μm and not more than 1 μm, not less than 1 μm and not more than 1.5 μm, and not less than 1.5 μm and not more than 1.8 μm. The thickness of the second oxide film 33 is preferably not less than 0.1 μm.

The second oxide film 33 enhances the flatness of the first planar insulating film 23 (that is, the film formability of the first planar insulating film 23 with respect to the electrode surface 26). Fluctuations in electrical characteristics of the gate electrode 22 due to the impurity diffusion in the second oxide film 33 are prevented by the undoped first oxide film 32. Fluctuations in insulation characteristics of the second oxide film 33 due to the impurity diffusion in the gate electrode 22 are prevented by the undoped first oxide film 32.

The plurality of side wall insulating films 24 and 25 respectively cover the first side wall 27 and the second side wall 28. Specifically, the plurality of side wall insulating films 24 and 25 include the first side wall insulating film 24 covering the first side wall 27 and the second side wall insulating film 25 covering the second side wall 28.

The first side wall insulating film 24 covers the first side wall 27 on the gate insulating film 21. The first side wall insulating film 24 is formed on the gate insulating film 21 at an interval from the contact region 16 and exposes a portion of the second source region 15 and the contact region 16. Specifically, the first side wall insulating film 24 is arranged on just the gate insulating film 21 and has neither a portion directly covering the second source region 15 nor a portion directly covering the contact region 16.

The first side wall insulating film 24 faces a portion of the second source region 15 with the gate insulating film 21 interposed therebetween. The first side wall insulating film 24 is formed at an interval inward of the body region 12 from the second channel region 18. The first side wall insulating film 24 does not have a portion facing the second channel region 18 with the gate insulating film 21 interposed therebetween.

In this embodiment, the first side wall insulating film 24 is led out from the first side wall 27 toward the first insulating side wall 30 of the first planar insulating film 23 and covers the first insulating side wall 30. That is, the first side wall insulating film 24 has a portion covering the first side wall 27 and a portion covering the first insulating side wall 30. Also, the first side wall insulating film 24 has a portion covering a boundary portion between the gate electrode 22 and the first planar insulating film 23.

The first side wall insulating film 24 covers the first side wall 27 and the first insulating side wall 30 in a film shape conforming to an inclination angle of the first side wall 27 and an inclination angle of the first insulating side wall 30. The first side wall insulating film 24 has a film surface extending at an inclination angle substantially equal to the inclination angle of the first side wall 27 in a covering portion with respect to the first side wall 27 and extending substantially parallel to the first side wall 27. The first side wall insulating film 24 has a film surface extending at an inclination angle substantially equal to the inclination angle of the first insulating side wall 30 at a covering portion with respect to the first insulating side wall 30 and extending substantially parallel to the first insulating side wall 30.

In this embodiment, the first side wall insulating film 24 extends substantially vertically in a region between the gate insulating film 21 (the first main surface 3) and the first insulating surface 29. That is, the first side wall insulating film 24 has a film surface extending in the vertical direction Z in the covering portion with respect to the first side wall 27 and has a film surface extending in the vertical direction Z in the covering portion with respect to the first insulating side wall 30.

The first side wall insulating film 24 covers both the first oxide film 32 and the second oxide film 33 on the first insulating side wall 30 side. That is, the first side wall insulating film 24 has a portion covering a boundary portion between the first oxide film 32 and the second oxide film 33. The first side wall insulating film 24 is formed on the first main surface 3 side with respect to the first insulating surface 29 and exposes the first insulating surface 29. That is, the first side wall insulating film 24 exposes the second oxide film 33 from the first insulating surface 29.

The second side wall insulating film 25 covers the second side wall 28 on the gate insulating film 21. The second side wall insulating film 25 is formed on the gate insulating film 21 at an interval from the contact region 16 and exposes a portion of the first source region 14 and the contact region 16. Specifically, the second side wall insulating film 25 is arranged on just the gate insulating film 21 and has neither a portion directly covering the first source region 14 nor a portion directly covering the contact region 16.

The second side wall insulating film 25 faces a portion of the first source region 14 with the gate insulating film 21 interposed therebetween. The second side wall insulating film 25 is formed at an interval inward of the body region 12 from the first channel region 17. The second side wall insulating film 25 does not have a portion facing the first channel region 17 with the gate insulating film 21 interposed therebetween.

In this embodiment, the second side wall insulating film 25 is led out from the second side wall 28 toward the second insulating side wall 31 of the first planar insulating film 23 and covers the second insulating side wall 31. That is, the second side wall insulating film 25 has a portion covering the second side wall 28 and a portion covering the second insulating side wall 31. Also, the second side wall insulating film 25 has a portion covering the boundary portion between the gate electrode 22 and the first planar insulating film 23.

The second side wall insulating film 25 covers the second side wall 28 and the second insulating side wall 31 in a film shape conforming to an inclination angle of the second side wall 28 and an inclination angle of the second insulating side wall 31. The second side wall insulating film 25 has a film surface extending at an inclination angle substantially equal to the inclination angle of the second side wall 28 in a covering portion with respect to the second side wall 28 and extending substantially parallel to the second side wall 28. The second side wall insulating film 25 has a film surface extending at an inclination angle substantially equal to the inclination angle of the second insulating side wall 31 in a covering portion with respect to the second insulating side wall 31 and extending substantially parallel to the second insulating side wall 31.

In this embodiment, the second side wall insulating film 25 extends substantially vertically in a region between the gate insulating film 21 (the first main surface 3) and the first insulating surface 29. That is, the second side wall insulating film 25 has a film surface extending in the vertical direction Z in the covering portion with respect to the second side wall 28 and has a film surface extending in the vertical direction Z in the covering portion with respect to the second insulating side wall 31.

The second side wall insulating film 25 covers both the first oxide film 32 and the second oxide film 33 on the second insulating side wall 31 side. That is, the second side wall insulating film 25 has a portion covering the boundary portion between the first oxide film 32 and the second oxide film 33. The second side wall insulating film 25 has a portion facing the first side wall insulating film 24 with the first oxide film 32 interposed therebetween, and a portion facing the first side wall insulating film 24 with the second oxide film 33 interposed therebetween.

The second side wall insulating film 25 is formed on the first main surface 3 side with respect to the first insulating surface 29 and exposes the first insulating surface 29. That is, the second side wall insulating film 25 exposes the second oxide film 33 from the first insulating surface 29.

The plurality of side wall insulating films 24 and 25 may include at least one among a silicon oxide film, a silicon nitride film, and a silicon oxynitride film. Each of the plurality of side wall insulating films 24 and 25 may have a single layer structure constituted of a single insulating film. Each of the plurality of side wall insulating films 24 and 25 may have a laminated structure including a plurality of insulating films.

In this embodiment, each of the plurality of side wall insulating films 24 and 25 has a single layer structure constituted of an undoped silicon oxide film. That is, each of the plurality of side wall insulating films 24 and 25 is constituted of the NSG film. In this embodiment, each of the plurality of side wall insulating films 24 and 25 includes a tetraethyl orthosilicate film as an example of the NSG film. The tetraethyl orthosilicate film may be referred to as a “TEOS film.”

In a case where the plurality of side wall insulating films 24 and 25 are each constituted of the NSG film (the TEOS film), fluctuations in electrical characteristics of the gate electrode 22 due to the impurity diffusion in the second oxide film 33 are prevented by the plurality of side wall insulating films 24 and 25. Also, fluctuations in insulation characteristics of the second oxide film 33 due to the impurity diffusion in the gate electrode 22 are prevented by the plurality of side wall insulating films 24 and 25.

Each of the plurality of side wall insulating films 24 and 25 has a thickness less than the thickness of the gate electrode 22. The thickness of the plurality of side wall insulating films 24 and 25 is a thickness of the plurality of side wall insulating films 24 and 25 in the horizontal direction with the first side wall 27 or the second side wall 28 of the gate electrode 22 as a reference. The thickness of the plurality of side wall insulating films 24 and 25 is less than the thickness (the total thickness) of the first planar insulating film 23.

The thickness of the plurality of side wall insulating films 24 and 25 is preferably less than the thickness of the second oxide film 33. The thickness of the plurality of side wall insulating films 24 and 25 is preferably less than the thickness of the first oxide film 32. The thickness of the plurality of side wall insulating films 24 and 25 is preferably larger than the thickness of the gate insulating film 21. The thickness of the plurality of side wall insulating films 24 and 25 may be less than the thickness of the gate insulating film 21.

The thickness of the plurality of side wall insulating films 24 and 25 may be not less than 0.05 μm and not more than 0.5 μm. The thickness of the plurality of side wall insulating films 24 and 25 may have a value falling within at least one of ranges of not less than 0.05 μm and not more than 0.1 μm, not less than 0.1 μm and not more than 0.15 μm, not less than 0.15 μm and not more than 0.2 μm, not less than 0.2 μm and not more than 0.25 μm, not less than 0.25 μm and not more than 0.3 μm, not less than 0.3 μm and not more than 0.35 μm, not less than 0.35 μm and not more than 0.4 μm, not less than 0.4 μm and not more than 0.45 μm, and not less than 0.45 μm and not more than 0.5 μm. The thickness of the plurality of side wall insulating films 24 and 25 is preferably not less than 0.1 μm and not more than 0.3 μm.

The gate structure 20 controls inversion and non-inversion of the channel regions 17 and 18 in response to a gate potential applied to the gate electrode 22. When the gate potential is applied to the gate electrode 22, the channel regions 17 and 18 enter an ON state, and a drain current flows between the second semiconductor region 11 and the source regions 14 and 15 via the channel regions 17 and 18 (the body region 12). As described above, the transistor structure Tr of a planar gate type is formed in the inner portion (the active region 8) of the chip 2.

The semiconductor device 1A includes an outer body region 40 of the p-type formed in a surface layer portion of the first main surface 3 in the outer peripheral region 9. The outer body region 40 is formed in a surface layer portion of the second semiconductor region 11. The outer body region 40 has a p-type impurity concentration higher than the n-type impurity concentration of the second semiconductor region 11.

The outer body region 40 preferably has the p-type impurity concentration substantially equal to the p-type impurity concentration of the body region 12. The p-type impurity concentration of the outer body region 40 may be less than the p-type impurity concentration of the body region 12 or may be higher than the p-type impurity concentration of the body region 12.

The outer body region 40 is formed at an interval to the active region 8 side from the peripheral edges (the first to fourth side surfaces 5A to 5D) of the first main surface 3 and extends as a band along the active region 8. The outer body region 40 has a portion extending as a band in the first direction X and a portion extending as a band in the second direction Y in plan view and demarcates the plurality of body regions 12 (the active region 8) from a plurality of directions.

In this embodiment, the outer body region 40 collectively surrounds the plurality of body regions 12 (the active region 8) in plan view and is demarcated as a polygonal annular shape (a quadrangular annular shape in this embodiment) having four sides parallel to the peripheral edges of the first main surface 3.

That is, the outer body region 40 forms a boundary portion between the active region 8 and the outer peripheral region 9. The outer body region 40 may have an edge portion connecting, in a circular arc shape (preferably, a quadrant arc shape), the portion extending in the first direction X and the portion extending in the second direction Y in plan view (see FIG. 4).

The outer body region 40 is exposed from the first main surface 3. The outer body region 40 is formed at an interval to the first main surface 3 side from the bottom portion of the second semiconductor region 11 and faces (the first semiconductor region 10) with a portion of the second semiconductor region 11 interposed therebetween. The outer body region 40 is preferably formed at an interval to the first main surface 3 side from the intermediate portion of the second semiconductor region 11. The outer body region 40 may cross the depth position of the intermediate portion of the second semiconductor region 11 in the thickness direction.

The outer body region 40 has an inner edge portion on the active region 8 side and an outer edge portion on the peripheral edge side of the first main surface 3. The inner edge portion of the outer body region 40 is connected to the plurality of body regions 12 in the portion extending in the first direction X and demarcates each of the plurality of body regions 12 and the plurality of surface layer drift regions 13 in the surface layer portion of the second semiconductor region 11.

That is, the outer body region 40 is electrically connected to the plurality of body regions 12. Thereby, the source potential is applied to the outer body region 40 via the plurality of body regions 12. The outer body region 40 forms a pn junction portion with the second semiconductor region 11 and expands a depletion layer into the second semiconductor region 11 when a reverse bias voltage is applied.

The outer body region 40 is connected to the plurality of body regions 12 at intervals from the source regions 14 and 15 in the second direction Y. Therefore, the outer body region 40 does not have the source regions 14 and 15 in a surface layer portion thereof (see FIG. 5). Also, the outer body region 40 is connected to the plurality of body regions 12 at intervals from the contact regions 16 in the second direction Y. Therefore, the outer body region 40 does not have the contact regions 16 in the surface layer portion (see FIG. 5).

The outer body region 40 preferably has a width larger than the width of the body region 12. The width of the outer body region 40 is a width in a direction orthogonal to the extension direction. The width of the outer body region 40 may be substantially equal to the width of the body region 12 or may be less than the width of the body region 12.

A ratio of the width of the outer body region 40 to the width of the body region 12 may be not less than 1 and not more than 50. The ratio of the widths may have a value falling within at least one of ranges of not less than 1 and not more than 10, not less than 10 and not more than 20, not less than 20 and not more than 30, not less than 30 and not more than 40, and not less than 40 and not more than 50. The ratio of the widths is preferably not less than 10. The ratio of the widths is preferably not less than 20 and not more than 40.

The outer body region 40 preferably has a thickness (a depth) substantially equal to the thickness (the depth) of the body region 12. The thickness of the outer body region 40 may be less than the thickness of the body region 12 or may be larger than the thickness of the body region 12.

The semiconductor device 1A includes a terminal region 41 of the p-type formed in the first main surface 3 in the outer peripheral region 9. The terminal region 41 may be referred to as a “well region,” a “terminal well region,” etc. The terminal region 41 is formed in the surface layer portion of the second semiconductor region 11.

The terminal region 41 has a p-type impurity concentration different from the p-type impurity concentration of the body region 12. The p-type impurity concentration of the terminal region 41 is preferably higher than the p-type impurity concentration of the body region 12. The p-type impurity concentration of the terminal region 41 may be lower than the p-type impurity concentration of the body region 12. Also, the p-type impurity concentration of the terminal region 41 may be substantially equal to the p-type impurity concentration of the body region 12.

The terminal region 41 has the p-type impurity concentration different from the p-type impurity concentration of the outer body region 40. The p-type impurity concentration of the terminal region 41 is preferably higher than the p-type impurity concentration of the outer body region 40. The p-type impurity concentration of the terminal region 41 may be lower than the p-type impurity concentration of the outer body region 40. Also, the p-type impurity concentration of the terminal region 41 may be substantially equal to the p-type impurity concentration of the outer body region 40.

The terminal region 41 is formed in a region between the peripheral edges of the first main surface 3 and the outer body region 40 at intervals inward from the peripheral edges of the first main surface 3. The terminal region 41 extends as a band along the outer body region 40 in plan view. The terminal region 41 has a portion extending as a band in the first direction X and a portion extending as a band in the second direction Y in plan view and demarcates the active region 8 from a plurality of directions.

In this embodiment, the terminal region 41 surrounds the outer body region 40 (the active region 8 and the plurality of body regions 12) in plan view and is demarcated as a polygonal annular shape (a quadrangular annular shape in this embodiment) having four sides parallel to the peripheral edges of the first main surface 3. The terminal region 41 may have an edge portion connecting, in a circular arc shape (preferably, a quadrant arc shape), the portion extending in the first direction X and the portion extending in the second direction Y in plan view (see FIG. 4).

The terminal region 41 is formed at an interval to the first main surface 3 side from a bottom portion of the second semiconductor region 11 and faces the first semiconductor region 10 with a portion of the second semiconductor region 11 interposed therebetween. The terminal region 41 is preferably formed at an interval to the first main surface 3 side from the intermediate portion of the second semiconductor region 11.

The terminal region 41 may cross the depth position of the intermediate portion of the second semiconductor region 11 in the thickness direction. The terminal region 41 may have a thickness (a depth) substantially equal to the thickness (the depth) of the outer body region 40. The thickness of the terminal region 41 may be larger than the thickness of the outer body region 40 or may be smaller than the thickness of the outer body region 40.

The terminal region 41 has an inner edge portion on the active region 8 side and an outer edge portion on the peripheral edge side of the first main surface 3. The inner edge portion of the terminal region 41 is connected to the outer edge portion of the outer body region 40 in the surface layer portion of the second semiconductor region 11.

Thereby, the terminal region 41 is electrically connected to the outer body region 40 and is electrically connected to the plurality of body regions 12 via the outer body region 40. The terminal region 41 forms a pn junction portion with the second semiconductor region 11 and expands a depletion layer into the second semiconductor region 11 when a reverse bias voltage is applied.

In this embodiment, the inner edge portion of the terminal region 41 is connected to the outer edge portion of the outer body region 40 along the entire periphery thereof. In a case where the terminal region 41 has the p-type impurity concentration substantially equal to the p-type impurity concentration of the outer body region 40, the terminal region 41 may be regarded as a portion (a lead-out portion) of the outer body region 40.

The terminal region 41 (the inner edge portion) has an overlap region 42 overlapping the outer edge portion of the outer body region 40 in the surface layer portion of the second semiconductor region 11. The overlap region 42 is a high-concentration region including the outer edge portion of the outer body region 40 and the inner edge portion of the terminal region 41. That is, the overlap region 42 contains both a p-type impurity of the outer body region 40 and a p-type impurity of the terminal region 41 and has a p-type impurity concentration higher than both the p-type impurity concentration of the outer body region 40 and the p-type impurity concentration of the terminal region 41.

The p-type impurity concentration of the overlap region 42 is preferably higher than the p-type impurity concentration of the body region 12. The p-type impurity concentration of the overlap region 42 may be less than the p-type impurity concentration of the contact region 16. The p-type impurity concentration of the overlap region 42 may be higher than the p-type impurity concentration of the contact region 16.

The overlap region 42 extends as a band along the outer body region 40 in plan view. The overlap region 42 has a portion extending as a band in the first direction X and a portion extending as a band in the second direction Y in plan view and demarcates the active region 8 from a plurality of directions. In this embodiment, the overlap region 42 is demarcated as a polygonal annular shape (a quadrangular annular shape in this embodiment) having four sides parallel to the peripheral edges of the first main surface 3.

The overlap region 42 may have an edge portion connecting, in a circular arc shape (preferably, a quadrant arc shape), the portion extending in the first direction X and the portion extending in the second direction Y in plan view (see FIG. 4). A width of the overlap region 42 is preferably larger than the width of the body region 12. The width of the overlap region 42 may be less than the width of the body region 12.

The semiconductor device 1A may have a well region (42) of the p-type having a relatively high concentration instead of the overlap region 42. In this case, the well region (42) has a p-type impurity concentration higher than both the p-type impurity concentration of the outer body region 40 and the p-type impurity concentration of the terminal region 41.

The p-type impurity concentration of the well region (42) is preferably higher than the p-type impurity concentration of the body region 12. The p-type impurity concentration of the well region (42) may be substantially equal to the p-type impurity concentration of the contact region 16. The p-type impurity concentration of the well region (42) may be less than the p-type impurity concentration of the contact region 16 or may be higher than the p-type impurity concentration of the contact region 16.

The well region (42) may be formed in either or both of the surface layer portion of the outer body region 40 and the surface layer portion of the terminal region 41. The well region (42) is effective in a case where the terminal region 41 has a p-type impurity concentration substantially equal to the p-type impurity concentration of the outer body region 40 and is formed as a portion (the lead-out portion) of the outer body region 40.

The semiconductor device 1A includes at least one field region 43 of the p-type which is formed in the surface layer portion of the first main surface 3 in the outer peripheral region 9. A plurality of the field regions 43 may be formed in an electrically floating state. The plurality of field regions 43 may be fixed to the source potential.

The number of the field regions 43 is arbitrary. The number of the field regions 43 may be not less than 1 and not more than 20. The number of the field regions 43 may have a value falling within at least one of ranges of not less than 1 and not more than 5, not less than 5 and not more than 10, not less than 10 and not more than 15, and not less than 15 and not more than 20. The number of the field regions 43 is typically not less than 1 and not more than 8. In this embodiment, the semiconductor device 1A includes three field regions 43.

The plurality of field regions 43 are formed in the surface layer portion of the second semiconductor region 11. The plurality of field regions 43 are formed in a region between the peripheral edges of the first main surface 3 and the plurality of body regions 12 (the active region 8) at intervals inward from the peripheral edges of the first main surface 3.

Specifically, the plurality of field regions 43 are formed in a region between the peripheral edges of the first main surface 3 and the outer body region 40. More specifically, in a region between the peripheral edges of the first main surface 3 and the terminal region 41, the plurality of field regions 43 are aligned at an interval to the peripheral edge side of the first main surface 3 from the outer edge portion of the terminal region 41.

The plurality of field regions 43 are formed as bands extending along the plurality of body regions 12 (the terminal region 41) in plan view. Each of the plurality of field regions 43 has a portion extending as a band in the first direction X and a portion extending as a band in the second direction Y.

In this embodiment, the plurality of field regions 43 are each formed in a polygonal annular shape (a quadrangular annular shape in this embodiment) surrounding the plurality of body regions 12 (the terminal regions 41) in plan view. Each of the plurality of field regions 43 may have an edge portion connecting, in a circular arc shape (preferably, a quadrant arc shape), the portion extending in the first direction X and the portion extending in the second direction Y (see FIG. 4).

The plurality of field regions 43 are formed at an interval to on the first main surface 3 side from the depth position of the bottom portion of the second semiconductor region 11. The plurality of field regions 43 are preferably formed at an interval to the first main surface 3 side from the depth position of the intermediate portion of the second semiconductor region 11. The plurality of field regions 43 may cross the depth position of the intermediate portion of the second semiconductor region 11 in the thickness direction. The plurality of field regions 43 respectively form pn junction portions with the second semiconductor region 11 and expand a depletion layer into the second semiconductor region 11 when a reverse bias voltage is applied.

Widths, depths, intervals, p-type impurity concentrations, etc., of the plurality of field regions 43 are arbitrary and can have various values depending on an electric field to be relaxed. The widths of the plurality of field regions 43 may be substantially constant or may be non-uniform. The widths of the plurality of field regions 43 may gradually increase toward the peripheral edges of the first main surface 3. The widths of the plurality of field regions 43 may gradually decrease toward the peripheral edges of the first main surface 3.

The depths of the plurality of field regions 43 may be substantially constant or may be non-uniform. The depths of the plurality of field regions 43 may gradually increase toward the peripheral edges of the first main surface 3. The depths of the plurality of field regions 43 may gradually decrease toward the peripheral edges of the first main surface 3.

The plurality of field regions 43 may have a relatively shallow portion and a deep portion deeper than the shallow portion. The shallow portion may be formed on the inner side, and the deep portion may be formed on the peripheral edge side. The shallow portion may be formed on the peripheral edge side, and the deep portion may be formed on the inner side.

The intervals between the plurality of field regions 43 may be substantially constant or may be non-uniform. The intervals between the plurality of field regions 43 may gradually increase toward the peripheral edges of the first main surface 3. The intervals between the plurality of field regions 43 may gradually decrease toward the peripheral edges of the first main surface 3.

The p-type impurity concentrations of the plurality of field regions 43 may be substantially constant or may be non-uniform. The p-type impurity concentrations of the plurality of field regions 43 may gradually increase toward the peripheral edges of the first main surface 3. The p-type impurity concentration of the plurality of field regions 43 may gradually decrease toward the peripheral edges of the first main surface 3.

The plurality of field regions 43 may have p-type impurity concentrations substantially equal to the p-type impurity concentration of the body region 12. The p-type impurity concentrations of the plurality of field regions 43 may be higher than the p-type impurity concentration of the body region 12 or may be lower than the p-type impurity concentration of the body region 12.

The p-type impurity concentrations of the plurality of field regions 43 may be substantially equal to the p-type impurity concentration of the outer body region 40. The p-type impurity concentrations of the plurality of field regions 43 may be higher than the p-type impurity concentration of the outer body region 40 or may be lower than the p-type impurity concentration of the outer body region 40.

The p-type impurity concentrations of the plurality of field regions 43 may be substantially equal to the p-type impurity concentration of the terminal region 41. The p-type impurity concentrations of the plurality of field regions 43 may be higher than the p-type impurity concentration of the terminal region 41 or may be lower than the p-type impurity concentration of the terminal region 41.

The semiconductor device 1A includes a main surface insulating film 44 covering the first main surface 3 in the outer peripheral region 9. The main surface insulating film 44 may include at least one among a silicon oxide film, a silicon nitride film, and a silicon oxynitride film. In this embodiment, the main surface insulating film 44 has a single layer structure constituted of the silicon oxide film.

The main surface insulating film 44 preferably includes the silicon oxide film constituted of the oxide of the chip 2. The main surface insulating film 44 is preferably constituted of the same type of insulating material as an insulating material of the gate insulating film 21. The main surface insulating film 44 preferably has a thickness substantially equal to the thickness of the gate insulating film 21.

The main surface insulating film 44 covers the first main surface 3 in a film shape in the outer peripheral region 9. The main surface insulating film 44 collectively covers the second semiconductor region 11, the outer body region 40, the terminal region 41, and the plurality of field regions 43. The main surface insulating film 44 is connected to a plurality of the gate insulating films 21 on the active region 8 side. Specifically, the main surface insulating film 44 is integrally formed with the plurality of gate insulating films 21 and forms one insulating film with the plurality of gate insulating films 21.

The semiconductor device 1A includes a wiring structure 50 of a planar type arranged on the first main surface 3 in the outer peripheral region 9. The wiring structure 50 is selectively routed around on the first main surface 3 in a layout different from a layout of the plurality of gate structures 20 in the outer peripheral region 9 and is connected to the plurality of gate structures 20 on the active region 8 side. The wiring structure 50 may be referred to as a “gate wiring structure.” The wiring structure 50 applies a gate potential to the plurality of gate structures 20.

The wiring structure 50 includes the main surface insulating film 44 described above, a gate wiring 51, a second planar insulating film 52, and a plurality of third side wall insulating films 53. The gate wiring 51 may be referred to as a “second gate electrode,” etc. The gate wiring 51 may contain either or both of a conductive polysilicon of the p-type and a conductive polysilicon of the n-type. The gate wiring 51 preferably has the same conductivity type as the conductivity type of the gate electrode 22.

The gate wiring 51 is arranged on the main surface insulating film 44 at an interval to the active region 8 side from the peripheral edges of the first main surface 3 in the outer peripheral region 9. In this embodiment, the gate wiring 51 is arranged at an interval to the active region 8 side from the terminal region 41 and is arranged on a portion of the main surface insulating film 44 covering the outer body region 40. That is, the gate wiring 51 faces the outer body region 40 with the main surface insulating film 44 interposed therebetween. The gate wiring 51 may face the terminal region 41 in the lamination direction.

The gate wiring 51 has a portion extending in a direction different from a plurality of the gate electrodes 22. The gate wiring 51 has a portion extending as a band in the first direction X and a portion extending as a band in the second direction Y in plan view and demarcates the plurality of gate electrodes 22 (the active region 8) from a plurality of directions.

In this embodiment, the gate wiring 51 surrounds the plurality of gate electrodes 22 (the active region 8) in plan view and is demarcated as a polygonal annular shape (a quadrangular annular shape in this embodiment) having four sides parallel to the peripheral edges of the first main surface 3. The gate wiring 51 may have a shape with ends or may be an endless shape.

In this embodiment, the gate wiring 51 extends as a band (an annular band in this embodiment) along the outer body region 40 in plan view and faces the outer body region 40 with the main surface insulating film 44 interposed therebetween in the entire region in the lamination direction. The gate wiring 51 may have an edge portion connecting, in a circular arc shape (preferably, a quadrant arc shape), the portion extending in the first direction X and the portion extending in the second direction Y in plan view (see FIG. 4).

In this embodiment, the gate wiring 51 has a width less than the width of the outer body region 40 in plan view and is arranged on the outer body region 40 at intervals from the inner edge portion and the outer edge portion of the outer body region 40. That is, in this embodiment, the plurality of gate electrodes 22 are led out onto the outer body region 40, and the gate wiring 51 is connected to the plurality of gate electrodes 22 on the outer body region 40. The width of the gate wiring 51 may be larger than the width of the outer body region 40.

The width of the gate wiring 51 is preferably larger than the width of the gate electrode 22. The width of the gate wiring 51 is a width in a direction orthogonal to the extension direction. The width of the gate wiring 51 may be not more than the width of the gate electrode 22. For example, a ratio of the width of the gate wiring 51 to the width of the gate electrode 22 may be not less than 0.5 and not more than 50.

The ratio of the widths may have a value falling within at least one of ranges of not less than 0.5 and not more than 1, not less than 1 and not more than 10, not less than 10 and not more than 20, not less than 20 and not more than 30, not less than 30 and not more than 40, and not less than 40 and not more than 50. The ratio of the widths may be not less than 5. The ratio of the widths may be not less than 20 and not more than 40.

The gate wiring 51 includes a wiring surface 54, a first wiring side wall 55 on an inner edge side, and a second wiring side wall 56 on an outer edge side. The wiring surface 54 extends flatly along the main surface insulating film 44 (the first main surface 3). The wiring surface 54 may extend substantially parallel to the main surface insulating film 44 (the first main surface 3).

The first wiring side wall 55 extends in the vertical direction Z on the main surface insulating film 44. The first wiring side wall 55 is connected to the plurality of gate electrodes 22 (the first side wall 27 and the second side wall 28) in the portion extending in the first direction X.

That is, the gate wiring 51 has a plurality of portions connected to the plurality of gate electrodes 22 in a T-shape and is electrically connected to the plurality of gate electrodes 22. The second wiring side wall 56 extends in the vertical direction Z on the main surface insulating film 44. The second wiring side wall 56 is formed as an open end in the outer peripheral region 9.

The first wiring side wall 55 and the second wiring side wall 56 may extend perpendicularly to the main surface insulating film 44. That is, the gate wiring 51 may be formed in a quadrangular shape (a flat rectangular shape) in cross-sectional view. The first wiring side wall 55 and the second wiring side wall 56 may be inclined obliquely toward the wiring surface 54. That is, the gate wiring 51 may be formed in a tapered shape (preferably, an isosceles trapezoidal shape) in cross-sectional view.

The gate wiring 51 preferably has a thickness substantially equal to the thickness of the gate electrode 22. The thickness of the gate wiring 51 may be larger than the thickness of the gate electrode 22 or may be less than the thickness of the gate electrode 22.

The gate wiring 51 may have a thickness of not less than 1 μm and not more than 10 μm. The thickness of the gate wiring 51 may have a value falling within at least one of ranges of not less than 1 μm and not more than 2.5 μm, not less than 2.5 μm and not more than 5 μm, not less than 5 μm and not more than 7.5 μm, and not less than 7.5 μm and not more than 10 μm. The thickness of the gate wiring 51 is preferably not less than 1 μm and not more than 5 μm.

The second planar insulating film 52 is arranged on the gate wiring 51 and covers the wiring surface 54 in a film shape. The second planar insulating film 52 exposes the first wiring side wall 55 of the gate wiring 51 and covers the second wiring side wall 56 of the gate wiring 51. The second planar insulating film 52 directly covers the wiring surface 54 and the second wiring side wall 56 along the entire gate wiring 51 and exposes the first wiring side wall 55.

The second planar insulating film 52 is connected to the first planar insulating films 23 at connection portions between the plurality of gate electrodes 22 and the gate wiring 51. That is, the second planar insulating film 52 has a plurality of portions connected to the plurality of first planar insulating films 23 in a T-shape. The second planar insulating film 52 has an arcuate corner portion curved in a circular arc shape in a covering portion with respect to a corner portion on the second wiring side wall 56 side.

The second planar insulating film 52 has a second insulating surface 57 and a third insulating side wall 58 on the first wiring side wall 55 side. The second insulating surface 57 extends flatly along the wiring surface 54. The second insulating surface 57 may extend substantially parallel to the wiring surface 54.

The third insulating side wall 58 extends in the vertical direction Z on the gate wiring 51 and is connected to the first wiring side wall 55 of the gate wiring 51. The third insulating side wall 58 is connected to the first insulating side walls 30 and the second insulating side walls 31 of the plurality of first planar insulating films 23 at the connection portions between the plurality of gate electrodes 22 and the gate wiring 51. That is, the third insulating side wall 58 has a portion connected to the first side wall insulating film 24 in an L-shape and a portion connected to the second side wall insulating film 25 in an L-shape.

The third insulating side wall 58 may be formed to be flush with the first wiring side wall 55. The third insulating side wall 58 may be positioned further to the active region 8 side than the first wiring side wall 55 is, and may face the main surface insulating film 44 in the lamination direction.

The third insulating side wall 58 may be positioned on the wiring surface 54 at an interval from the first wiring side wall 55 and may expose a peripheral edge portion of the wiring surface 54. In this case, the third insulating side wall 58 may be connected to the first wiring side wall 55 via the peripheral edge portion of the wiring surface 54. The third insulating side wall 58 may extend substantially perpendicular to the main surface insulating film 44. The third insulating side wall 58 may be inclined obliquely toward the second insulating surface 57.

The second planar insulating film 52 preferably has a thickness substantially equal to the thickness of the first planar insulating film 23. The thickness of the second planar insulating film 52 may be larger than the thickness of the first planar insulating film 23 or may be less than the thickness of the first planar insulating film 23.

The thickness of the second planar insulating film 52 may be not less than 0.1 μm and not more than 2 μm. The thickness of the second planar insulating film 52 may have a value falling within at least one of ranges of not less than 0.1 μm and not more than 0.5 μm, not less than 0.5 μm and not more than 1 μm, not less than 1 μm and not more than 1.5 μm, and not less than 1.5 μm and not more than 2 μm. The thickness of the second planar insulating film 52 is preferably not less than 0.2 μm.

The second planar insulating film 52 may include at least one among a silicon oxide film, a silicon nitride film, and a silicon oxynitride film. The second planar insulating film 52 may have a single layer structure constituted of a single insulating film. The second planar insulating film 52 may have a laminated structure including a plurality of insulating films.

In this embodiment, similarly to the first planar insulating film 23, the second planar insulating film 52 has the laminated structure including a first oxide film 59 (a first insulating film) and a second oxide film 60 (a second insulating film) laminated in that order from the gate wiring 51 side.

The first oxide film 59 has a single layer structure constituted of an NSG film. The first oxide film 59 directly covers the wiring surface 54 and the second wiring side wall 56 of the gate wiring 51 in a film shape and exposes the first wiring side wall 55 of the gate wiring 51. The first oxide film 59 forms a portion of the third insulating side wall 58 on the gate wiring 51.

The first oxide film 59 extends flatly in the horizontal direction in a covering portion with respect to the wiring surface 54. The first oxide film 59 is connected to a plurality of the first oxide films 32 at the connection portions between the plurality of gate electrodes 22 and the gate wiring 51. That is, the first oxide film 59 has a plurality of portions connected to the plurality of first oxide films 32 in a T-shape.

The first oxide film 59 extends in the vertical direction Z in a covering portion with respect to the second wiring side wall 56. The first oxide film 59 preferably extends at an inclination angle substantially equal to an inclination angle of the second wiring side wall 56 in a covering portion with respect to the second wiring side wall 56. A film surface of the first oxide film 59 preferably has a portion extending substantially parallel to the second wiring side wall 56. The first oxide film 59 preferably has an arcuate corner portion curved in a circular arc shape in a covering portion with respect to a corner portion of the gate wiring 51 on the second wiring side wall 56 side.

The first oxide film 59 preferably has a thickness substantially equal to the thickness of the first oxide film 32 of the first planar insulating film 23. The thickness of the first oxide film 59 may be larger than the thickness of the first oxide film 32 or may be less than the thickness of the first oxide film 32.

The first oxide film 59 may have a thickness of not less than 0.01 μm and not more than 0.2 μm. The thickness of the first oxide film 59 may have a value falling within at least one of ranges of not less than 0.01 μm and not more than 0.05 μm, not less than 0.05 μm and not more than 0.1 μm, not less than 0.1 μm and not more than 0.15 μm, and not less than 0.15 μm and not more than 0.2 μm. The thickness of the first oxide film 59 is preferably not less than 0.05 μm.

The second oxide film 60 may have a single layer structure or a laminated structure including either or both of the PSG film and the BPSG film. The second oxide film 60 may have a laminated structure including the PSG film laminated on the first oxide film 59, and the BPSG film laminated on the PSG film. The second oxide film 60 may have a laminated structure including the BPSG film laminated on the first oxide film 59, and the PSG film laminated on the BPSG film. In this embodiment, the second oxide film 60 has, as an example, a single layer structure constituted of the PSG film.

The second oxide film 60 directly covers the first oxide film 59 in a film shape. The second oxide film 60 covers the wiring surface 54 and the second wiring side wall 56 in a film shape across the first oxide film 59 and exposes the first wiring side wall 55 of the gate wiring 51.

The second oxide film 60 extends flatly in the horizontal direction in the covering portion with respect to the wiring surface 54 and forms a portion of the third insulating side wall 58 on the first oxide film 59. The second oxide film 60 is connected to a plurality of the second oxide films 33 at the connection portions between the plurality of gate electrodes 22 and the gate wiring 51. That is, the second oxide film 60 has a plurality of portions connected to the plurality of second oxide films 33 in a T-shape.

The second oxide film 60 extends in the vertical direction Z in a covering portion with respect to the second wiring side wall 56. The second oxide film 60 preferably extends at an inclination angle substantially equal to the inclination angle of the second wiring side wall 56 in a covering portion with respect to the second wiring side wall 56. A film surface of the second oxide film 60 preferably has a portion extending substantially parallel to the second wiring side wall 56. The second oxide film 60 preferably has an arcuate corner portion curved in a circular arc shape in a covering portion with respect to a corner portion of the gate wiring 51 on the second wiring side wall 56 side.

The second oxide film 60 preferably has a thickness larger than the thickness of the first oxide film 59. The thickness of the second oxide film 60 may be less than the thickness of the first oxide film 59. The second oxide film 60 preferably has a thickness substantially equal to the thickness of the second oxide film 33 of the first planar insulating film 23. The thickness of the second oxide film 60 may be larger than the thickness of the second oxide film 33 or may be less than the thickness of the second oxide film 33.

The thickness of the second oxide film 60 may be not less than 0.05 μm and not more than 1.8 μm. The thickness of the second oxide film 60 may have a value falling within at least one of ranges of not less than 0.05 μm and not more than 0.1 μm, not less than 0.1 μm and not more than 0.5 μm, not less than 0.5 μm and not more than 1 μm, not less than 1 μm and not more than 1.5 μm, and not less than 1.5 μm and not more than 1.8 μm. The thickness of the second oxide film 60 is preferably not less than 0.1 μm.

The second oxide film 60 enhances the flatness of the second planar insulating film 52 (that is, the film formability of the second planar insulating film 52 with respect to the wiring surface 54). Fluctuations in electrical characteristics of the gate wiring 51 due to the impurity diffusion in the second oxide film 60 are prevented by the undoped first oxide film 59. Fluctuations in insulation characteristics of the second oxide film 60 due to the impurity diffusion in the gate wiring 51 are prevented by the undoped first oxide film 59.

Each of the plurality of third side wall insulating films 53 covers the first wiring side wall 55 of the gate wiring 51. Specifically, the plurality of third side wall insulating films 53 cover portions of the first wiring side wall 55 other than the connection portions between the plurality of gate electrodes 22 and the gate wiring 51. Hereinafter, an arrangement of one of the third side wall insulating films 53 shall be described.

The third side wall insulating film 53 covers the first wiring side wall 55 on the main surface insulating film 44 and faces a portion of the outer body region 40 with the main surface insulating film 44 interposed therebetween. The third side wall insulating film 53 is formed at an interval to the gate wiring 51 side from the plurality of source regions 14 and 15 and the contact region 16. The third side wall insulating film 53 does not have a portion facing the plurality of source regions 14 and 15 and the contact region 16.

In this embodiment, the third side wall insulating film 53 is led out from the first wiring side wall 55 toward the third insulating side wall 58 of the second planar insulating film 52 and covers the third insulating side wall 58. That is, the third side wall insulating film 53 has a portion covering the first wiring side wall 55 and a portion covering the third insulating side wall 58. Also, the third side wall insulating film 53 has a portion covering a boundary portion between the gate wiring 51 and the second planar insulating film 52.

The third side wall insulating film 53 covers the first wiring side wall 55 and the third insulating side wall 58 in a film shape conforming to an inclination angle of the first wiring side wall 55 and an inclination angle of the third insulating side wall 58. The third side wall insulating film 53 has a film surface extending at an inclination angle substantially equal to the inclination angle of the first wiring side wall 55 in a covering portion with respect to the first wiring side wall 55 and extending substantially parallel to the first wiring side wall 55. The third side wall insulating film 53 has a film surface extending at an inclination angle substantially equal to the inclination angle of the third insulating side wall 58 in a covering portion with respect to the third insulating side wall 58 and extending substantially parallel to the third insulating side wall 58.

In this embodiment, the third side wall insulating film 53 extends substantially vertically in a region between the main surface insulating film 44 (the first main surface 3) and the second insulating surface 57. That is, the third side wall insulating film 53 has a film surface extending in the vertical direction Z in the covering portion with respect to the first wiring side wall 55 and has a film surface extending in the vertical direction Z in the covering portion with respect to the third insulating side wall 58.

The third side wall insulating film 53 covers both the first oxide film 59 and the second oxide film 60 on the third insulating side wall 58 side. Also, the third side wall insulating film 53 has a portion covering a boundary portion between the first oxide film 59 and the second oxide film 60. The third side wall insulating film 53 is formed on the first main surface 3 side with respect to the second insulating surface 57 and exposes the second insulating surface 57. That is, the third side wall insulating film 53 exposes the second oxide film 60 from the second insulating surface 57.

The third side wall insulating film 53 is connected to the plurality of side wall insulating films 24 and 25 at connection portions between the gate electrodes 22 and the gate wiring 51. That is, the third side wall insulating film 53 has a portion connected to the first side wall insulating film 24 in an L-shape and a portion connected to the second side wall insulating film 25 in an L-shape.

The third side wall insulating film 53 may include at least one among a silicon oxide film, a silicon nitride film, and a silicon oxynitride film. The third side wall insulating film 53 may have a single layer structure constituted of a single insulating film. The third side wall insulating film 53 may have a laminated structure including a plurality of insulating films.

The third side wall insulating film 53 is preferably constituted of the same type of insulating material as an insulating material of the plurality of side wall insulating films 24 and 25. In this embodiment, the third side wall insulating film 53 has a single layer structure constituted of the NSG film. In this embodiment, each of the third side wall insulating films 53 is constituted of the TEOS film as an example of the NSG film.

In a case where the third side wall insulating film 53 is constituted of the NSG film, fluctuations in electrical characteristics of the gate wiring 51 (the gate electrode 22) due to the impurity diffusion in the second oxide film 60 (the second oxide film 33) are prevented by the third side wall insulating film 53. Also, fluctuations in insulation characteristics of the second oxide film 60 (the second oxide film 33) due to the impurity diffusion in the gate wiring 51 (the gate electrode 22) are prevented by the third side wall insulating film 53.

The third side wall insulating film 53 preferably has a thickness substantially equal to the thickness of the plurality of side wall insulating films 24 and 25. The thickness of the third side wall insulating film 53 is a thickness of the third side wall insulating film 53 in the horizontal direction with the first wiring side wall 55 as a reference.

Each of the third side wall insulating films 53 has a thickness less than the thickness of the gate wiring 51. The thickness of the third side wall insulating film 53 is less than the thickness (a total thickness) of the second planar insulating film 52. The thickness of the third side wall insulating film 53 is less than the thickness of the gate electrode 22. The thickness of the third side wall insulating film 53 is less than the thickness (the total thickness) of the first planar insulating film 23.

The thickness of the third side wall insulating film 53 is preferably less than the thickness of the second oxide film 60 (the second oxide film 33). The thickness of the third side wall insulating film 53 is preferably less than the thickness of the first oxide film 59 (the first oxide film 32). The thickness of the third side wall insulating film 53 is preferably larger than the thickness of the gate insulating film 21. The thickness of the third side wall insulating film 53 may be less than the thickness of the gate insulating film 21.

Preferably, the thickness of the third side wall insulating film 53 is substantially equal to the thickness of the side wall insulating film 24, 25. The thickness of the third side wall insulating film 53 may be larger than the thickness of the side wall insulating film 24, 25 or may be less than the thickness of the side wall insulating film 24, 25. The thickness of the third side wall insulating film 53 may be not less than 0.1 μm and not more than 0.5 μm.

The thickness of the third side wall insulating film 53 may have a value falling within at least one of ranges of not less than 0.1 μm and not more than 0.15 μm, not less than 0.15 μm and not more than 0.2 μm, not less than 0.2 μm and not more than 0.25 μm, not less than 0.25 μm and not more than 0.3 μm, not less than 0.3 μm and not more than 0.35 μm, not less than 0.35 μm and not more than 0.4 μm, not less than 0.4 μm and not more than 0.45 μm, and not less than 0.45 μm and not more than 0.5 μm. The thickness of the third side wall insulating film 53 is preferably not less than 0.15 μm and not more than 0.25 μm.

The semiconductor device 1A includes an outer insulating film 61 covering the main surface insulating film 44 in the outer peripheral region 9. The outer insulating film 61 is formed in a region between the peripheral edges of the chip 2 and the gate structures 20 (the gate wiring 51) in the outer peripheral region 9 and covers the outer body region 40, the terminal region 41, and the plurality of field regions 43 across the main surface insulating film 44.

The outer insulating film 61 is continuous to the first to fourth side surfaces 5A to 5D on the peripheral edge side of the chip 2. The outer insulating film 61 may be formed at intervals inward from the first to fourth side surfaces 5A to 5D and may expose the peripheral edge portions (the second semiconductor region 11) of the first main surface 3. The outer insulating film 61 is connected to the second planar insulating film 52 on the wiring structure 50 side.

Specifically, similarly to the second planar insulating film 52, the outer insulating film 61 has a laminated structure including the first oxide film 59 and the second oxide film 60 and is integrally formed with the second planar insulating film 52. The outer insulating film 61 may be regarded as a lead-out portion of the second planar insulating film 52 which is led out from the covering portion with respect to the gate wiring 51 to the peripheral edge side of the chip 2.

The semiconductor device 1A includes a plurality of source openings 65 respectively demarcated in regions between the plurality of gate structures 20 on the active region 8 side. In this embodiment, the plurality of source openings 65 are formed at intervals in the first direction X in accordance with the array of the plurality of gate structures 20 and are each formed as a band extending in the second direction Y. That is, the plurality of source openings 65 are formed as stripes extending in the second direction Y.

The plurality of source openings 65 are respectively demarcated in regions surrounded by the plurality of gate structures 20 and the wiring structure 50. Specifically, the plurality of source openings 65 are each demarcated by the first side wall insulating film 24 of one of the gate structures 20 and the second side wall insulating film 25 of the other gate structure 20 in the first direction X. Each of the plurality of source openings 65 has both end portions demarcated by the third side wall insulating films 53 of the wiring structure 50 in the second direction Y.

The plurality of source openings 65 are respectively demarcated directly above the plurality of body regions 12, and penetrate the plurality of gate insulating films 21 and the main surface insulating film 44. That is, the plurality of source openings 65 expose the plurality of gate insulating films 21 and the main surface insulating film 44 at lower end portions thereof. Each of the plurality of source openings 65 exposes a portion of the first main surface 3 (the chip 2).

Specifically, each of the plurality of source openings 65 exposes the plurality of source regions 14 and 15 and the contact region 16 formed in the corresponding body region 12. In this embodiment, the plurality of source openings 65 respectively expose the both end portions of the body region 12.

Each of the plurality of source openings 65 has an opening width W of not less than the thickness of the plurality of side wall insulating films 24 and 25 in the first direction X. The opening width W is also a distance between the plurality of gate structures 20. The opening width W is preferably larger than the thickness of the plurality of side wall insulating films 24 and 25. The opening width W is preferably not more than the width of the gate electrode 22. The width of the source opening 65 is particularly preferably less than the width of the gate electrode 22.

The opening width W may be not less than 0.2 μm and not more than 0.6 μm. The opening width W may have a value falling within at least one of ranges of not less than 0.2 μm and not more than 0.25 μm, not less than 0.25 μm and not more than 0.3 μm, not less than 0.3 μm and not more than 0.35 μm, not less than 0.35 μm and not more than 0.4 μm, not less than 0.4 μm and not more than 0.45 μm, not less than 0.45 μm and not more than 0.5 μm, not less than 0.5 μm and not more than 0.55 μm, and not less than 0.55 μm and not more than 0.6 μm. The opening width W is preferably not less than 0.25 μm and not more than 0.45 μm.

The source opening 65 may have an opening depth D of not less than 0.1 μm and not more than 2 μm. The opening depth D may have a value falling within at least one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm. The opening depth D is preferably not less than 0.5 μm and not more than 1 μm.

The source opening 65 preferably has an aspect ratio D/W of not less than 0.5 and not more than 3. The aspect ratio D/W is defined by a ratio of the opening depth D to the opening width W. The aspect ratio D/W may have a value falling within at least one of ranges of not less than 0.5 and not more than 0.75, not less than 0.75 and not more than 1, not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3.

The semiconductor device 1A includes a plurality of source recesses 66 respectively formed in portions of first main surface 3 exposed from the plurality of source openings 65. The plurality of source recesses 66 may be regarded as one component of the first main surface 3. The semiconductor device 1A does not necessarily have to have the source recesses 66. Therefore, an arrangement not having the source recesses 66 may be adopted.

Each of the plurality of source recesses 66 has a planar shape matching a planar shape of the corresponding source opening 65 and is recessed from the first main surface 3 toward the second main surface 4. The plurality of source recesses 66 are formed at an interval to the first main surface 3 side from the bottom portions of the corresponding body regions 12 and respectively expose the plurality of corresponding source regions 14 and 15 and the corresponding contact regions 16.

Specifically, the plurality of source recesses 66 are formed at an interval to the first main surface 3 side from the bottom portions of the plurality of corresponding source regions 14 and 15 (the contact regions 16). In this embodiment, the plurality of source recesses 66 respectively expose the both end portions of the body region 12.

The semiconductor device 1A includes at least one outer opening 67 (in this embodiment, a plurality of outer openings 67) formed in the outer insulating film 61 in the outer peripheral region 9. The plurality of outer openings 67 are formed in portions of the outer insulating film 61 which cover the terminal region 41.

The plurality of outer openings 67 penetrate the outer insulating film 61 and expose the terminal region 41. In this embodiment, the plurality of outer openings 67 are formed in the portions of the outer insulating film 61 which cover the overlap region 42 of the terminal region 41 and expose the overlap region 42.

The plurality of outer openings 67 may expose either or both of the outer body region 40 and the terminal region 41, instead of or in addition to the terminal region 41 (the overlap region 42).

The plurality of outer openings 67 have wall surfaces that penetrate both the first oxide film 59 and the second oxide film 60 and are demarcated by both the first oxide film 59 and the second oxide film 60. Each of the plurality of outer openings 67 has an opening end demarcated by an arcuate corner portion of the outer insulating film 61.

The plurality of outer openings 67 are formed at intervals along the terminal region 41 (the overlap region 42) (see FIG. 4 and FIG. 5). The plurality of outer openings 67 may be formed in a quadrangular shape (a square shape), a rectangular shape, a hexagonal shape, a circular shape, etc., in plan view. The plurality of outer openings 67 may be formed as bands extending along the terminal region 41 (the overlap region 42) in plan view. The outer opening 67 may have an aspect ratio of not less than 0.5 and not more than 3 (preferably, larger than 1).

The semiconductor device 1A may have the single outer opening 67. The single outer opening 67 may be formed as a band extending along the terminal region 41 (the overlap region 42). The single outer opening 67 may have a portion extending as a band in the first direction X and a portion extending as a band in the second direction Y in plan view.

The single outer opening 67 may be formed in a polygonal annular shape with ends or an endless polygonal annular shape (a quadrangular annular shape in this embodiment) having four sides parallel to the peripheral edges of the first main surface 3. The single outer opening 67 may have an edge portion connecting, in a circular arc shape (preferably, a quadrant arc shape), the portion extending in the first direction X and the portion extending in the second direction Y by conforming to the terminal region 41 (the overlap region 42) in plan view (see FIG. 4).

The semiconductor device 1A includes a plurality of outer recesses 68 respectively formed in portions of the first main surface 3 exposed from the plurality of outer openings 67. The plurality of outer recesses 68 may be regarded as one component of the first main surface 3. The semiconductor device 1A does not necessarily have to have the outer recesses 68. Therefore, an arrangement not having the outer recesses 68 may be adopted.

Each of the plurality of outer recesses 68 has a planar shape matching a planar shape of the corresponding outer opening 67 and is recessed from the first main surface 3 toward the second main surface 4. The plurality of outer recesses 68 are formed at an interval to the first main surface 3 side from the bottom portion of the terminal region 41 (the overlap region 42) and respectively expose the terminal region 41 (the overlap region 42).

The outer recess 68 may have a depth substantially equal to the depth of the source recess 66. In a case where the single outer opening 67 is formed, the single outer recess 68 matching the planar shape of the single outer opening 67 is formed.

The semiconductor device 1A includes at least one gate opening 69 (in this embodiment, a plurality of gate openings 69) formed in the second planar insulating film 52 in the outer peripheral region 9. The plurality of gate openings 69 penetrate the second planar insulating film 52 and expose the gate wiring 51. The plurality of gate openings 69 are formed at intervals along the gate wiring 51 (see FIG. 4 and FIG. 5).

The plurality of gate openings 69 have wall surfaces that penetrate both the first oxide film 59 and the second oxide film 60 and are demarcated by both the first oxide film 59 and the second oxide film 60. Each of the plurality of gate openings 69 may have an opening end demarcated by an arcuate corner portion of the second planar insulating film 52.

The plurality of gate openings 69 may be formed in a quadrangular shape (a square shape), a rectangular shape, a hexagonal shape, a circular shape, etc., in plan view. The plurality of gate openings 69 may be formed as bands extending along the gate wiring 51 in plan view. The gate opening 69 may have an aspect ratio of not less than 0.5 and not more than 3 (preferably, larger than 1).

The semiconductor device 1A may have the single gate opening 69. The single gate opening 69 may be formed as a band extending along the gate wiring 51. The single gate opening 69 may have a portion extending as a band in the first direction X and a portion extending as a band in the second direction Y in plan view.

The single gate opening 69 may be formed in a polygonal annular shape with ends or an endless polygonal annular shape (a quadrangular annular shape in this embodiment) having four sides parallel to the peripheral edges of the first main surface 3. The single gate opening 69 may have an edge portion connecting, in a circular arc shape (preferably, a quadrant arc shape), the portion extending in the first direction X and the portion extending in the second direction Y by conforming to the gate wiring 51 in plan view (see FIG. 4).

With reference to FIG. 1, etc., the semiconductor device 1A includes a source main electrode 70 arranged on the plurality of gate structures 20. The source main electrode 70 is a terminal electrode to which a source potential is applied from the exterior. The source main electrode 70 may be referred to as a “first main electrode,” a “first terminal electrode,” a “first pad electrode,” etc.

The source main electrode 70 collectively covers the plurality of gate structures 20 in the active region 8. The source main electrode 70 covers the plurality of gate electrodes 22 across the plurality of first planar insulating films 23 and is electrically disconnected from the plurality of gate electrodes 22 by the plurality of first planar insulating films 23.

The source main electrode 70 has a peripheral edge portion covering the wiring structure 50 in a film shape. The peripheral edge portion of the source main electrode 70 covers the gate wiring 51 across the second planar insulating film 52 and is electrically disconnected from the gate wiring 51 by the second planar insulating film 52. The source main electrode 70 enters the plurality of source openings 65 from above the plurality of gate structures 20 and the wiring structure 50.

The source main electrode 70 is mechanically connected to a plurality of the first side wall insulating films 24, a plurality of the second side wall insulating films 25, and the plurality of third side wall insulating films 53 in the plurality of source openings 65 and is electrically connected to the first main surface 3 in the plurality of source openings 65. Specifically, the source main electrode 70 is electrically connected to the plurality of body regions 12, the plurality of source regions 14 and 15, the plurality of contact regions 16, etc., in the plurality of source openings 65.

The source main electrode 70 includes a first pad portion 70a, a second pad portion 70b, and a third pad portion 70c in plan view. The first pad portion 70a has a relatively large plane area and forms a main body of the source main electrode 70.

In this embodiment, the first pad portion 70a is unevenly distributed on the fourth side surface 5D side with respect to a central portion of the active region 8 in plan view and is formed in a polygonal shape (a quadrangular shape in this embodiment) having four sides parallel to the peripheral edges of the chip 2. The first pad portion 70a is electrically disconnected from the plurality of gate electrodes 22 by the plurality of first planar insulating films 23 and is electrically connected to the plurality of body regions 12, etc., via the plurality of source openings 65.

The second pad portion 70b has a plane area less than the plane area of the first pad portion 70a and is led out as a band (in a quadrangular shape) from one end portion (an end portion on the first side surface 5A side) of the first pad portion 70a in the second direction Y toward the third side surface 5C. The second pad portion 70b is electrically disconnected from the plurality of gate electrodes 22 by the plurality of first planar insulating films 23 and is electrically connected to the plurality of body regions 12, etc., via the plurality of source openings 65.

The third pad portion 70c has a plane area less than the plane area of the first pad portion 70a, is led out as a band (in a quadrangular shape) from the other end portion (an end portion on the second side surface 5B side) of the first pad portion 70a in the second direction Y toward the third side surface 5C, and faces the second pad portion 70b in the second direction Y. The third pad portion 70c is electrically disconnected from the plurality of gate electrodes 22 by the plurality of first planar insulating films 23 and is electrically connected to the plurality of body regions 12, etc., via the plurality of source openings 65.

The plane area of the third pad portion 70c may be substantially equal to the plane area of the second pad portion 70b. The plane area of the third pad portion 70c may be larger than the plane area of the second pad portion 70b or may be less than the plane area of the second pad portion 70b. Either or both of the second pad portion 70b and the third pad portion 70c may be used as a terminal portion for current monitoring.

The source main electrode 70 does not necessarily have to have both the second pad portion 70b and the third pad portion 70c simultaneously. The source main electrode 70 may include just one of either of the second pad portion 70b and the third pad portion 70c. The source main electrode 70 may be constituted of just the first pad portion 70a and does not have to have the second pad portion 70b and the third pad portion 70c.

With reference to FIG. 6 and FIG. 7, the source main electrode 70 includes a first lower electrode film 71, a plurality of first embedded electrodes 72, and a first upper electrode film 73. The first lower electrode film 71 may be referred to as a “first lower electrode.”

The first upper electrode film 73 may be referred to as a “first upper electrode.” The first lower electrode film 71 forms a lower layer portion of the source main electrode 70 (the first pad portion 70a, the second pad portion 70b, and the third pad portion 70c) and collectively covers the plurality of gate structures 20 in a film shape in the active region 8.

In this embodiment, the first lower electrode film 71 has a laminated structure including a first electrode film 74 laminated on the plurality of gate structures 20 and a second electrode film 75 laminated on the first electrode film 74. In this embodiment, the first electrode film 74 includes a Ti film, and the second electrode film 75 includes a TiN film. The first lower electrode film 71 does not necessarily have to have the laminated structure and may have a single layer structure constituted of one of either of the first electrode film 74 (the Ti film) and the second electrode film 75 (the TiN film).

The first electrode film 74 directly and collectively covers the plurality of gate structures 20 in a film shape in the active region 8. The first electrode film 74 covers the plurality of gate electrodes 22 across the plurality of first planar insulating films 23 and is electrically disconnected from the plurality of gate electrodes 22 by the plurality of first planar insulating films 23. The first electrode film 74 has a peripheral edge portion directly covering the wiring structure 50 in a film shape. The peripheral edge portion of the first electrode film 74 covers the gate wiring 51 across the second planar insulating film 52 and is electrically disconnected from the gate wiring 51 by the second planar insulating film 52.

The first electrode film 74 has a portion directly covering the first insulating surface 29 and the second insulating surface 57 in a film shape and enters the plurality of source openings 65 from above the first insulating surface 29 and the second insulating surface 57. The first electrode film 74 directly covers the first main surface 3, the plurality of first side wall insulating films 24, the plurality of second side wall insulating films 25, and the plurality of third side wall insulating films 53 in a film shape in the plurality of source openings 65. Hereinafter, an arrangement of the first electrode film 74 in one of the source openings 65 shall be described.

The first electrode film 74 extends along the plurality of side wall insulating films 24 and 25 and faces the plurality of gate electrodes 22 and the plurality of first planar insulating films 23 with the plurality of side wall insulating films 24 and 25 interposed therebetween. In this embodiment, the first electrode film 74 faces the first oxide film 32 and the second oxide film 33 with the plurality of side wall insulating films 24 and 25 interposed therebetween.

The first electrode film 74 preferably has a film surface extending at an inclination angle substantially equal to the inclination angle of the plurality of side wall insulating films 24 and 25 in covering portions with respect to the plurality of side wall insulating films 24 and 25 and extending substantially parallel to the plurality of side wall insulating films 24 and 25. The first electrode film 74 extends along the third side wall insulating film 53 and faces the gate wiring 51 and the second planar insulating film 52 with the third side wall insulating film 53 interposed therebetween.

In this embodiment, the first electrode film 74 faces the first oxide film 59 and the second oxide film 60 with the third side wall insulating film 53 interposed therebetween. The first electrode film 74 preferably has a film surface extending at an inclination angle substantially equal to the inclination angle of the third side wall insulating film 53 in a covering portion with respect to the third side wall insulating film 53 and extending substantially parallel to the third side wall insulating film 53.

The first electrode film 74 covers the first main surface 3 in a film shape at a bottom portion of the source opening 65 and is electrically connected to the first main surface 3. Specifically, the first electrode film 74 has a portion covering the source recess 66 in a film shape at the bottom portion of the source opening 65 and is electrically connected to the body regions 12, the plurality of source regions 14 and 15, and the contact regions 16.

The first electrode film 74 may cover the source recess 66 in a film shape at an interval to the bottom portion side of the source recess 66 from a height position of the first main surface 3. The first electrode film 74 may have a portion positioned on the bottom portion side of the source recess 66 with respect to the height position of the first main surface 3, and a portion positioned on the gate insulating film 21 side with respect to the height position of the first main surface 3.

The first electrode film 74 has a thickness less than the thickness of the gate electrode 22 (the gate wiring 51). The thickness of the first electrode film 74 is less than the thickness (the total thickness) of the first planar insulating film 23 (the second planar insulating film 52). The thickness of the first electrode film 74 may be less than the thickness of the second oxide film 33 (the second oxide film 60). The thickness of the first electrode film 74 may be less than the thickness of the first oxide film 32 (the first oxide film 59).

The thickness of the first electrode film 74 may be less than the thickness of the side wall insulating film 24, 25. The thickness of the first electrode film 74 may be larger than the thickness of the side wall insulating film 24, 25. The thickness of the first electrode film 74 is preferably larger than the thickness of the gate insulating film 21. The thickness of the first electrode film 74 may be less than the thickness of the gate insulating film 21.

The thickness of the first electrode film 74 may be not less than 10 nm and not more than 100 nm. The thickness of the first electrode film 74 may have a value falling within at least one of ranges of not less than 10 nm and not more than 25 nm, not less than 25 nm and not more than 50 nm, not less than 50 nm and not more than 75 nm, and not less than 75 nm and not more than 100 nm.

The second electrode film 75 collectively covers the plurality of gate structures 20 in a film shape across the first electrode film 74 in the active region 8. The second electrode film 75 covers the plurality of first planar insulating films 23 in a film shape across the first electrode film 74. The second electrode film 75 has a peripheral edge portion covering the wiring structure 50 in a film shape across the first electrode film 74. The peripheral edge portion of the second electrode film 75 covers the second planar insulating film 52 (the gate wiring 51) across the peripheral edge portion of the first electrode film 74.

The second electrode film 75 has a portion covering the first insulating surface 29 and the second insulating surface 57 in a film shape across the first electrode film 74 and enters the plurality of source openings 65 from above the first insulating surface 29 and the second insulating surface 57.

The second electrode film 75 covers the first main surface 3, the plurality of first side wall insulating films 24, the plurality of second side wall insulating films 25, and the plurality of third side wall insulating films 53 in a film shape across the first electrode film 74 in the plurality of source openings 65. Hereinafter, an arrangement of the second electrode film 75 in one of the source openings 65 shall be described.

The second electrode film 75 extends along the first electrode film 74 in covering portions with respect to the plurality of side wall insulating films 24 and 25 and faces the plurality of gate electrodes 22 and the plurality of first planar insulating films 23 with the plurality of side wall insulating films 24 and 25 and the first electrode film 74 interposed therebetween. In this embodiment, the second electrode film 75 faces the first oxide film 32 and the second oxide film 33 with the plurality of side wall insulating films 24 and 25 and the first electrode film 74 interposed therebetween.

The second electrode film 75 extends along the first electrode film 74 in a covering portion with respect to the third side wall insulating film 53 and faces the gate wiring 51 and the second planar insulating film 52 with the third side wall insulating film 53 and the first electrode film 74 interposed therebetween. In this embodiment, the second electrode film 75 faces the first oxide film 59 and the second oxide film 60 with the third side wall insulating film 53 and the first electrode film 74 interposed therebetween.

The second electrode film 75 preferably has a film surface extending at an inclination angle substantially equal to the inclination angle of the plurality of side wall insulating films 24 and 25 in covering portions with respect to the plurality of side wall insulating films 24 and 25 and extending substantially parallel to the plurality of side wall insulating films 24 and 25. The second electrode film 75 preferably has a film surface extending at an inclination angle substantially equal to the inclination angle of the third side wall insulating film 53 in a covering portion with respect to the third side wall insulating film 53 and extending substantially parallel to the third side wall insulating film 53.

The second electrode film 75 covers the first main surface 3 in a film shape across the first electrode film 74 at the bottom portion of the source opening 65 and is electrically connected to the first main surface 3 via the first electrode film 74. Specifically, the second electrode film 75 has a portion covering the source recess 66 in a film shape across the first electrode film 74 and is electrically connected to the body regions 12, the plurality of source regions 14 and 15, and the contact regions 16 via the first electrode film 74.

In a case where the first electrode film 74 is positioned on the bottom portion side of the source recess 66 with respect to the first main surface 3, the second electrode film 75 may have a portion positioned in the source recess 66. In a case where the first electrode film 74 has a portion positioned higher than the first main surface 3, the entire second electrode film 75 is positioned above the source recess 66.

The second electrode film 75 has a thickness less than the thickness of the gate electrode 22 (the gate wiring 51). The thickness of the second electrode film 75 is less than the thickness (the total thickness) of the second planar insulating film 52 (the first planar insulating film 23). The thickness of the second electrode film 75 may be less than the thickness of the second oxide film 33 (the second oxide film 60). The thickness of the second electrode film 75 may be less than the thickness of the first oxide film 32 (the first oxide film 59).

The thickness of the second electrode film 75 may be less than the thickness of the side wall insulating film 24, 25. The thickness of the second electrode film 75 may be larger than the thickness of the side wall insulating film 24, 25. The thickness of the second electrode film 75 is preferably larger than the thickness of the gate insulating film 21. The thickness of the second electrode film 75 may be less than the thickness of the gate insulating film 21. The thickness of the second electrode film 75 is preferably larger than the thickness of the first electrode film 74. The thickness of the second electrode film 75 may be less than the thickness of the first electrode film 74.

The thickness of the second electrode film 75 may be not less than 50 nm and not more than 200 nm. The thickness of the second electrode film 75 may have a value falling within at least one of ranges of not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The plurality of first embedded electrodes 72 form a middle layer portion of the source main electrode 70 (the first pad portion 70a, the second pad portion 70b, and the third pad portion 70c) and respectively are embedded in the plurality of source openings 65. The first embedded electrode 72 contains a conductive material different from a conductive material of the first lower electrode film 71. The first embedded electrode 72 contains at least one among tungsten, molybdenum, a tungsten alloy, and a molybdenum alloy. In this embodiment, the first embedded electrode 72 contains tungsten.

In this embodiment, the plurality of first embedded electrodes 72 are embedded in the plurality of source openings 65 in one-to-one correspondence via the single first lower electrode film 71. The plurality of first embedded electrodes 72 are electrically connected to the first main surface 3 (the chip 2) via the first lower electrode film 71 in the plurality of source openings 65. Specifically, the plurality of first embedded electrodes 72 are electrically connected to the plurality of body regions 12, the plurality of source regions 14 and 15, and the contact region 16. Hereinafter, an arrangement of one of the first embedded electrodes 72 shall be described.

The first embedded electrode 72 is embedded in the source opening 65 at an interval to the first main surface 3 side from the first insulating surface 29 and the second insulating surface 57 and exposes portions of the first lower electrode film 71 (the second electrode film 75) which cover the first insulating surface 29 and the second insulating surface 57. That is, the first embedded electrode 72 does not have a portion facing the electrode surface 26 of the gate electrode 22 with the first insulating surface 29 interposed therebetween. Also, the first embedded electrode 72 does not have a portion facing the wiring surface 54 of the gate wiring 51 with the second insulating surface 57 interposed therebetween.

The first embedded electrode 72 faces the plurality of gate electrodes 22 and the plurality of first planar insulating films 23 in the horizontal direction with the plurality of side wall insulating films 24 and 25 interposed therebetween. In this embodiment, the first embedded electrode 72 faces the first oxide film 32 and the second oxide film 33 in the horizontal direction with the plurality of side wall insulating films 24 and 25 interposed therebetween.

The first embedded electrode 72 faces the gate wiring 51 and the second planar insulating film 52 in the horizontal direction with the third side wall insulating film 53 interposed therebetween. In this embodiment, the first embedded electrode 72 faces the first oxide film 59 and the second oxide film 60 in the horizontal direction with the plurality of side wall insulating films 24 and 25 interposed therebetween. The first embedded electrode 72 faces the plurality of source regions 14 and 15 and the contact region 16 in the lamination direction with the first lower electrode film 71 interposed therebetween and is electrically connected to the plurality of source regions 14 and 15 and the contact region 16 via the first lower electrode film 71.

In a case where the first lower electrode film 71 is positioned on the bottom portion side of the source recess 66 with respect to the first main surface 3, the first embedded electrode 72 may have a portion positioned in the source recess 66. In a case where the first lower electrode film 71 has a portion positioned higher than the first main surface 3, the entire first embedded electrode 72 is positioned above the source recess 66.

The first embedded electrode 72 has a first embedded electrode surface 76 exposed from the source opening 65. The first embedded electrode surface 76 is positioned further to the first insulating surface 29 side than a height position of the electrode surface 26 of the gate electrode 22.

The first embedded electrode 72 is preferably positioned further to the first insulating surface 29 side than a height position of the first oxide film 32. The first embedded electrode surface 76 is positioned further to the second insulating surface 57 side than a height position of the wiring surface 54 of the gate wiring 51. The first embedded electrode 72 is preferably positioned further to the second insulating surface 57 side than a height position of the first oxide film 59.

The first embedded electrode surface 76 has a recess recessed toward the first main surface 3 (the chip 2) at a central portion thereof. A bottom portion of the recess is preferably positioned on the first insulating surface 29 (the second insulating surface 57) side with respect to the height position of the electrode surface 26 (the wiring surface 54).

The bottom portion of the recess is preferably positioned further to the first insulating surface 29 side than the height position of the first oxide film 32 (the first oxide film 59). The bottom portion of the recess may be positioned further to the first main surface 3 side than the height position of the first oxide film 32 (the first oxide film 59). Also, the bottom portion of the recess may be positioned further to the first main surface 3 side than the height position of the electrode surface 26 (the wiring surface 54).

The first upper electrode film 73 forms an upper layer portion of the source main electrode 70 (the first pad portion 70a, the second pad portion 70b, and the third pad portion 70c) and covers the first lower electrode film 71 and the plurality of first embedded electrodes 72 in a film shape.

The first upper electrode film 73 contains a conductive material different from the conductive material of the first lower electrode film 71 and the conductive material of the first embedded electrode 72. The first upper electrode film 73 may include at least one among an Al film, an Al alloy film, a Cu film, and a Cu alloy film. The first upper electrode film 73 may include at least one of an AlSi alloy film, an AlCu alloy film, and an AlSiCu alloy film.

The first upper electrode film 73 collectively covers the plurality of gate structures 20 in a film shape across the first lower electrode film 71 in the active region 8. The first upper electrode film 73 is mechanically and electrically connected to the first lower electrode film 71 in portions covering the first insulating surface 29 and the second insulating surface 57.

Specifically, the first upper electrode film 73 covers the plurality of first planar insulating films 23 in a film shape across the first lower electrode film 71. The first upper electrode film 73 has a peripheral edge portion covering the wiring structure 50 in a film shape across the first lower electrode film 71. The peripheral edge portion of the first upper electrode film 73 covers the second planar insulating film 52 (the gate wiring 51) across the peripheral edge portion of the first lower electrode film 71.

The first upper electrode film 73 is mechanically and electrically connected to the plurality of first embedded electrodes 72 in portions covering the plurality of source openings 65. Thereby, the first upper electrode film 73 is electrically connected to the plurality of body regions 12, the plurality of source regions 14 and 15, the contact region 16, etc., via both the first lower electrode film 71 and the plurality of first embedded electrodes 72.

The first upper electrode film 73 is connected to the first embedded electrode 72 (the first embedded electrode surface 76) at a height position on the first main surface 3 side with respect to the height positions of the first insulating surface 29 and the second insulating surface 57 and faces the first planar insulating film 23 in the horizontal direction with the plurality of side wall insulating films 24 and 25 interposed therebetween. Also, the first upper electrode film 73 faces the second planar insulating film 52 in the horizontal direction with the third side wall insulating film 53 interposed therebetween.

The first upper electrode film 73 backfills the recess of the first embedded electrode surface 76 in a covering portion with respect to the first embedded electrode 72. In this embodiment, the first upper electrode film 73 is connected to the first embedded electrode surface 76 at a position higher than the electrode surface 26 and does not have a portion facing the gate electrode 22 in the horizontal direction.

In this embodiment, the first upper electrode film 73 is connected to the first embedded electrode surface 76 at a position higher than the height position of the first oxide film 32. In a case where the first embedded electrode surface 76 has a portion positioned below the height position of the electrode surface 26, the first upper electrode film 73 may have a portion facing the gate electrode 22 in the horizontal direction.

The first upper electrode film 73 has a thickness larger than the thickness (a total thickness) of the first lower electrode film 71. The thickness of the first upper electrode film 73 is larger than both the thickness of the gate electrode 22 and the thickness of the gate wiring 51. The thickness of the first upper electrode film 73 is larger than the thickness of the first embedded electrode 72. The thickness of the first upper electrode film 73 is larger than both the thickness of the first planar insulating film 23 and the thickness of the second planar insulating film 52.

The thickness of the first upper electrode film 73 may be not less than 0.5 μm and not more than 5 μm. The thickness of the first upper electrode film 73 may have a value falling within at least one of ranges of not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 am, and not less than 4.5 μm and not more than 5 μm.

The semiconductor device 1A includes a source finger electrode 80 led out from the source main electrode 70 onto the outer peripheral region 9. The source finger electrode 80 transmits, to the outer peripheral region 9, the source potential applied to the source main electrode 70. In this embodiment, the source finger electrode 80 is led out from a portion of the source main electrode 70 (the first pad portion 70a) on the fourth side surface 5D side onto the outer peripheral region 9.

The source finger electrode 80 is led out from the source main electrode 70 via the wiring structure 50 onto the outer insulating film 61. The source finger electrode 80 is led out to a region of the outer insulating film 61 in which the plurality of outer openings 67 are formed and is electrically connected to the terminal region 41 in the plurality of outer openings 67. Specifically, the source finger electrode 80 is electrically connected to the overlap region 42 of the terminal region 41 via the plurality of outer openings 67.

The source finger electrode 80 extends as a band along the terminal region 41 (the overlap region 42). The source finger electrode 80 has a portion extending as a band in the first direction X and a portion extending as a band in the second direction Y in plan view.

In this embodiment, the source finger electrode 80 is formed in a polygonal annular shape (a quadrangular annular shape in this embodiment) having four sides parallel to the peripheral edge of the first main surface 3 and surrounds the source main electrode 70. The source finger electrode 80 may have an edge portion connecting, in a circular arc shape (preferably, a quadrant arc shape), the portion extending in the first direction X and the portion extending in the second direction Y in plan view (see FIG. 4).

Similarly to the source main electrode 70, the source finger electrode 80 includes the first lower electrode film 71, the plurality of first embedded electrodes 72, and the first upper electrode film 73. Similarly to the source main electrode 70, the first lower electrode film 71 has the laminated structure including the first electrode film 74 and the second electrode film 75. The first lower electrode film 71 forms a lower layer portion of the source finger electrode 80 and covers the outer insulating film 61 in the outer peripheral region 9.

The first lower electrode film 71 collectively covers, in a film shape, a region of the outer insulating film 61 in which the plurality of outer openings 67 are formed and enters the plurality of outer openings 67 from above the first insulating surface 29.

The first lower electrode film 71 covers the first main surface 3 in a film shape at a bottom portion of each of the outer openings 67 and is electrically connected to the first main surface 3 (the chip 2). Specifically, first lower electrode film 71 has portions covering the outer recesses 68 in a film shape at the bottom portion of each of the outer openings 67 and is electrically connected to the terminal region 41 (the overlap region 42) in the outer recesses 68.

The first lower electrode film 71 may cover the outer recess 68 in a film shape at an interval to the bottom portion side of the outer recess 68 from the height position of the first main surface 3. The first lower electrode film 71 may have a portion positioned on the bottom portion side of the outer recess 68 with respect to the height position of the first main surface 3, and a portion positioned on the main surface insulating film 44 side with respect to the height position of the first main surface 3.

The plurality of first embedded electrodes 72 form a middle layer portion of the source finger electrode 80 and are respectively embedded in the plurality of outer openings 67. In this embodiment, the plurality of first embedded electrodes 72 are embedded in the plurality of outer openings 67 in one-to-one correspondence via the single first lower electrode film 71. The plurality of first embedded electrodes 72 are electrically connected to the terminal region 41 (the overlap region 42) via the first lower electrode film 71.

The first embedded electrodes 72 are embedded in the outer openings 67 at an interval to the first main surface 3 side from an insulating surface of the outer insulating film 61 and expose a portion of the first lower electrode film 71 (the second electrode film 75) covering the insulating surface of the outer insulating film 61. The first embedded electrode 72 faces the first oxide film 59 and the second oxide film 60 in the horizontal direction with the first lower electrode film 71 interposed therebetween. The first embedded electrode 72 faces the terminal region 41 (the overlap region 42) in the lamination direction with the first lower electrode film 71 interposed therebetween.

The first embedded electrode 72 has the first embedded electrode surface 76 exposed from the outer opening 67. The first embedded electrode surface 76 is positioned further to the insulating surface side of the outer insulating film 61 than the height position of the first oxide film 59 in the outer opening 67. The first embedded electrode surface 76 may be positioned further to the first main surface 3 side than the height position of the first oxide film 59.

In a case where the first lower electrode film 71 is positioned on the bottom portion side of the outer recess 68 with respect to the first main surface 3, the first embedded electrode 72 may have a portion positioned in the outer recess 68. In a case where the first lower electrode film 71 has a portion positioned higher than the first main surface 3, the entire first embedded electrode 72 is positioned above the outer recess 68.

The first upper electrode film 73 forms an upper layer portion of the source finger electrode 80 and covers the first lower electrode film 71 and the plurality of first embedded electrodes 72 in a film shape. The first upper electrode film 73 is mechanically and electrically connected to the first lower electrode film 71 in a portion covering the insulating surface of the outer insulating film 61 and is mechanically and electrically connected to the plurality of first embedded electrodes 72 in portions covering the plurality of outer openings 67. The first upper electrode film 73 is electrically connected to the terminal region 41 (the overlap region 42) via the first lower electrode film 71 and the plurality of first embedded electrodes 72.

The first upper electrode film 73 is connected to the first embedded electrode surface 76 at a height position on the first main surface 3 side with respect to a height position of the insulating surface of the outer insulating film 61. The first upper electrode film 73 is connected to the first embedded electrode surface 76 at a position higher than the height position of the first oxide film 59. In a case where the first embedded electrode 72 is embedded below the height position of the first oxide film 59, the first upper electrode film 73 may be connected to the first embedded electrode surface 76 below the height position of the first oxide film 59.

The semiconductor device 1A includes a plurality of first silicide portions 81 respectively formed in surface portions of portions of the first main surface 3 exposed from the plurality of source openings 65. The first silicide portion 81 may contain at least one among titanium silicide, nickel silicide, cobalt silicide, molybdenum silicide, tungsten silicide, and vanadium silicide. The first silicide portion 81 is preferably constituted of titanium silicide, nickel silicide, or cobalt silicide.

In this embodiment, the plurality of first silicide portions 81 are respectively formed in a film shape along wall surfaces (side walls and bottom walls) of the plurality of source recesses 66 in the surface layer portions of the plurality of body regions 12 and are mechanically and electrically connected to the source main electrode 70.

The plurality of first silicide portions 81 are formed at an interval to the first main surface 3 side from the bottom portions of the plurality of source regions 14 and 15 and the bottom portions of the plurality of contact regions 16. The plurality of first silicide portions 81 electrically connect the source main electrode 70 to the plurality of body regions 12, the plurality of source regions 14 and 15, and the plurality of contact regions 16.

The semiconductor device 1A includes a plurality of second silicide portions 82 respectively formed in surface portions of portions of the first main surface 3 exposed from the plurality of outer openings 67. The second silicide portion 82 may contain at least one among titanium silicide, nickel silicide, cobalt silicide, molybdenum silicide, tungsten silicide, and vanadium silicide. The second silicide portion 82 is preferably constituted of titanium silicide, nickel silicide, or cobalt silicide. The second silicide portion 82 is particularly preferably constituted of the same type of silicide as that of the first silicide portion 81.

In this embodiment, the plurality of second silicide portions 82 are formed in a film shape along wall surfaces (side walls and bottom walls) of the plurality of outer recesses 68 in the surface layer portion of the terminal region 41 (the overlap region 42) and are mechanically and electrically connected to the source finger electrode 80.

The plurality of second silicide portions 82 are formed at an interval to the first main surface 3 side from the bottom portion of the terminal region 41 (the overlap region 42). That is, the plurality of second silicide portions 82 electrically connect the source finger electrode 80 to the terminal region 41 (overlap region 42).

The semiconductor device 1A includes agate finger electrode 83 selectively routed around on the outer peripheral region 9. The gate finger electrode 83 is provided in a region between the source main electrode 70 and the source finger electrode 80 and is arranged on the wiring structure 50 at intervals from the source main electrode 70 and the source finger electrode 80.

The gate finger electrode 83 extends as a band along the wiring structure 50. The gate finger electrode 83 has a portion extending as a band in the first direction X and a portion extending as a band in the second direction Y in plan view. In this embodiment, the gate finger electrode 83 is formed in a polygonal annular shape (a quadrangular annular shape in this embodiment) having four sides parallel to the peripheral edge of the first main surface 3 and surrounds the source main electrode 70. The gate finger electrode 83 has a pair of open ends through which the source finger electrode 80 passes on the fourth side surface 5D side.

The gate finger electrode 83 may have an edge portion connecting, in a circular arc shape (preferably, a quadrant arc shape), the portion extending in the first direction X and the portion extending in the second direction Y in plan view (see FIG. 4). The gate finger electrode 83 enters the plurality of gate openings 69 from above the second planar insulating film 52 and is electrically connected to the gate wiring 51.

The gate finger electrode 83 has a width less than the width of the gate wiring 51 and is arranged on the gate wiring 51 at intervals from the first wiring side wall 55 and the second wiring side wall 56 of the gate wiring 51.

That is, the gate finger electrode 83 is formed at an interval to the peripheral edge side of the chip 2 from the third side wall insulating film 53. The width of the gate finger electrode 83 may be larger than the width of the gate wiring 51. In this case, the gate finger electrode 83 may have a portion led out further to the peripheral edge side of the chip 2 than the second wiring side wall 56 of the gate wiring 51.

With reference to FIG. 8 and FIG. 9, the gate finger electrode 83 includes a second lower electrode film 84, at least one second embedded electrode 85 (in this embodiment, a plurality of second embedded electrodes 85), and a second upper electrode film 86. The second lower electrode film 84 may be referred to as a “second lower electrode.” The second upper electrode film 86 may be referred to as a “second upper electrode.” The second lower electrode film 84 forms a lower layer portion of the gate finger electrode 83 and covers the wiring structure 50 in a film shape in the outer peripheral region 9.

In this embodiment, the second lower electrode film 84 has a laminated structure including a first electrode film 87 laminated on the wiring structure 50 and a second electrode film 88 laminated on the first electrode film 87. In this embodiment, the first electrode film 87 includes a Ti film, and the second electrode film 88 includes a TiN film. The second lower electrode film 84 does not necessarily have to have the laminated structure and may have a single layer structure constituted of one of either of the first electrode film 87 (the Ti film) and the second electrode film 88 (the TiN film).

The first electrode film 87 directly covers the wiring structure 50 in a film shape in the outer peripheral region 9. The first electrode film 87 has a portion directly covering the second insulating surface 57 of the second planar insulating film 52 in a film shape and enters the plurality of gate openings 69 from above the second insulating surface 57. The first electrode film 87 extends in a film shape along wall surfaces of the plurality of gate openings 69 and directly covers the first oxide film 59 and the second oxide film 60. The first electrode film 87 covers the wiring surface 54 in a film shape and is electrically connected to the gate wiring 51.

The first electrode film 87 has a thickness less than the thickness of the gate wiring 51 (the gate electrode 22). The thickness of the first electrode film 87 is less than the thickness (the total thickness) of the second planar insulating film 52 (the first planar insulating film 23). The thickness of the first electrode film 87 may be less than the thickness of the second oxide film 60 (the second oxide film 33). The thickness of the first electrode film 87 may be less than the thickness of the first oxide film 59 (the first oxide film 32).

The thickness of the first electrode film 87 may be less than the thickness of the side wall insulating film 24, 25. The thickness of the first electrode film 87 may be larger than the thickness of the side wall insulating film 24, 25. The thickness of the first electrode film 87 is preferably larger than the thickness of the gate insulating film 21. The thickness of the first electrode film 87 may be less than the thickness of the gate insulating film 21. Preferably, the thickness of the first electrode film 87 is substantially equal to the thickness of the first electrode film 74 on the source side.

The thickness of the first electrode film 87 may be not less than 10 nm and not more than 100 nm. The thickness of the first electrode film 87 may have a value falling within at least one of ranges of not less than 10 nm and not more than 25 nm, not less than 25 nm and not more than 50 nm, not less than 50 nm and not more than 75 nm, and not less than 75 nm and not more than 100 nm.

The second electrode film 88 covers the wiring structure 50 in a film shape across the first electrode film 87 in the outer peripheral region 9. The second electrode film 88 has a portion covering the second insulating surface 57 of the second planar insulating film 52 in a film shape across the first electrode film 87 and enters the plurality of gate openings 69 from above the second insulating surface 57.

The second electrode film 88 extends in a film shape along wall surfaces of the plurality of gate openings 69 and covers the first oxide film 59 and the second oxide film 60 across the first electrode film 87. The second electrode film 88 covers the wiring surface 54 in a film shape across the first electrode film 87 and is electrically connected to the gate wiring 51 via the first electrode film 87.

The second electrode film 88 has a thickness less than the thickness of the gate electrode 22 (the gate wiring 51). The thickness of the second electrode film 88 is less than the thickness (the total thickness) of the second planar insulating film 52 (the first planar insulating film 23). The thickness of the second electrode film 88 may be less than the thickness of the second oxide film 33 (the second oxide film 60). The thickness of the second electrode film 88 may be less than the thickness of the first oxide film 32 (the first oxide film 59).

The thickness of the second electrode film 88 may be less than the thickness of the side wall insulating film 24, 25. The thickness of the second electrode film 88 may be larger than the thickness of the side wall insulating film 24, 25. The thickness of the second electrode film 88 is preferably larger than the thickness of the gate insulating film 21. The thickness of the second electrode film 88 may be less than the thickness of the gate insulating film 21.

The thickness of the second electrode film 88 is preferably larger than the thickness of the first electrode film 87. The thickness of the second electrode film 88 may be less than the thickness of the first electrode film 87. Preferably, the thickness of the second electrode film 88 is substantially equal to the thickness of the second electrode film 75 on the source side.

The thickness of the second electrode film 88 may be not less than 50 nm and not more than 200 nm. The thickness of the second electrode film 75 may have a value falling within at least one of ranges of not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The plurality of second embedded electrodes 85 form a middle layer portion of the gate finger electrode 83 and are respectively embedded in the plurality of gate openings 69. The second embedded electrode 85 contains a conductive material different from a conductive material of the second lower electrode film 84.

The second embedded electrode 85 contains at least one among tungsten, molybdenum, a tungsten alloy, and a molybdenum alloy. The second embedded electrode 85 preferably contains the same type of conductive material as the conductive material of the first embedded electrode 72 on the source side. In this embodiment, the second embedded electrode 85 contains tungsten.

In this embodiment, the plurality of second embedded electrodes 85 are embedded in the plurality of gate openings 69 in one-to-one correspondence via the single second lower electrode film 84. The plurality of second embedded electrodes 85 are electrically connected to the gate wiring 51 via the second lower electrode film 84 in the plurality of gate openings 69.

The second embedded electrodes 85 are embedded in the gate openings 69 at an interval to the gate wiring 51 side from the second insulating surface 57 of the second planar insulating film 52 and expose a portion of the second lower electrode film 84 (the second electrode film 88) covering the second insulating surface 57. That is, the second embedded electrode 85 does not have a portion facing the wiring surface 54 of the gate wiring 51 with the second planar insulating film 52 in the lamination direction (the vertical direction Z) interposed therebetween.

The second embedded electrodes 85 cover the second planar insulating film 52 across the second lower electrode film 84. In this embodiment, the second embedded electrodes 85 cover the first oxide film 59 and the second oxide film 60 across the second lower electrode film 84.

The second embedded electrode 85 has a second embedded electrode surface 89 exposed from the gate opening 69. The second embedded electrode surface 89 is positioned further to the first insulating surface 29 side than the second insulating surface 57. The second embedded electrode surface 89 has a recess recessed toward the first main surface 3 (the chip 2) at a central portion thereof. A bottom portion of the recess is preferably positioned further to the second insulating surface 57 side than the height position of the first oxide film 59. The bottom portion of the recess may be positioned further to the gate wiring 51 side than the height position of the first oxide film 59.

The second upper electrode film 86 forms an upper layer portion of the gate finger electrode 83 and covers the second lower electrode film 84 and the plurality of second embedded electrodes 85 in a film shape. The second upper electrode film 86 contains a conductive material different from the conductive material of the second lower electrode film 84 and the conductive material of the second embedded electrode 85.

The second upper electrode film 86 may include at least one among an Al film, an Al alloy film, a Cu film, and a Cu alloy film. The second upper electrode film 86 may include at least one of an AlSi alloy film, an AlCu alloy film, and an AlSiCu alloy film. The second upper electrode film 86 preferably contains the same type of conductive material as a conductive material of the first upper electrode film 73 on the source side.

The second upper electrode film 86 is mechanically and electrically connected to the second lower electrode film 84 in a portion covering the second insulating surface 57 and is mechanically and electrically connected to the plurality of second embedded electrodes 85 in portions covering the plurality of gate openings 69. Thereby, the second upper electrode film 86 to be electrically connected to the gate wiring 51 via the second lower electrode film 84 and the plurality of second embedded electrodes 85.

The second upper electrode film 86 is connected to the second embedded electrode 85 (the second embedded electrode surface 89) at a height position on the gate wiring 51 side with respect to the height position of the second insulating surface 57. The second upper electrode film 86 is connected to the second embedded electrode surface 89 at a position higher than the height position of the first oxide film 59.

The second upper electrode film 86 backfills the recess of the second embedded electrode surface 89 in a covering portion with respect to the second embedded electrode 85. In a case where the second embedded electrode 85 is embedded below the height position of the first oxide film 59, the second upper electrode film 86 may be connected to the second embedded electrode surface 89 below the height position of the first oxide film 59.

The second upper electrode film 86 has a thickness larger than the thickness (a total thickness) of the second lower electrode film 84. The thickness of the second upper electrode film 86 is larger than the thickness of the gate wiring 51. The thickness of the second upper electrode film 86 is larger than the thickness of the second embedded electrode 85. The thickness of the second upper electrode film 86 is larger than both the thickness of the first planar insulating film 23 and the thickness of the second planar insulating film 52. Preferably, the thickness of the second upper electrode film 86 is substantially equal to the thickness of the first upper electrode film 73 on the source side.

The thickness of the second upper electrode film 86 may be not less than 0.5 μm and not more than 5 μm. The thickness of the second upper electrode film 86 may have a value falling within at least one of ranges of not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The semiconductor device 1A includes a gate main electrode 90 arranged on the plurality of gate structures 20. The gate main electrode 90 is a terminal electrode to which a gate potential is applied from the exterior. The gate main electrode 90 may be referred to as a “second main electrode,” a “second pad electrode,” a “second terminal electrode,” etc. The gate main electrode 90 is arranged in a region between the source main electrode 70 and the source finger electrode 80 at intervals from the source main electrode 70 and the source finger electrode 80.

In this embodiment, the gate main electrode 90 is arranged in a region on the third side surface 5C side with respect to the first pad portion 70a and is sandwiched between the second pad portion 70b and the third pad portion 70c. That is, gate main electrode 90 faces first pad portion 70a in the first direction X and faces second pad portion 70b and third pad portion 70c in the second direction Y.

The gate main electrode 90 is formed in a polygonal shape (a quadrangular shape in this embodiment) having four sides parallel to the peripheral edges of the chip 2 in plan view. The gate main electrode 90 has a plane area less than a plane area of the source main electrode 70 (the first pad portion 70a). The gate main electrode 90 may have a plane area less than the plane area of the second pad portion 70b (the third pad portion 70c).

The gate main electrode 90 is arranged on a portion covering the active region 8 and the outer peripheral region 9 and is connected to the gate finger electrode 83. The gate main electrode 90 is arranged on an insulating region in which the plurality of first planar insulating films 23 are integrated in the active region 8 and is electrically disconnected from the plurality of body regions 12, the plurality of source regions 14 and 15, and the plurality of contact regions 16. The gate main electrode 90 may cover the gate wiring 51 across the second planar insulating film 52 in the outer peripheral region 9.

Similarly to the gate finger electrode 83, the gate main electrode 90 includes the second lower electrode film 84 and the second upper electrode film 86. Similarly to the gate finger electrode 83, the second lower electrode film 84 has the laminated structure including the first electrode film 74 and the second electrode film 75. The second lower electrode film 84 forms a lower layer portion of the gate main electrode 90 and covers the insulating region in a film shape. The second upper electrode film 86 forms an upper layer portion of the gate main electrode 90 and covers the second lower electrode film 84 in a film shape.

Although specific illustration shall be omitted, similarly to the gate finger electrode 83, the gate main electrode 90 may have the plurality of second embedded electrodes 85. In this case, similarly to the gate finger electrode 83, the gate main electrode 90 may be electrically connected to the gate wiring 51 via the plurality of second embedded electrodes 85.

In a case where the plurality of gate electrodes 22 are arranged below the gate main electrode 90, the gate main electrode 90 may be electrically connected to the plurality of gate electrodes 22 via the plurality of second embedded electrodes 85. The gate main electrode 90 does not have to have the plurality of second embedded electrodes 85.

That is, the gate main electrode 90 does not have to have electrical connection portions with respect to the plurality of gate electrodes 22 and an electrical connection portion with respect to the gate wiring 51 in a directly lower region. An arrangement may be adopted, in which the plurality of gate electrodes 22 are not positioned in a region below the gate main electrode 90.

The gate potential applied to the gate main electrode 90 is applied to the gate wiring 51 via the gate finger electrode 83. The gate potential is transmitted to the plurality of gate electrodes 22 via a wiring path (current path) along the gate wiring 51. Thereby, the plurality of gate electrodes 22 enter an ON state, and ON/OFF of the plurality of channel regions 17 and 18 is controlled.

The semiconductor device 1A includes a drain main electrode 91 covering the second main surface 4. The drain main electrode 91 is a terminal electrode to which a drain potential is applied from the exterior. The drain main electrode 91 may be referred to as a “third main electrode,” a “third pad electrode,” a “third terminal electrode,” etc.

The drain main electrode 91 is electrically connected to the first semiconductor region 10. The drain main electrode 91 may cover the entire second main surface 4 such as to be continuous to the peripheral edges (the first to fourth side surfaces 5A to 5D) of the second main surface 4. The drain main electrode 91 may partially cover the second main surface 4 such as to expose the peripheral edge portions of the second main surface 4.

A breakdown voltage that can be applied between the source main electrode 70 and the drain main electrode 91 (between the first main surface 3 and the second main surface 4) may be not less than 500 V and not more than 3000 V. The breakdown voltage may have a value falling within at least one of ranges of not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

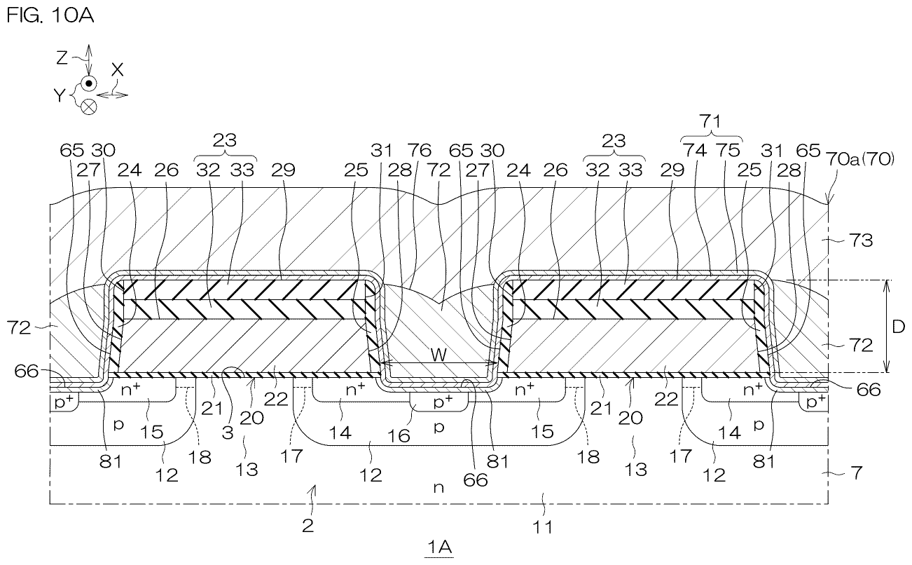

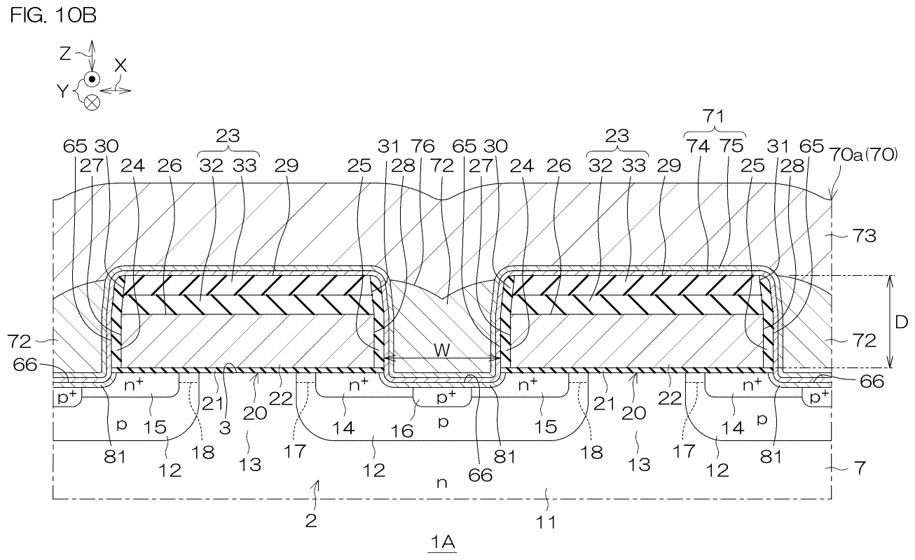

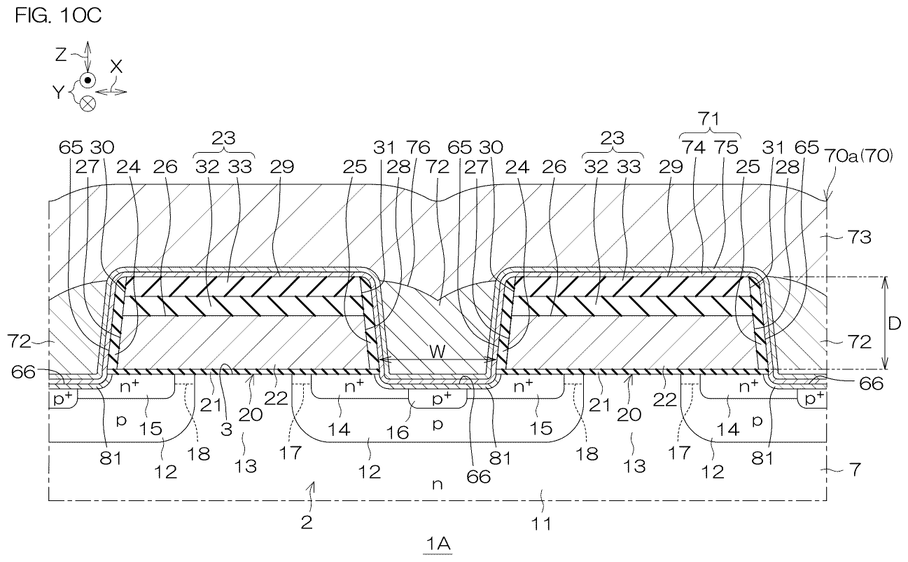

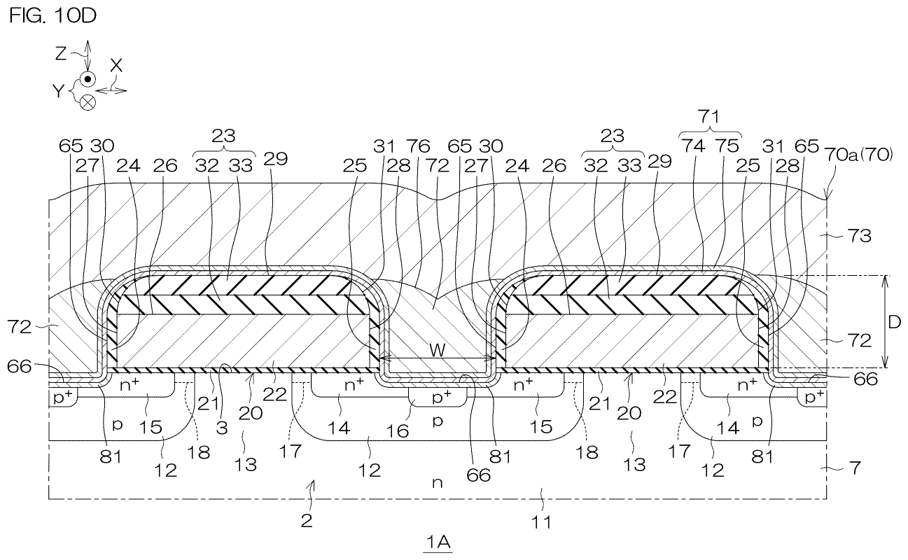

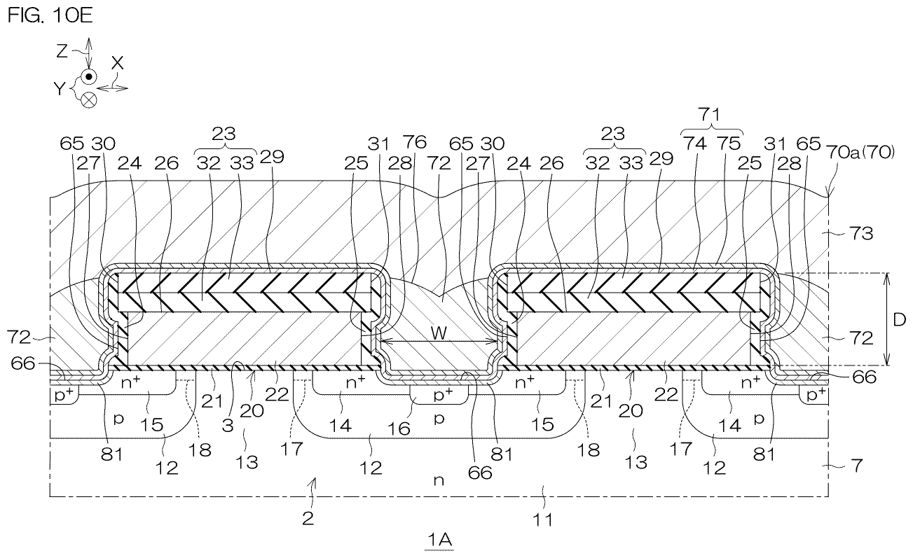

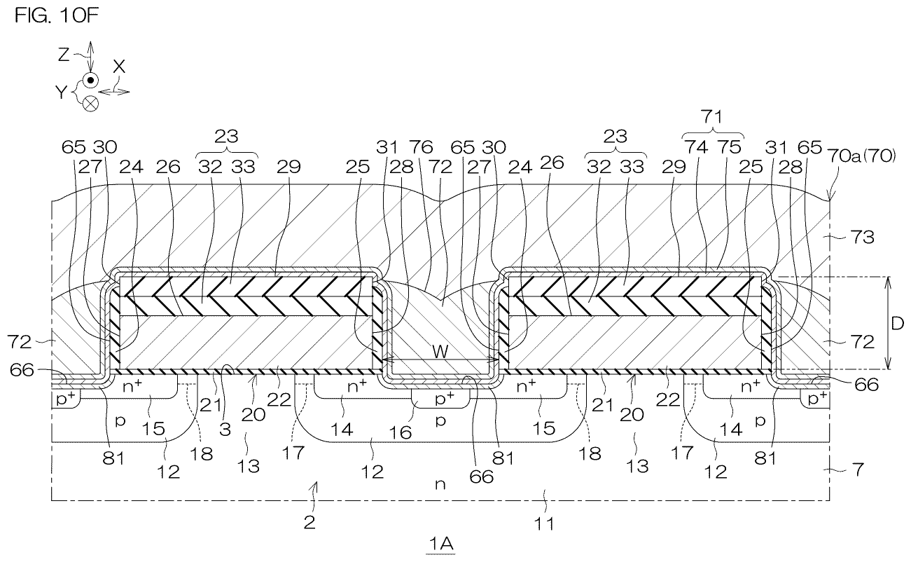

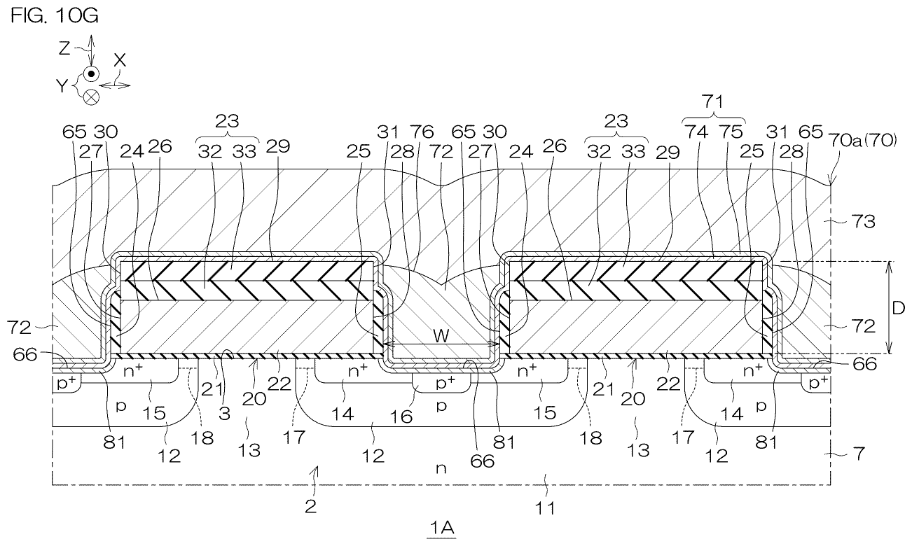

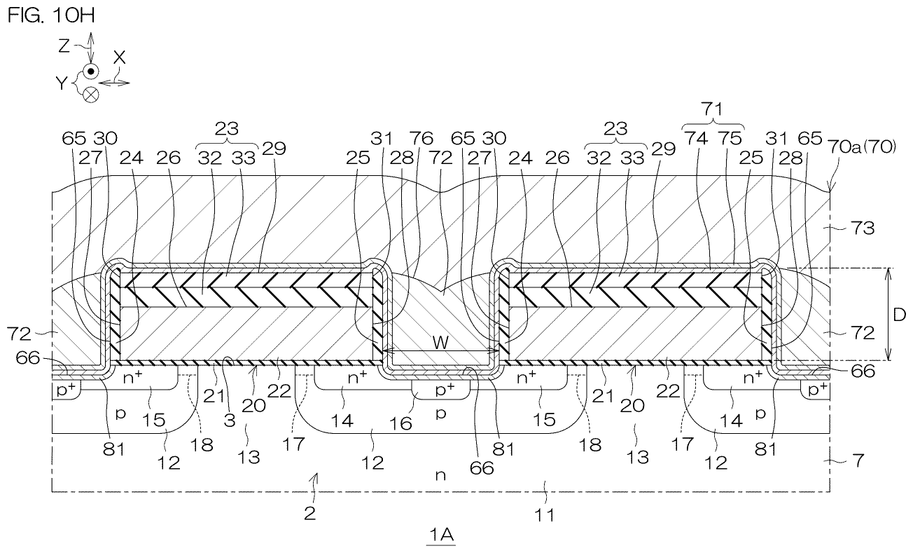

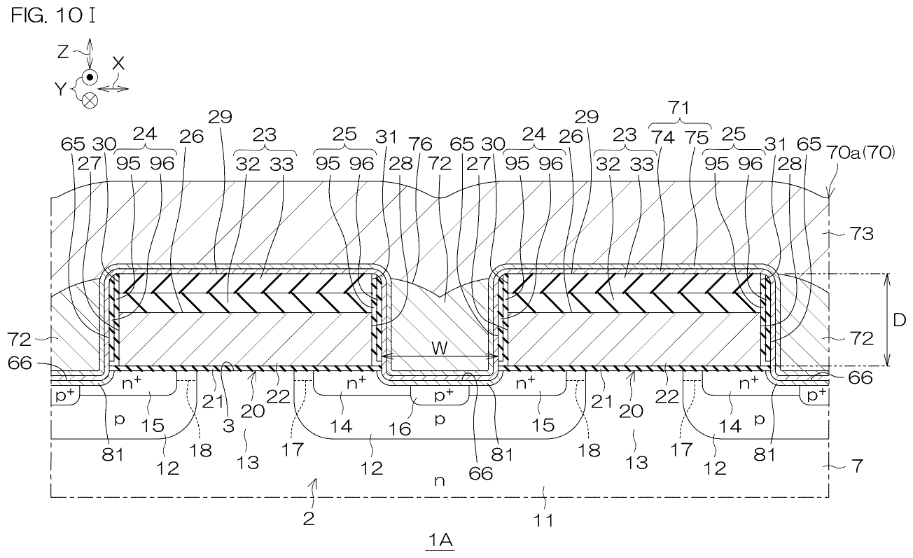

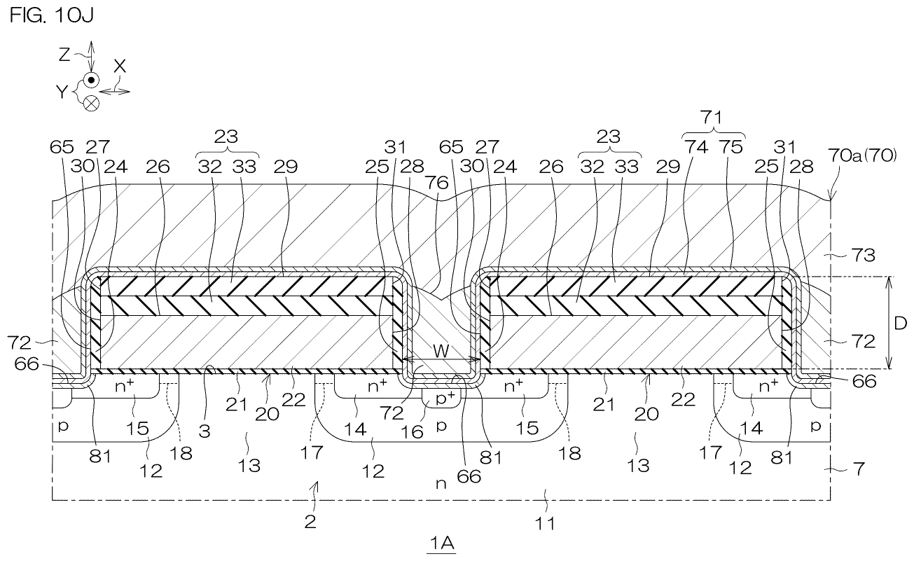

Hereinafter, other configuration examples of the gate structure 20 shall be described with reference to FIG. 10A to FIG. 10J. FIG. 10A to FIG. 10J are enlarged cross-sectional views showing the gate structures 20 according to second to eleventh examples. The gate structure 20 does not necessarily have to be constituted of any one of arrangements of the first to eleventh examples (FIG. 7 and FIG. 10A to FIG. 10J). The gate structure 20 may simultaneously include at least two features of the arrangements of the first to eleventh examples. The gate structures 20 according to the first to eleventh examples are all obtained by adjusting process conditions in a manufacturing process.

With reference to FIG. 10A (the second example), in this embodiment, the gate electrode 22 is formed in a tapered shape (preferably, an isosceles trapezoidal shape) in cross-sectional view. The gate electrode 22 has the first side wall 27 and the second side wall 28 inclined obliquely toward the electrode surface 26 and is formed in a tapered shape having a width gradually narrowing from the gate insulating film 21 side toward the electrode surface 26 side. The second side wall 28 may have an inclination angle (an absolute value) different from an inclination angle (an absolute value) of the first side wall 27.

In this embodiment, the first planar insulating film 23 is laminated on the gate electrode 22 at an inclination angle different from the inclination angle of the gate electrode 22. The first planar insulating film 23 has the first insulating side wall 30 having an inclination angle different from the inclination angle of the first side wall 27 and the second insulating side wall 31 having an inclination angle different from the inclination angle of the second side wall 28.

The inclination angle of the first insulating side wall 30 is smaller than the inclination angle of the first side wall 27 when a vertical line along the vertical direction Z is set as a reference (0°). The inclination angle of the second insulating side wall 31 is smaller than the inclination angle of the second side wall 28 when the vertical line along the vertical direction Z is set as the reference (0°). In this embodiment, the first insulating side wall 30 and the second insulating side wall 31 extend substantially perpendicular to the first main surface 3.

The first side wall insulating film 24 covers the first side wall 27 and the first insulating side wall 30 in a film shape conforming to an inclination angle of the first side wall 27 and an inclination angle of the first insulating side wall 30. The first side wall insulating film 24 has the film surface inclined obliquely with respect to the vertical line in the covering portion with respect to the first side wall 27 and the film surface extending along the vertical line in the covering portion with respect to the first insulating side wall 30.

The second side wall insulating film 25 covers the second side wall 28 and the second insulating side wall 31 in a film shape conforming to an inclination angle of the second side wall 28 and an inclination angle of the second insulating side wall 31. The second side wall insulating film 25 has the film surface inclined obliquely with respect to the vertical line in the covering portion with respect to the second side wall 28 and the film surface extending along the vertical line in the covering portion with respect to the second insulating side wall 31.

With reference to FIG. 10B (the third example), in this embodiment, the gate electrode 22 has the first side wall 27 and the second side wall 28 extending substantially perpendicular to the electrode surface 26 in cross-sectional view and is formed in a flat rectangular shape. In this embodiment, the first planar insulating film 23 is laminated on the gate electrode 22 at an inclination angle different from the inclination angle of the gate electrode 22. Specifically, the first planar insulating film 23 is formed in a tapered shape (preferably, an isosceles trapezoidal shape) in cross-sectional view.

The first planar insulating film 23 has the first insulating side wall 30 and the second insulating side wall 31 inclined obliquely toward the first insulating surface 29 and is formed in a tapered shape having a width gradually narrowing from the gate electrode 22 side toward the first insulating surface 29 side. The inclination angle of the first insulating side wall 30 is larger than the inclination angle of the first side wall 27 when the vertical line along the vertical direction Z is set as the reference (0°). The inclination angle of the second insulating side wall 31 is larger than the inclination angle of the second side wall 28 when the vertical line along the vertical direction Z is set as the reference (0°).

The first side wall insulating film 24 covers the first side wall 27 and the first insulating side wall 30 in a film shape conforming to an inclination angle of the first side wall 27 and an inclination angle of the first insulating side wall 30. The first side wall insulating film 24 has the film surface extending along the vertical line in the covering portion with respect to the first side wall 27 and the film surface inclined obliquely with respect to the vertical line in the covering portion with respect to the first insulating side wall 30.

The second side wall insulating film 25 covers the second side wall 28 and the second insulating side wall 31 in a film shape conforming to an inclination angle of the second side wall 28 and an inclination angle of the second insulating side wall 31. The second side wall insulating film 25 has the film surface extending along the vertical line in the covering portion with respect to the second side wall 28 and the film surface inclined obliquely with respect to the vertical line in the covering portion with respect to the second insulating side wall 31.

With reference to FIG. 10C (the fourth example), in this embodiment, the gate electrode 22 is formed in a tapered shape (preferably, an isosceles trapezoidal shape) in cross-sectional view. The gate electrode 22 may have the first side wall 27 and the second side wall 28 inclined obliquely toward the electrode surface 26 and may be formed in a tapered shape having a width gradually narrowing from the gate insulating film 21 side toward the electrode surface 26 side.

The second side wall 28 may have an inclination angle (an absolute value) different from an inclination angle (an absolute value) of the first side wall 27. The inclination angle (the absolute value) of the second side wall 28 may be substantially equal to the inclination angle (the absolute value) of the first side wall 27.

In this embodiment, the first planar insulating film 23 is formed in a tapered shape (preferably, an isosceles trapezoidal shape) in cross-sectional view. The first planar insulating film 23 has the first insulating side wall 30 and the second insulating side wall 31 inclined obliquely toward the first insulating surface 29 and is formed in a tapered shape having a width gradually narrowing from the gate electrode 22 side toward the first insulating surface 29 side.

The inclination angle of the first insulating side wall 30 may be larger than the inclination angle of the first side wall 27 when the vertical line along the vertical direction Z is set as the reference (0°). The inclination angle of the first insulating side wall 30 may be less than the inclination angle of the first side wall 27 or may be larger than the inclination angle of the first side wall 27. In this embodiment, the first insulating side wall 30 has the inclination angle substantially equal to the inclination angle of the first side wall 27 and is formed substantially flush with the first side wall 27.

The inclination angle of the second insulating side wall 31 may be different from the inclination angle of the second side wall 28 when the vertical line along the vertical direction Z is set as the reference (0°). The inclination angle of the second insulating side wall 31 may be less than the inclination angle of the second side wall 28 or may be larger than the inclination angle of the second side wall 28. In this embodiment, the second insulating side wall 31 has the inclination angle substantially equal to the inclination angle of the first side wall 27 and is formed substantially flush with the first side wall 27.

The first side wall insulating film 24 covers the first side wall 27 and the first insulating side wall 30 in a film shape conforming to an inclination angle of the first side wall 27 and an inclination angle of the first insulating side wall 30. The first side wall insulating film 24 has the film surface inclined obliquely with respect to the vertical line in the covering portion with respect to the first side wall 27 and the film surface inclined obliquely with respect to the vertical line in the covering portion with respect to the first insulating side wall 30.

The second side wall insulating film 25 covers the second side wall 28 and the second insulating side wall 31 in a film shape conforming to an inclination angle of the second side wall 28 and an inclination angle of the second insulating side wall 31. The second side wall insulating film 25 has the film surface inclined obliquely with respect to the vertical line in the covering portion with respect to the second side wall 28 and the film surface inclined obliquely with respect to the vertical line in the covering portion with respect to the second insulating side wall 31.

With reference to FIG. 10D (the fifth example), in this embodiment, the first planar insulating film 23 has a first arcuate corner portion and a second arcuate corner portion. The first arcuate corner portion connects the first insulating surface 29 and the first insulating side wall 30 in a circular arc shape. The second arcuate corner portion connects the first insulating surface 29 and the second insulating side wall 31 in a circular arc shape.

The first side wall insulating film 24 covers the first side wall 27 in a film shape conforming to the inclination angle of the first side wall 27 and covers the first arcuate corner portion in an arcuate film shape conforming to an arcuate surface of the first arcuate corner portion. The first side wall insulating film 24 may have a film thickness that gradually increases from the first insulating surface 29 side toward the gate electrode 22 side in a covering portion with respect to the first arcuate corner portion.

The second side wall insulating film 25 covers the second side wall 28 in a film shape conforming to the inclination angle of the second side wall 28 and covers the second arcuate corner portion in an arcuate film shape conforming to an arcuate surface of the second arcuate corner portion. The second side wall insulating film 25 may have a film thickness that gradually increases from the first insulating surface 29 side toward the gate electrode 22 side in a covering portion with respect to the second arcuate corner portion.

With reference to FIG. 10E (the sixth example), in this embodiment, the first planar insulating film 23 is laminated on the gate electrode 22 such as to protrude from a position on the gate electrode 22 to a region outside the gate electrode 22 in the horizontal direction (the first direction X).

In this embodiment, the first planar insulating film 23 has the first insulating side wall 30 projecting in the horizontal direction (the first direction X) from the first side wall 27 and the second insulating side wall 31 projecting in the horizontal direction (the first direction X) from the second side wall 28. That is, the first planar insulating film 23 has a first overhang portion protruding from a position on the gate electrode 22 to one side in the first direction X and a second overhang portion protruding from above the gate electrode 22 to one side in the first direction X.

The first overhang portion is demarcated by a rear surface of the first planar insulating film 23 and the first insulating side wall 30 and faces the gate insulating film 21 without interposition of the gate electrode 22 in the lamination direction. The first insulating side wall 30 is connected to the first side wall 27 via the rear surface of the first planar insulating film 23.

The second overhang portion is demarcated by the rear surface of the first planar insulating film 23 and the second insulating side wall 31 and faces the gate insulating film 21 without interposition of the gate electrode 22 in the lamination direction. The second insulating side wall 31 is connected to the second side wall 28 via the rear surface of the first planar insulating film 23.

The first side wall insulating film 24 covers the first side wall 27 and the first insulating side wall 30 in a film shape conforming to an inclination angle of the first side wall 27 and an inclination angle of the first insulating side wall 30. The first side wall insulating film 24 may have a portion covering the rear surface of the first planar insulating film 23. The first side wall insulating film 24 may have a recess recessed toward the gate electrode 22 (the first side wall 27) from the covering portion with respect to the first insulating side wall 30 in the covering portion with respect to the first side wall 27.

The second side wall insulating film 25 covers the second side wall 28 and the second insulating side wall 31 in a film shape conforming to an inclination angle of the second side wall 28 and an inclination angle of the second insulating side wall 31. The second side wall insulating film 25 may have a portion covering the rear surface of the first planar insulating film 23. The second side wall insulating film 25 may have a recess recessed toward the gate electrode 22 (the first side wall 27) from the covering portion with respect to the second insulating side wall 31 in the covering portion with respect to the second side wall 28.

The first lower electrode film 71 (the first electrode film 74 and the second electrode film 75) of the source main electrode 70 may have a portion extending along the recess of the first side wall insulating film 24. In this case, either or both of the first electrode film 74 and the second electrode film 75 may face the gate insulating film 21 with a portion of the first side wall insulating film 24 interposed therebetween.

The first lower electrode film 71 (the first electrode film 74 and the second electrode film 75) of the source main electrode 70 may have a portion extending along the recess of the first side wall insulating film 24. In this case, either or both of the first electrode film 74 and the second electrode film 75 may face the gate insulating film 21 with a portion of the second side wall insulating film 25 interposed therebetween.

In a case where a protrusion amount of the first planar insulating film 23 with respect to the gate electrode 22 is small, the first side wall insulating film 24 does not have to have the recess and may have a film surface continuously extending along the vertical line in both the covering portion with respect to the first side wall 27 and the covering portion with respect to the first insulating side wall 30. Similarly, in the case where the protrusion amount of the first planar insulating film 23 with respect to the gate electrode 22 is small, the second side wall insulating film 25 does not have to have the recess and may have a film surface continuously extending the vertical line in both the covering portion with respect to the second side wall 28 and the covering portion with respect to the second insulating side wall 31.

With reference to FIG. 10F (the seventh example), in this embodiment, the first side wall insulating film 24 covers the first insulating side wall 30 of the first planar insulating film 23 at an interval to the first main surface 3 (the gate insulating film 21) side from the first insulating surface 29. In this embodiment, the first side wall insulating film 24 crosses the boundary portion between the first oxide film 32 and the second oxide film 33 and covers both the first oxide film 32 and the second oxide film 33 and exposes an upper end portion of the second oxide film 33 from the first insulating side wall 30.

In this embodiment, the second side wall insulating film 25 covers the second insulating side wall 31 of the first planar insulating film 23 at an interval to the first main surface 3 (the gate insulating film 21) side from the first insulating surface 29. In this embodiment, the second side wall insulating film 25 crosses the boundary portion between the first oxide film 32 and the second oxide film 33 and covers both the first oxide film 32 and the second oxide film 33 and exposes an upper end portion of the second oxide film 33 from the second insulating side wall 31.

In this embodiment, the first lower electrode film 71 of the source main electrode 70 has a portion directly covering an exposed portion of the first insulating side wall 30 and an exposed portion of the second insulating side wall 31. Specifically, the first electrode film 74 has a portion directly covering the second oxide film 33 on the first insulating side wall 30 and the second insulating side wall 31. On the other hand, the second electrode film 75 has a portion covering the second oxide film 33 across the first electrode film 74 on the first insulating side wall 30 and the second insulating side wall 31.

With reference to FIG. 10G (the eighth example), in this embodiment, the first side wall insulating film 24 covers the first insulating side wall 30 at an interval to the first main surface 3 (the gate insulating film 21) side from the boundary portion between the first oxide film 32 and the second oxide film 33 and exposes both the first oxide film 32 and the second oxide film 33 from the first insulating side wall 30.

In this embodiment, the second side wall insulating film 25 covers the second insulating side wall 31 at an interval to the first main surface 3 (the gate insulating film 21) side from the boundary portion between the first oxide film 32 and the second oxide film 33 and exposes both the first oxide film 32 and the second oxide film 33 from the second insulating side wall 31.

In this embodiment, the first lower electrode film 71 of the source main electrode 70 has portions directly covering both the exposed portion of the first insulating side wall 30 and the exposed portion of the second insulating side wall 31. Specifically, the first electrode film 74 has portions directly covering both the first oxide film 32 and the second oxide film 33 on the first insulating side wall 30 and the second insulating side wall 31. On the other hand, the second electrode film 75 has portions covering both the first oxide film 32 and the second oxide film 33 across the first electrode film 74 on the first insulating side wall 30 and the second insulating side wall 31.

With reference to FIG. 10H (the ninth example), in this embodiment, each of the plurality of side wall insulating films 24 and 25 has a projecting portion projecting further upward than the first insulating surface 29. The projecting portion has a projection amount less than the thickness of the first planar insulating film 23. The projection amount of the projecting portion is less than the thickness of the first oxide film 32. The projection amount of the projecting portion is less than the thickness of the second oxide film 33. The projection amount of the projecting portion may be less than the thickness of the plurality of side wall insulating films 24 and 25. The projection amount of the projecting portion may be larger than the thickness of the plurality of side wall insulating films 24 and 25.

In this embodiment, the first lower electrode film 71 of the source main electrode 70 has portions directly covering the projecting portions of the plurality of side wall insulating films 24 and 25. Specifically, the first electrode film 74 has the portions directly covering the projecting portions of the plurality of side wall insulating films 24 and 25. On the other hand, the second electrode film 75 has portions covering the projecting portions of the plurality of side wall insulating films 24 and 25 across the first electrode film 74.

With reference to FIG. 10I (the tenth example), in this embodiment, each of the plurality of side wall insulating films 24 and 25 has a laminated structure including a plurality of insulating films. The number of laminated insulating films may be two, three, four, or five. The plurality of side wall insulating films 24 and 25 may include, as the plurality of insulating films, at least one among a silicon oxide film, a silicon nitride film, and a silicon oxynitride film. The silicon oxide film may be any one among an NSG film, a TEOS film, a PSG film, and a BPSG film.

Each of the plurality of insulating films may have a thickness of not less than 0.05 μm and not more than 0.5 μm. The thickness of the plurality of insulating films may have a value falling within at least one of ranges of not less than 0.05 μm and not more than 0.1 μm, not less than 0.1 μm and not more than 0.15 μm, not less than 0.15 μm and not more than 0.2 μm, not less than 0.2 μm and not more than 0.25 μm, not less than 0.25 μm and not more than 0.3 μm, not less than 0.3 μm and not more than 0.35 μm, not less than 0.35 μm and not more than 0.4 μm, not less than 0.4 μm and not more than 0.45 μm, and not less than 0.45 μm and not more than 0.5 μm.

FIG. 10I shows an example in which each of the plurality of side wall insulating films 24 and 25 has a laminated structure (a two-layer structure) including a first insulating film 95 and a second insulating film 96. Hereinafter, an arrangement on the first side wall insulating film 24 side shall be described. An arrangement on the second side wall insulating film 25 side is obtained by replacing the “first side wall 27” with the “second side wall 28” and replacing the “first insulating side wall 30” with the “second insulating side wall 31” in the following description.

The first insulating film 95 covers the first side wall 27 on the gate insulating film 21. The first insulating film 95 may have a lower end portion extending in the horizontal direction on the gate insulating film 21. In this embodiment, the first insulating film 95 is led out from the first side wall 27 toward the first insulating side wall 30 of the first planar insulating film 23 and has a portion covering the first side wall 27 and a portion covering the first insulating side wall 30. The first insulating film 95 has a portion covering the boundary portion between the gate electrode 22 and the first planar insulating film 23.

The first insulating film 95 covers the first side wall 27 and the first insulating side wall 30 in a film shape conforming to the inclination angle of the first side wall 27 and the inclination angle of the first insulating side wall 30. The first insulating film 95 has a film surface extending at an inclination angle substantially equal to the inclination angle of the first side wall 27 in a covering portion with respect to the first side wall 27 and extending substantially parallel to the first side wall 27. Also, the first insulating film 95 has a film surface extending at an inclination angle substantially equal to the inclination angle of the first insulating side wall 30 in a covering portion with respect to the first insulating side wall 30 and extending substantially parallel to the first insulating side wall 30.

The first insulating film 95 covers both the first oxide film 32 and the second oxide film 33 on the first insulating side wall 30. The first insulating film 95 has a portion covering the boundary portion between the first oxide film 32 and the second oxide film 33. The first insulating film 95 is formed on the first main surface 3 side with respect to the first insulating surface 29 and exposes the first insulating surface 29. The first insulating film 95 exposes the second oxide film 33 from the first insulating surface 29.

The second insulating film 96 covers the first side wall 27 across the first insulating film 95 on the gate insulating film 21. The second insulating film 96 has a lower end portion positioned on the lower end portion of the first insulating film 95. The lower end portion of the second insulating film 96 faces the gate insulating film 21 with the lower end portion of the first insulating film 95 interposed therebetween. The lower end portion of the second insulating film 96 may be directly connected to the gate insulating film 21.

In this embodiment, the second insulating film 96 is led out from the first side wall 27 toward the first insulating side wall 30 of the first planar insulating film 23 and covers the first insulating side wall 30 across the first insulating film 95. The second insulating film 96 has a portion covering the first side wall 27 across the first insulating film 95 and a portion covering the first insulating side wall 30 across the first insulating film 95. The second insulating film 96 has a portion covering the boundary portion between the gate electrode 22 and the first planar insulating film 23 across the first insulating film 95.

The second insulating film 96 covers the first side wall 27 and the first insulating side wall 30 in a film shape conforming to the inclination angle of the first side wall 27 and the inclination angle of the first insulating side wall 30. The second insulating film 96 has a film surface extending at an inclination angle substantially equal to the inclination angle of the first side wall 27 in a covering portion with respect to the first side wall 27 and extending substantially parallel to the first side wall 27. Also, the second insulating film 96 has a film surface extending at an inclination angle substantially equal to the inclination angle of the first insulating side wall 30 in a covering portion with respect to the first insulating side wall 30 and extending substantially parallel to the first insulating side wall 30.

The second insulating film 96 covers both the first oxide film 32 and the second oxide film 33 across the first insulating film 95 on the first insulating side wall 30. The second insulating film 96 has a portion covering the boundary portion between the first oxide film 32 and the second oxide film 33 across the first insulating film 95. The second insulating film 96 is formed on the first main surface 3 side with respect to the first insulating surface 29 and exposes the first insulating surface 29. The second insulating film 96 exposes the second oxide film 33 from the first insulating surface 29.

With reference to FIG. 10J (the eleventh example), in this embodiment, the plurality of gate structures 20 are aligned at a narrow pitch and demarcate the plurality of vertically long source openings 65 having the aspect ratio D/W larger than 1. Each of the plurality of source openings 65 has the opening depth D larger than the opening width W and is formed in a vertically long shape in cross-sectional view.

In other words, the first side wall insulating film 24 and the second side wall insulating film 25 demarcate the vertically long source opening 65 having the aspect ratio D/W larger than 1. The thus described source opening 65 is appropriately formed by the film-shaped first side wall insulating film 24 not having a portion bulging in the horizontal direction and the film-shaped second side wall insulating film 25 not having a portion bulging in the horizontal direction.

The opening width W is preferably not less than one time and not more than five times the thickness of the first side wall insulating film 24 (the second side wall insulating film 25). The opening width W is particularly preferably not less than one and half times and not more than three times the thickness of the first side wall insulating film 24 (the second side wall insulating film 25). The opening width W is preferably not less than 0.25 μm and not more than 0.45 μm. The opening depth D is preferably not less than 0.5 μm and not more than 1 μm. The aspect ratio D/W is preferably not more than 3. The aspect ratio D/W is particularly preferably not more than 2.

In this embodiment, the source main electrode 70 includes the plurality of first embedded electrodes 72 extending in a vertically long columnar shape in cross-sectional view, and the first upper electrode film 73 mechanically and electrically connected to the plurality of first embedded electrodes 72 extending in the vertically long columnar shape. Each of the plurality of first embedded electrodes 72 has the aspect ratio D/W larger than 1 in cross-sectional view, corresponding to the aspect ratio D/W of the corresponding source opening 65.

In the arrangement in which the plurality of gate structures 20 are aligned at a narrow pitch, a channel area per unit area is increased. Therefore, the above-described arrangement is effective in reducing on resistance of the active region 8 (the transistor structure Tr). On the other hand, in the arrangement in which the plurality of gate structures 20 are aligned at a narrow pitch, the width of the source opening 65 is reduced due to a layout of the plurality of gate structures 20. In this case, concerns arise regarding the embeddability and film formability of the source main electrode 70 with respect to the source opening 65.

In this respect, the source main electrode 70 including the first embedded electrodes 72 and the first upper electrode film 73 prevents a decrease in the embeddability of the first upper electrode film 73 with respect to the plurality of source openings 65, since the plurality of first embedded electrodes 72 are embedded in the plurality of source openings 65. Also, since a level difference due to the plurality of source openings 65 is moderated by the plurality of first embedded electrodes 72, a decrease in the film formability of the first upper electrode film 73 with respect to the plurality of source openings 65 is prevented.

Accordingly, the source main electrode 70 can be appropriately electrically connected to the first main surface 3. The arrangement of the gate structure 20 according to the eleventh example (the aspect ratio D/W) is preferably applied to the gate structures 20 according to the first to tenth examples.

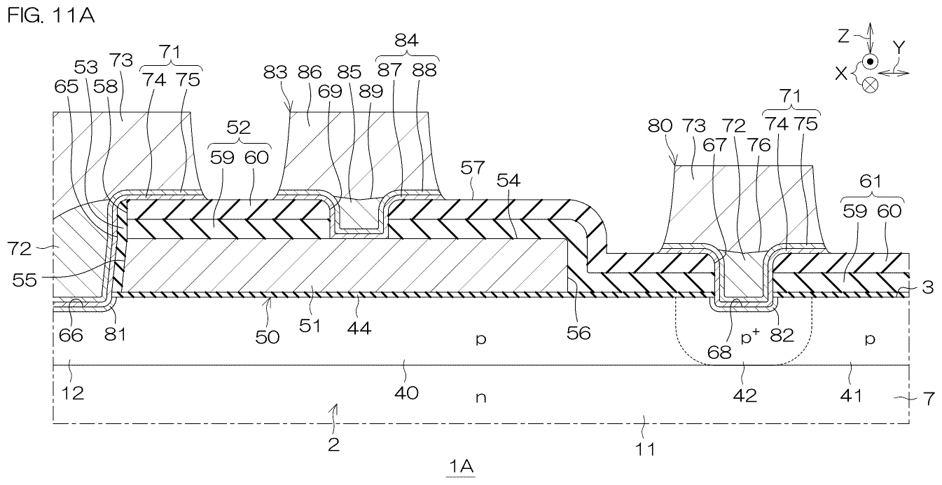

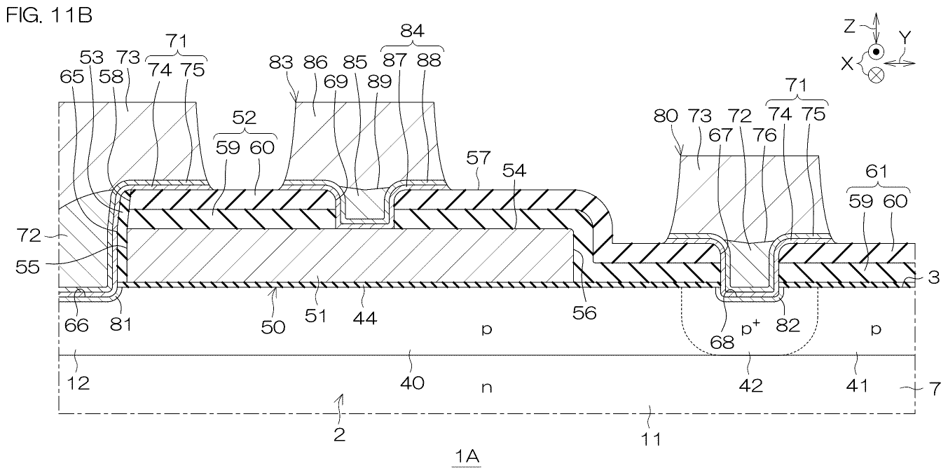

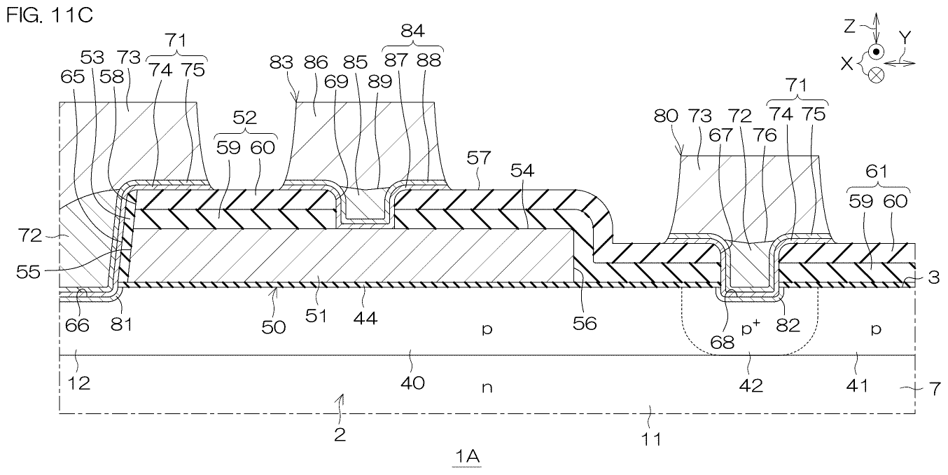

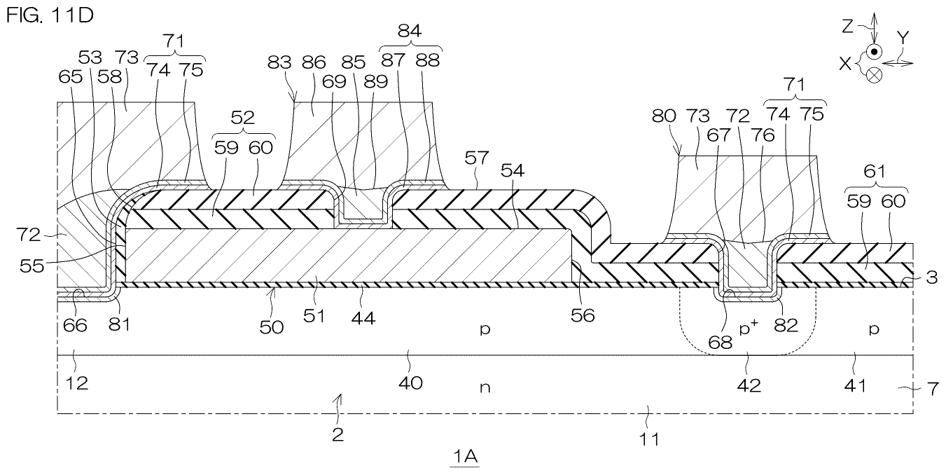

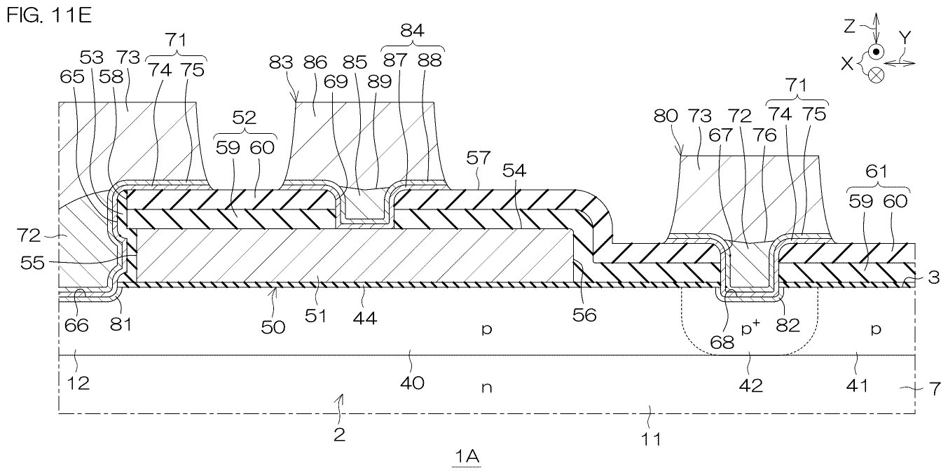

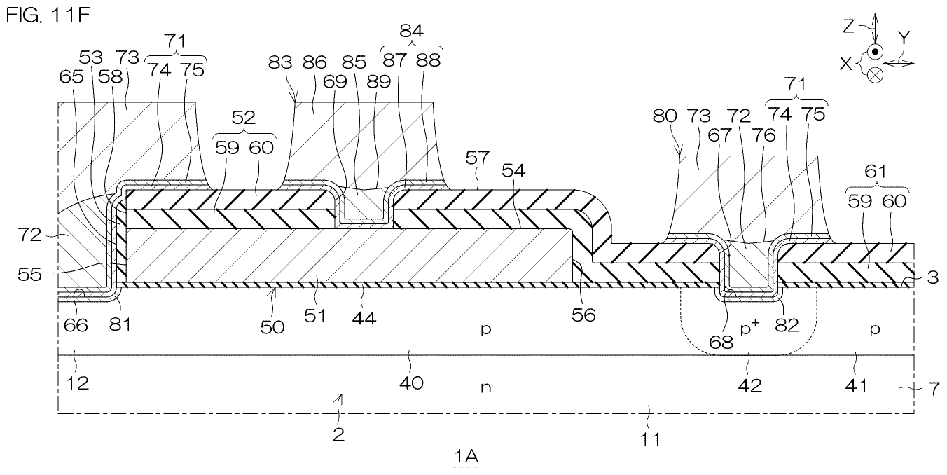

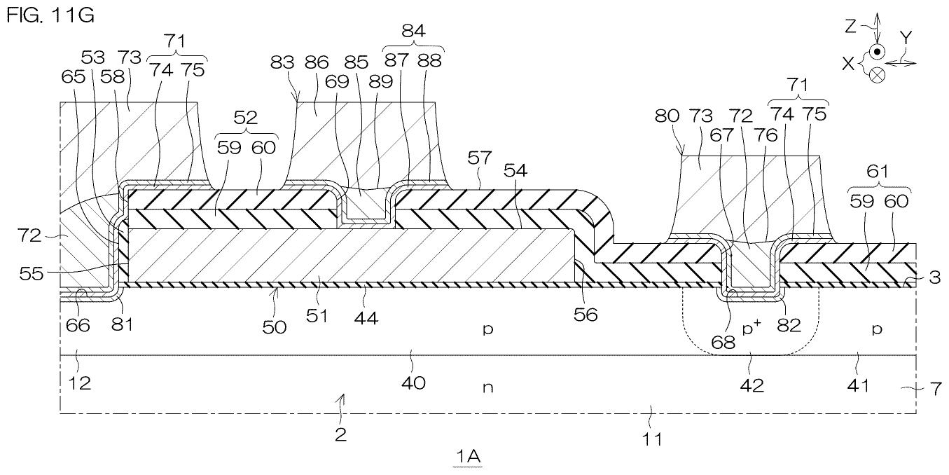

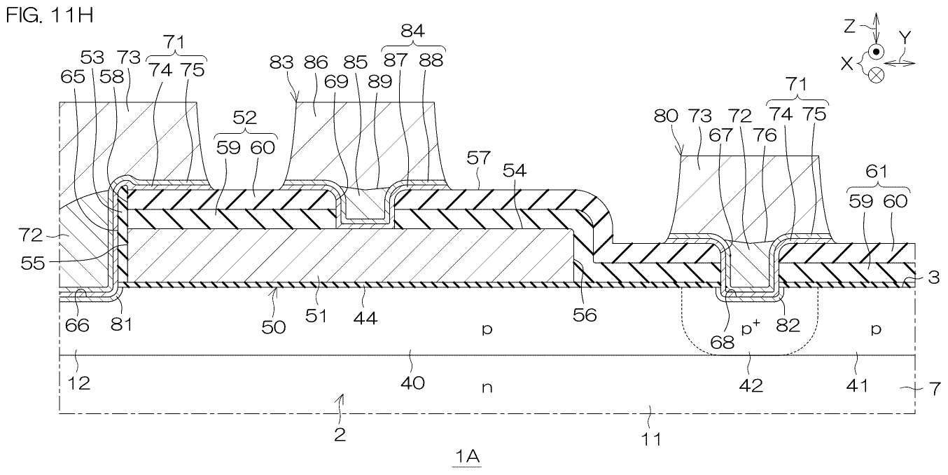

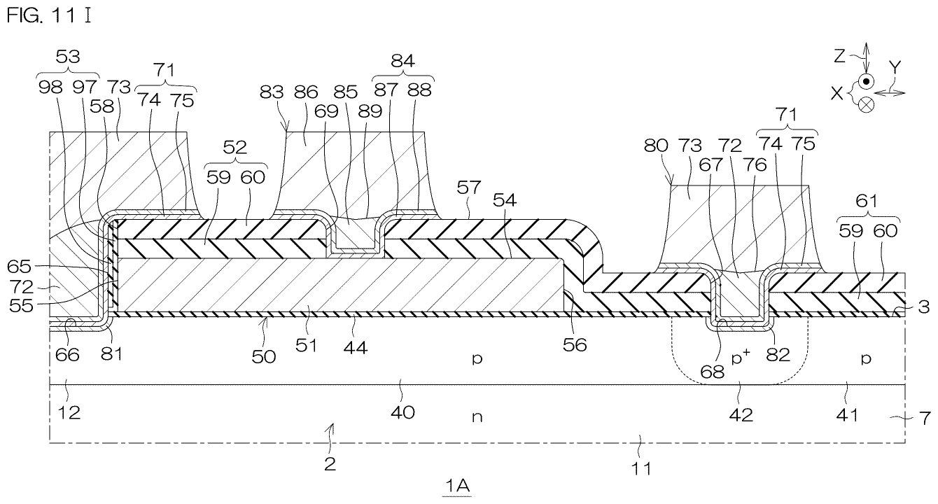

Hereinafter, other configuration examples of the wiring structure 50 shall be described with reference to FIG. 11A to FIG. 11I. FIG. 11A to FIG. 11I are enlarged cross-sectional views showing the wiring structures 50 according to second to tenth examples. The wiring structures 50 according to the first to tenth examples are all obtained by adjusting process conditions in a manufacturing process. The wiring structure 50 does not necessarily have to be constituted of any one of arrangements of the first to tenth examples (FIG. 9 and FIG. 11A to FIG. 11I). The wiring structure 50 may simultaneously include at least two features of the arrangements of the first to tenth examples.

Also, at least one of the wiring structures 50 according to the first to tenth examples can be combined with at least one of the gate structures 20 (see FIG. 7 and FIG. 10A to FIG. 10J) according to the first to eleventh examples. A combined configuration of at least two of the wiring structures 50 according to the first to tenth examples may be applied to at least one of the gate structures 20 (see FIG. 7 and FIG. 10A to FIG. 10J) according to the first to eleventh examples.

The wiring structures 50 (see FIG. 11A to FIG. 11I) according to the second to tenth examples to be described below have arrangements respectively corresponding to the arrangements of the gate structures 20 (see FIG. 10A to FIG. 10I) according to the second to tenth examples described above, in the order of the examples. Therefore, from the viewpoint of uniformity of layouts of the gate structures 20 and layouts of the wiring structures 50, it is preferable that, of the wiring structures 50 according to the first to tenth examples and the gate structures 20 according to the first to tenth examples, the wiring structure 50 and the gate structure 20 of the examples with the same ordinal number are combined to each other.

With reference to FIG. 11A (the second example), in this embodiment, the gate wiring 51 has the first wiring side wall 55 inclined obliquely toward the wiring surface 54. The gate wiring 51 is formed in a tapered shape (a tapered shape) having a width gradually narrowing from the main surface insulating film 44 side toward the wiring surface 54 side.

The second wiring side wall 56 of the gate wiring 51 may have an inclination angle (an absolute value) different from the inclination angle (the absolute value) of the first wiring side wall 55. In this embodiment, the second wiring side wall 56 extends substantially perpendicular to the wiring surface 54. The second wiring side wall 56 may be inclined obliquely toward the wiring surface 54.

In this embodiment, the second planar insulating film 52 includes the third insulating side wall 58 having an inclination angle different from the inclination angle of the first wiring side wall 55. The inclination angle of the third insulating side wall 58 is smaller than the inclination angle of the first wiring side wall 55 when the vertical line along the vertical direction Z is set as the reference (0°).

The third side wall insulating film 53 covers the first wiring side wall 55 and the third insulating side wall 58 in a film shape conforming to an inclination angle of the first wiring side wall 55 and an inclination angle of the third insulating side wall 58. The third side wall insulating film 53 has the film surface inclined obliquely with respect to the vertical line in the covering portion with respect to the first wiring side wall 55 and the film surface extending along the vertical line in the covering portion with respect to the third insulating side wall 58.

With reference to FIG. 11B (the third example), in this embodiment, the gate wiring 51 has the first wiring side wall 55 extending substantially perpendicular to the wiring surface 54 in cross-sectional view. In this embodiment, the second wiring side wall 56 of the gate wiring 51 extends substantially perpendicular to the wiring surface 54. The second wiring side wall 56 may be inclined obliquely toward the wiring surface 54.

In this embodiment, the second planar insulating film 52 includes the third insulating side wall 58 having an inclination angle different from the inclination angle of the first wiring side wall 55. Specifically, the third insulating side wall 58 is inclined obliquely toward the second insulating surface 57 in cross-sectional view. The inclination angle of the third insulating side wall 58 is larger than the inclination angle of the first wiring side wall 55 when the vertical line along the vertical direction Z is set as the reference (0°).

The third side wall insulating film 53 covers the first wiring side wall 55 and the third insulating side wall 58 in a film shape conforming to an inclination angle of the first wiring side wall 55 and an inclination angle of the third insulating side wall 58. The third side wall insulating film 53 has the film surface extending along the vertical line in the covering portion with respect to the first wiring side wall 55 and the film surface inclined obliquely with respect to the vertical line in the covering portion with respect to the third insulating side wall 58.

With reference to FIG. 11C (the fourth example), in this embodiment, the gate wiring 51 has the first wiring side wall 55 inclined obliquely toward the wiring surface 54. The gate wiring 51 is formed in a tapered shape (a tapered shape) having a width gradually narrowing from the main surface insulating film 44 side toward the wiring surface 54 side. In this embodiment, the second wiring side wall 56 of the gate wiring 51 extends substantially perpendicular to the wiring surface 54. The second wiring side wall 56 may be inclined obliquely toward the wiring surface 54.

In this embodiment, the second planar insulating film 52 has the third insulating side wall 58 inclined obliquely toward the second insulating surface 57. The inclination angle of the third insulating side wall 58 may be different from the inclination angle of the first wiring side wall 55 when the vertical line along the vertical direction Z is set as the reference (0°).

The inclination angle of the third insulating side wall 58 may be less than the inclination angle of the first wiring side wall 55 or may be larger than the inclination angle of the first wiring side wall 55. In this embodiment, the third insulating side wall 58 has the inclination angle substantially equal to the inclination angle of the first wiring side wall 55 and is formed substantially flush with the first wiring side wall 55.

The third side wall insulating film 53 covers the first wiring side wall 55 and the third insulating side wall 58 in a film shape conforming to an inclination angle of the first wiring side wall 55 and an inclination angle of the third insulating side wall 58. The third side wall insulating film 53 has the film surface inclined obliquely with respect to the vertical line in the covering portion with respect to the first wiring side wall 55 and the film surface inclined obliquely with respect to the vertical line in the covering portion with respect to the third insulating side wall 58.

With reference to FIG. 11D (the fifth example), in this embodiment, the second planar insulating film 52 has a third arcuate corner portion. The third arcuate corner portion connects the second insulating surface 57 and the third insulating side wall 58 in a circular arc shape.

The third side wall insulating film 53 covers the first wiring side wall 55 in a film shape conforming to the inclination angle of the first wiring side wall 55 and covers the third arcuate corner portion in an arcuate film shape conforming to an arcuate surface of the third arcuate corner portion. The third side wall insulating film 53 may have a film thickness that gradually increases from the second insulating surface 57 side toward the gate wiring 51 side in a covering portion with respect to the third arcuate corner portion.

With reference to FIG. 11E (the sixth example), in this embodiment, the second planar insulating film 52 is laminated on the gate wiring 51 such as to protrude from a position on the gate wiring 51 to a region outside the gate wiring 51 in the horizontal direction (the second direction Y). In this embodiment, the second planar insulating film 52 has the third insulating side wall 58 projecting in the horizontal direction (the second direction Y) from the first wiring side wall 55.

That is, the second planar insulating film 52 has a third overhang portion protruding from a position on the gate wiring 51 toward the inner side of the active region 8. The third overhang portion is demarcated by the rear surface of the second planar insulating film 52 and the third insulating side wall 58 and faces the main surface insulating film 44 without interposition of the gate wiring 51 in the lamination direction. The third insulating side wall 58 is connected to the first wiring side wall 55 via the rear surface of the second planar insulating film 52.

The third side wall insulating film 53 covers the first wiring side wall 55 and the third insulating side wall 58 in a film shape conforming to an inclination angle of the first wiring side wall 55 and an inclination angle of the third insulating side wall 58. The third side wall insulating film 53 may have a portion covering the rear surface of the second planar insulating film 52. The third side wall insulating film 53 may have a recess recessed toward the gate wiring 51 (the first wiring side wall 55) from the covering portion with respect to the third insulating side wall 58 in the covering portion with respect to the first wiring side wall 55.

The first lower electrode film 71 (the first electrode film 74 and the second electrode film 75) of the source main electrode 70 may have a portion extending along the recess of the third side wall insulating film 53. In this case, either or both of the first electrode film 74 and the second electrode film 75 may face the main surface insulating film 44 with a portion of the third side wall insulating film 53 interposed therebetween.

In a case where a protrusion amount of the second planar insulating film 52 with respect to the gate wiring 51 is small, the third side wall insulating film 53 does not have to have the recess and may have a film surface continuously extending along the vertical line in both the covering portion with respect to the first wiring side wall 55 and the covering portion with respect to the third insulating side wall 58.

With reference to FIG. 11F (the seventh example), in this embodiment, the third side wall insulating film 53 covers the third insulating side wall 58 of the second planar insulating film 52 at an interval to the first main surface 3 (the main surface insulating film 44) side from the second insulating surface 57. In this embodiment, the third side wall insulating film 53 crosses the boundary portion between the first oxide film 59 and the second oxide film 60 and covers both the first oxide film 59 and the second oxide film 60 and exposes an upper end portion of the second oxide film 60 from the third insulating side wall 58.

In this embodiment, the first lower electrode film 71 of the source main electrode 70 has a portion directly covering an exposed portion of the third insulating side wall 58. Specifically, the first electrode film 74 has a portion directly covering the second oxide film 60 on the third insulating side wall 58. On the other hand, the second electrode film 75 has a portion covering the second oxide film 60 across the first electrode film 74 on the third insulating side wall 58.

With reference to FIG. 11G (the eighth example), in this embodiment, the third side wall insulating film 53 covers the third insulating side wall 58 at an interval to the first main surface 3 (the main surface insulating film 44) side from the boundary portion between the first oxide film 59 and the second oxide film 60 and exposes both the first oxide film 59 and the second oxide film 60 from the third insulating side wall 58.

In this embodiment, the first lower electrode film 71 of the source main electrode 70 has a portion directly covering an exposed portion of the third insulating side wall 58. Specifically, the first electrode film 74 has a portion directly covering both the first oxide film 59 and the second oxide film 60 on the third insulating side wall 58. On the other hand, the second electrode film 75 has a portion covering both the first oxide film 59 and the second oxide film 60 across the first electrode film 74 on the third insulating side wall 58.

With reference to FIG. 11H (the ninth example), in this embodiment, the third side wall insulating film 53 has a projecting portion projecting further upward than the second insulating surface 57. The projecting portion has a projection amount less than the thickness of the second planar insulating film 52. The projection amount of the projecting portion is less than the thickness of the first oxide film 59. The projection amount of the projecting portion is less than the thickness of the second oxide film 60. The projection amount of the projecting portion may be less than the thickness of the third side wall insulating film 53. The projection amount of the projecting portion may be larger than the thickness of the third side wall insulating film 53.

In this embodiment, the first lower electrode film 71 of the source main electrode 70 has a portion directly covering the projecting portion of the third side wall insulating film 53. Specifically, the first electrode film 74 has the portion directly covering the projecting portion of the third side wall insulating film 53. On the other hand, the second electrode film 75 has a portion covering the projecting portion of the third side wall insulating film 53 across the first electrode film 74.

With reference to FIG. 11I (the tenth example), in this embodiment, the third side wall insulating film 53 has a laminated structure including a plurality of insulating films. The number of laminated insulating films may be two, three, four, or five. The third side wall insulating film 53 may include, as the plurality of insulating films, at least one among a silicon oxide film, a silicon nitride film, and a silicon oxynitride film. The silicon oxide film may be any one among an NSG film, a TEOS film, a PSG film, and a BPSG film.

Each of the plurality of insulating films may have a thickness of not less than 0.05 μm and not more than 0.5 μm. The thickness of the plurality of insulating films may have a value falling within at least one of ranges of not less than 0.05 μm and not more than 0.1 μm, not less than 0.1 μm and not more than 0.15 μm, not less than 0.15 μm and not more than 0.2 μm, not less than 0.2 μm and not more than 0.25 μm, not less than 0.25 μm and not more than 0.3 μm, not less than 0.3 μm and not more than 0.35 μm, not less than 0.35 μm and not more than 0.4 μm, not less than 0.4 μm and not more than 0.45 μm, and not less than 0.45 μm and not more than 0.5 μm.

FIG. 11I shows an example in which the third side wall insulating film 53 has a laminated structure (a two-layer structure) including a first insulating film 97 and a second insulating film 98. The first insulating film 97 covers the first wiring side wall 55 on the main surface insulating film 44. The first insulating film 97 may have a lower end portion extending in the horizontal direction on the main surface insulating film 44. The first insulating film 97 covers the first wiring side wall 55 and the third insulating side wall 58 in a film shape conforming to the inclination angle of the first wiring side wall 55 and the inclination angle of the third insulating side wall 58.

In this embodiment, the first insulating film 97 is led out from the first wiring side wall 55 toward the third insulating side wall 58 and has a portion covering the first wiring side wall 55 and a portion covering the third insulating side wall 58. The first insulating film 97 has a portion covering the boundary portion between the gate wiring 51 and the second planar insulating film 52.

The first insulating film 97 covers the first wiring side wall 55 and the third insulating side wall 58 in a film shape conforming to the inclination angle of the first wiring side wall 55 and the inclination angle of the third insulating side wall 58. The first insulating film 97 has a film surface extending at an inclination angle substantially equal to the inclination angle of the first wiring side wall 55 in a covering portion with respect to the first wiring side wall 55 and extending substantially parallel to the first wiring side wall 55. Also, the first insulating film 97 has a film surface extending at an inclination angle substantially equal to the inclination angle of the third insulating side wall 58 in a covering portion with respect to the third insulating side wall 58 and extending substantially parallel to the third insulating side wall 58.

The first insulating film 97 covers both the first oxide film 59 and the second oxide film 60 on the third insulating side wall 58. The first insulating film 97 has a portion covering the boundary portion between the first oxide film 59 and the second oxide film 60. The first insulating film 97 is formed on the first main surface 3 side with respect to the second insulating surface 57 and exposes the second insulating surface 57. The first insulating film 97 exposes the second oxide film 60 from the second insulating surface 57.

The second insulating film 98 covers the first wiring side wall 55 across the first insulating film 97 on the main surface insulating film 44. The second insulating film 98 has a lower end portion positioned on the lower end portion of the first insulating film 97. The lower end portion of the second insulating film 98 faces the main surface insulating film 44 with the lower end portion of the first insulating film 97 interposed therebetween. The lower end portion of the second insulating film 98 may be directly connected to the main surface insulating film 44.

In this embodiment, the second insulating film 98 is led out from the first wiring side wall 55 toward the third insulating side wall 58 and covers the third insulating side wall 58 across the first insulating film 97. The second insulating film 98 has a portion covering the first wiring side wall 55 across the first insulating film 97 and a portion covering the third insulating side wall 58 across the first insulating film 97. The second insulating film 98 has a portion covering the boundary portion between the gate wiring 51 and the second planar insulating film 52 across the first insulating film 97.

The second insulating film 98 covers the first wiring side wall 55 and the third insulating side wall 58 in a film shape conforming to the inclination angle of the first wiring side wall 55 and the inclination angle of the third insulating side wall 58. The second insulating film 98 has a film surface extending at an inclination angle substantially equal to the inclination angle of the first wiring side wall 55 in a covering portion with respect to the first wiring side wall 55 and extending substantially parallel to the first wiring side wall 55. Also, the second insulating film 98 has a film surface extending at an inclination angle substantially equal to the inclination angle of the third insulating side wall 58 in a covering portion with respect to the third insulating side wall 58 and extending substantially parallel to the third insulating side wall 58.

The second insulating film 98 covers both the first oxide film 59 and the second oxide film 60 across the first insulating film 97 on the third insulating side wall 58. The second insulating film 98 has a portion covering the boundary portion between the first oxide film 59 and the second oxide film 60 across the first insulating film 97. The second insulating film 98 is formed on the first main surface 3 side with respect to the second insulating surface 57 of the second planar insulating film 52 and exposes the second insulating surface 57. The second insulating film 98 exposes the second oxide film 60 from the second insulating surface 57.

As described above, the semiconductor device 1A includes the chip 2, the plurality of gate structures 20 of the planar type, the source opening 65 (the opening), and the source main electrode 70 (the main electrode). The chip 2 has the first main surface 3. The plurality of gate structures 20 are arranged at intervals on the first main surface 3. Each of the plurality of gate structures 20 includes the gate insulating film 21, the gate electrode 22, and the side wall insulating films 24 and 25. The gate insulating film 21 covers the first main surface 3. The gate electrode 22 is arranged on the gate insulating film 21. The side wall insulating films 24 and 25 cover the side walls of the gate electrode 22.

The source openings 65 are demarcated by the plurality of side wall insulating films 24 and 25 in regions between the plurality of gate structures 20 and expose the first main surface 3. The source main electrode 70 is mechanically connected to the plurality of side wall insulating films 24 and 25 in the source openings 65 and is electrically connected to the first main surface 3 in the source openings 65.

According to this arrangement, the semiconductor device 1A capable of improving the electrical characteristics is provided. For example, according to the semiconductor device 1A, the plurality of gate structures 20 are aligned at a narrow pitch, the current path per unit area can be increased. Thereby, the on resistance is reduced.

The chip 2 preferably contains SiC. According to this arrangement, the semiconductor device 1A as an SiC semiconductor device is provided. The side wall insulating films 24 and 25 may have film surfaces covering the side walls of the gate electrode 22 in a film shape in cross-sectional view and extending along the side walls of the gate electrode 22. According to this arrangement, since an area occupied by the side wall insulating films 24 and 25 is decreased, the opening width W of the source opening 65 is reduced. Thereby, the plurality of gate structures 20 is appropriately aligned at a narrow pitch.

The side wall insulating films 24 and 25 may cover the side walls of the gate electrode 22 on the gate insulating film 21. According to this arrangement, since formation locations of the side wall insulating films 24 and 25 are limited on the gate insulating film 21, the side wall insulating films 24 and 25 are prevented from extending to a region outside the gate insulating film 21. Thereby, the pitch of the plurality of gate structures 20 is prevented from being increased due to the area occupied by the side wall insulating films 24 and 25.

Each of the side wall insulating films 24 and 25 preferably has a thickness less than the thickness of the gate electrode 22. Each of the side wall insulating films 24 and 25 preferably has the single layer structure constituted of a single insulating film. Each of the side wall insulating films 24 and 25 is preferably constituted of an undoped oxide film as the single insulating film. According to these arrangements, the area occupied by the side wall insulating films 24 and 25 can be reduced.

Each of the plurality of gate structures 20 may include the first planar insulating film 23 arranged on the gate electrode 22. According to this arrangement, an insulating property with respect to the gate electrode 22 is improved. In this case, the side wall insulating films 24 and 25 may cover the side walls of the gate electrode 22 and the side walls of the first planar insulating film 23. According to this arrangement, the insulating property with respect to the gate electrode 22 is improved.

In this case, the source main electrode 70 may have a portion facing the gate electrode 22 in the lamination direction with the first planar insulating film 23 interposed therebetween and may be electrically disconnected from the gate electrode 22 by the first planar insulating film 23. According to this arrangement, in the layout in which the plurality of gate structures 20 are aligned at a narrow pitch, the source main electrode 70 is appropriately electrically disconnected from the plurality of gate structures 20 by the first planar insulating films 23.

The first planar insulating film 23 may have a laminated structure including a plurality of insulating films. In this case, the side wall insulating films 24 and 25 may cover the plurality of insulating films on the side walls of the first planar insulating film 23. The first planar insulating film 23 may include, as the plurality of insulating films, the undoped first oxide film 32 covering the gate electrode 22, and the second oxide film 33 containing phosphorus and covering the first oxide film 32.

The source opening 65 may have a width of not less than the thickness of the side wall insulating film 24, 25. The source opening 65 may have a width of not more than the width of the gate electrode 22. The width of the source opening 65 may be not less than one time and not more than five times the thickness of the side wall insulating film 24, 25. The thickness the side wall insulating film 24, 25 may be not less than 0.05 μm and not more than 0.5 μm. The width of the source opening 65 may be not less than 0.2 μm and not more than 0.6 μm.

The source main electrode 70 may have a laminated structure including the first embedded electrode 72 and the first upper electrode film 73. The first embedded electrode 72 is electrically connected to the first main surface 3 in the source opening 65. The first upper electrode film 73 is electrically connected to the first main surface 3 on the first embedded electrode 72 via the first embedded electrode 72.

In a case where the plurality of gate structures 20 are aligned at a narrow pitch, the width of the source opening 65 is reduced due to the layout of the plurality of gate structures 20. In this case, concerns arise regarding the embeddability and film formability of the source main electrode 70 with respect to the source opening 65.

In this respect, the source main electrode 70 including the first embedded electrode 72 and the first upper electrode film 73 prevents a decrease in the embeddability and the film formability of the first upper electrode film 73 with respect to the plurality of source openings 65, since the level difference due to the source openings 65 is moderated by the first embedded electrodes 72. Therefore, the source main electrode 70 can be appropriately electrically connected to the first main surface 3.

The semiconductor device 1A may include the first silicide portions 81 formed in portions in the first main surface 3 exposed from the source openings 65. According to this arrangement, the source main electrode 70 can be electrically connected to the chip 2 via the first silicide portions 81. Thereby, an ohmic property of the source main electrode 70 with respect to the chip 2 can be improved.

The semiconductor device 1A may include the second semiconductor region 11 (the semiconductor region) of the n-type, the body region 12 of the p-type, the source regions 14 and 15 (the impurity regions) of the n-type, and the channel regions 17 and 18 (the channels) of the p-type.

The second semiconductor region 11 may be formed in the surface layer portion of the first main surface 3. The body region 12 may be formed in the surface layer portion of the second semiconductor region 11. The source regions 14 and 15 may be formed in the surface layer portion of the body region 12. The channel regions 17 and 18 may be formed in a region between the second semiconductor region 11 and the source regions 14 and 15 in the surface layer portion of the body region 12.

In this case, the gate insulating film 21 may cover the channel regions 17 and 18. The gate electrodes 22 may face the channel regions 17 and 18 with the gate insulating film 21 interposed therebetween. The source openings 65 may expose the source regions 14 and 15. The source main electrode 70 may be electrically connected to the source regions 14 and 15 in the source opening 65.

The semiconductor device 1A may include the contact region 16 of the p-type. The contact region 16 may be formed in a region different from the source regions 14 and 15 in the surface layer portion of the body region 12. In this case, the source opening 65 may expose the source regions 14 and 15 and the contact region 16. The source main electrode 70 may be electrically connected to the source regions 14 and 15 and the contact region 16 in the source opening 65.

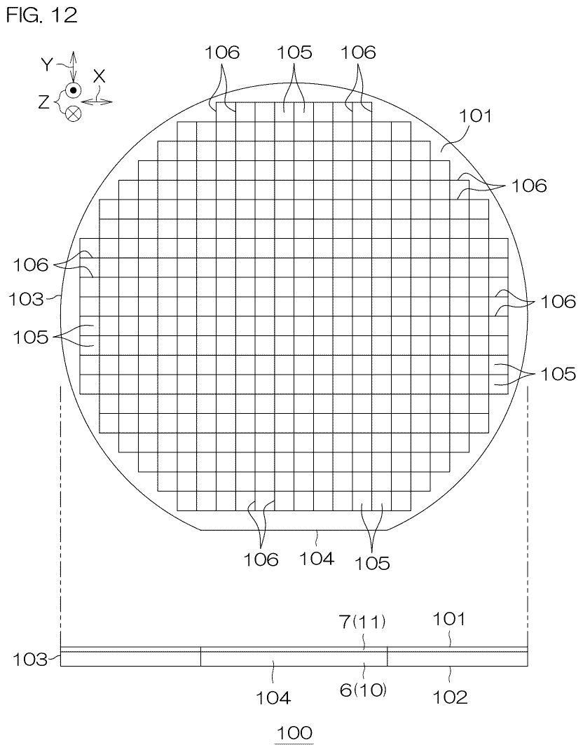

FIG. 12 is a schematic view showing a wafer 100 used in manufacture of the semiconductor device 1A. With reference to FIG. 12, the wafer 100 is a base material of the chip 2 and includes an SiC monocrystal. The wafer 100 is formed in a flat disc shape. The wafer 100 may be formed in a flat rectangular parallelepiped shape.

The wafer 100 has a first wafer main surface 101 at one side, a second wafer main surface 102 on the other side, and a wafer side surface 103 that connects the first wafer main surface 101 and the second wafer main surface 102. The first wafer main surface 101 corresponds to the first main surface 3 of the chip 2, and the second wafer main surface 102 corresponds to the second main surface 4 of the chip 2.

The first wafer main surface 101 and the second wafer main surface 102 are formed by c-planes of the SiC monocrystal. The first wafer main surface 101 is formed by a silicon plane of the SiC monocrystal and the second wafer main surface 102 is formed by a carbon plane of the SiC monocrystal. The wafer 100 (the first wafer main surface 101 and the second wafer main surface 102) has the off direction and the off angle described above.

The wafer 100 has, on the wafer side surface 103, a mark 104 that indicates a crystal orientation of the SiC monocrystal. The mark 104 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer main surface 101 in plan view.

The mark 104 may include either or both of a first orientation flat that extends in the m-axis direction and a second orientation flat that extends in the a-axis direction. The mark 104 may include either or both of an orientation notch that is recessed in the m-axis direction and an orientation notch that is recessed in the a-axis direction.

In this embodiment, the wafer 100 has the laminated structure including the first semiconductor layer 6 and the second semiconductor layer 7. The first semiconductor layer 6 is constituted of a semiconductor wafer (an SiC wafer) containing an SiC monocrystal (a semiconductor monocrystal) and has the off direction and the off angle described above. The first semiconductor layer 6 forms the second wafer main surface 102 and the wafer side surface 103.

The second semiconductor layer 7 is constituted of an epitaxial layer (an SiC epitaxial layer) containing an SiC monocrystal (a semiconductor monocrystal) and is laminated on the first semiconductor layer 6. That is, in this embodiment, the wafer 100 is constituted of an epitaxial wafer (a so-called epi-wafer) having a laminated structure including the semiconductor wafer and the epitaxial layer. The second semiconductor layer 7 has the off direction and the off angle described above. The second semiconductor layer 7 forms the first wafer main surface 101 and the wafer side surface 103.

The wafer 100 includes the first semiconductor region 10 in a region (a surface layer portion) on the second wafer main surface 102 side. The first semiconductor region 10 is formed in a layer shape extending along the second wafer main surface 102. In this embodiment, the first semiconductor region 10 is formed by the first semiconductor layer 6.

The wafer 100 includes the second semiconductor region 11 in a region (a surface layer portion) on the first wafer main surface 101 side. The second semiconductor region 11 is formed in a layer shape extending along the first wafer main surface 101 and is electrically connected to the first semiconductor region 10. In this embodiment, the second semiconductor region 11 is formed by the second semiconductor layer 7.

The wafer 100 includes a plurality of device regions 105 and a plurality of intended cutting lines 106. For example, the plurality of device regions 105 and the plurality of intended cutting lines 106 are demarcated by alignment marks, etc., formed on the first wafer main surface 101 side. Each of the device regions 105 is a region corresponding to the semiconductor device 1A. The plurality of device regions 105 are each set in a quadrangular shape in plan view.

In this embodiment, the plurality of device regions 105 are set in a matrix along the first direction X and the second direction Y in plan view. The plurality of device regions 105 are respectively set at intervals inward from peripheral edges of the first wafer main surface 101 in plan view. The plurality of intended cutting lines 106 are set in a lattice that extends along the first direction X and the second direction Y such as to demarcate the plurality of device regions 105.

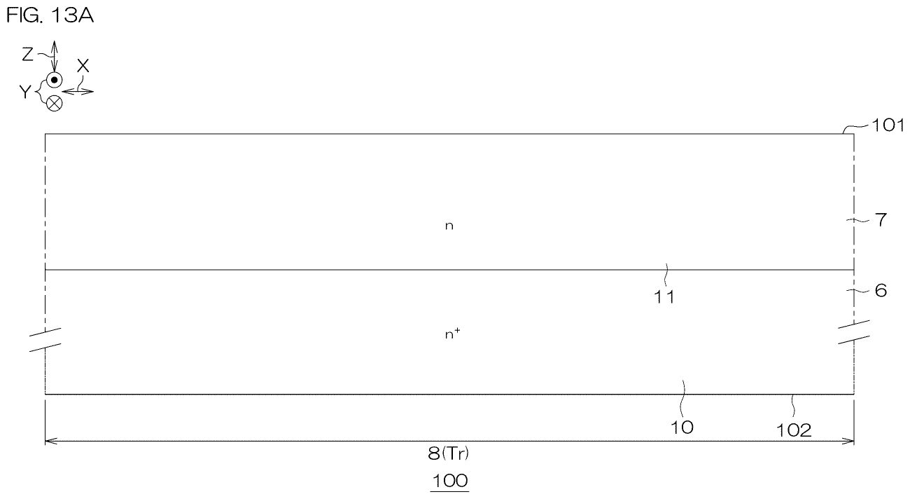

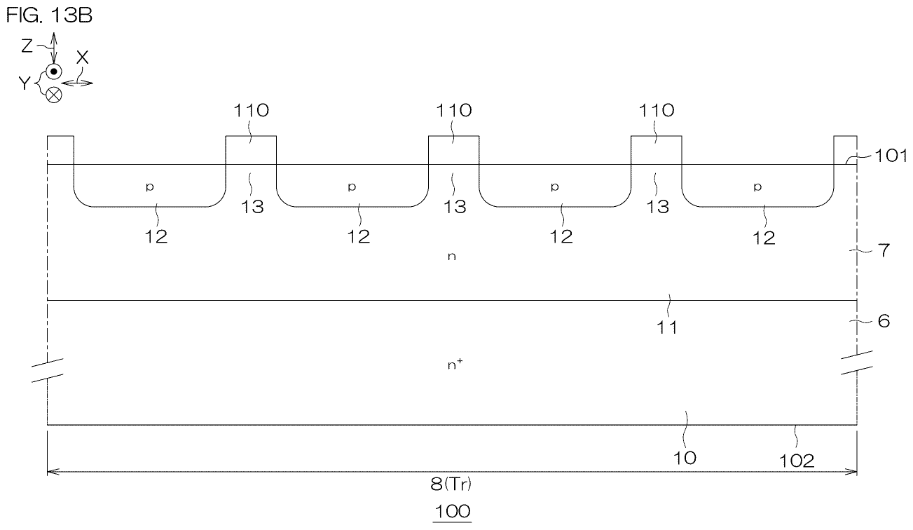

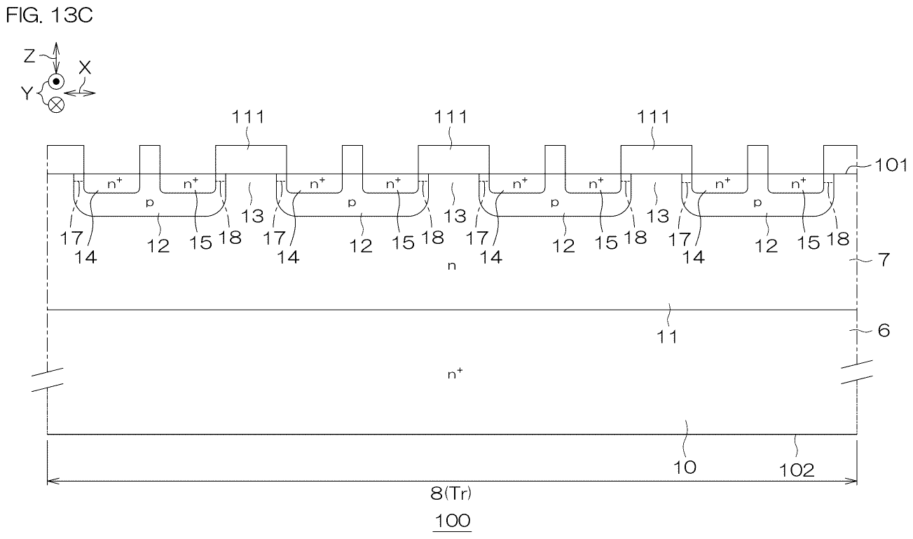

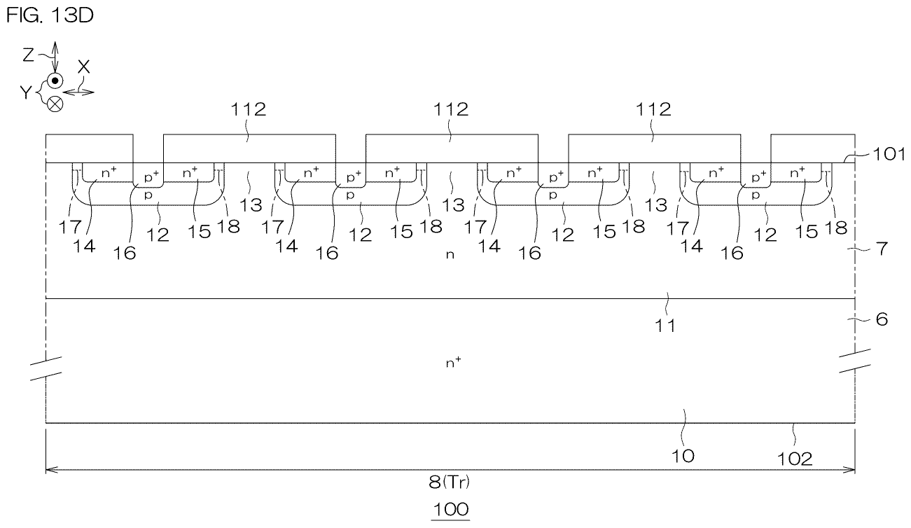

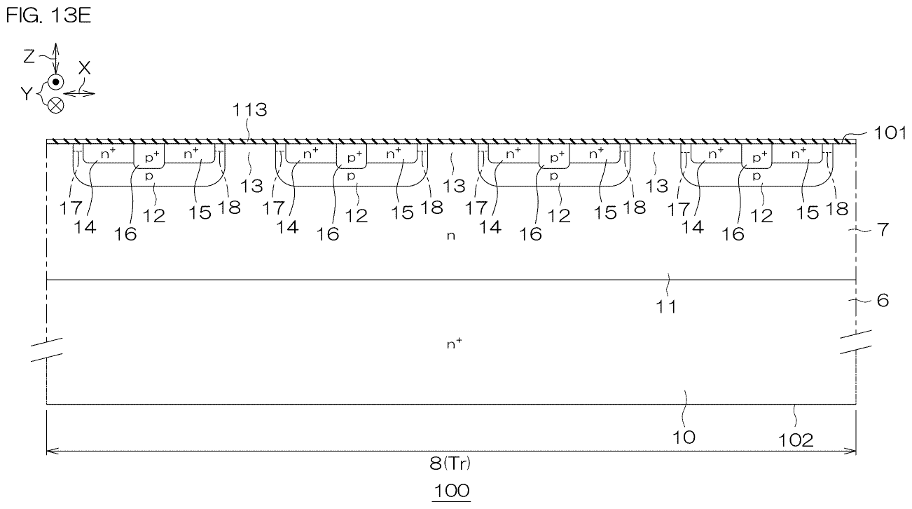

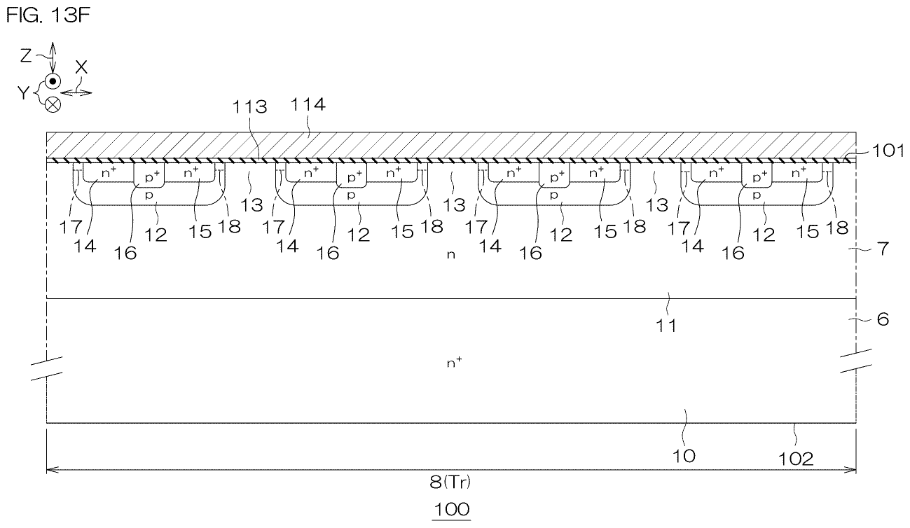

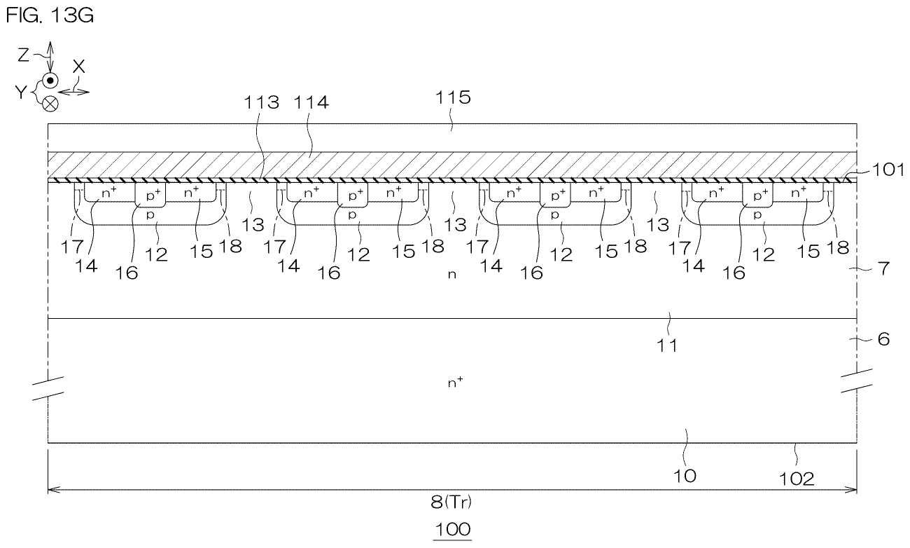

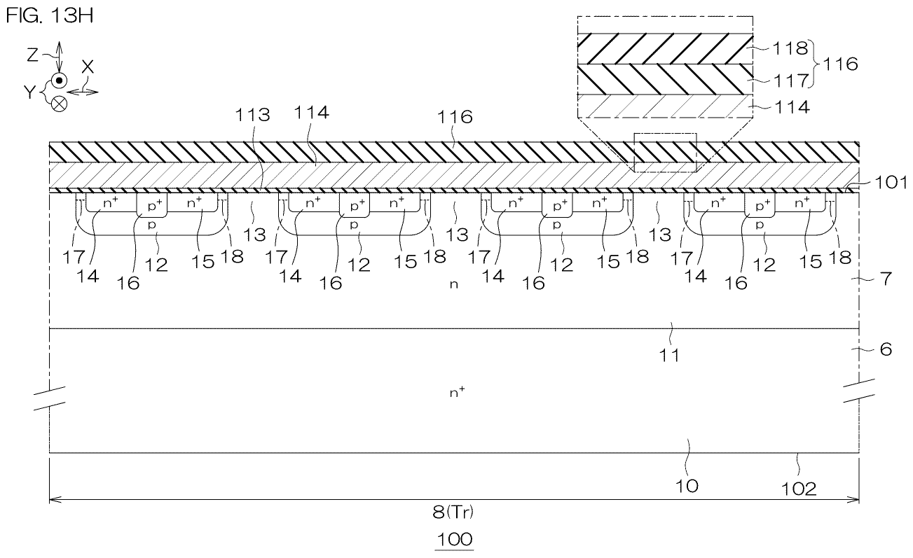

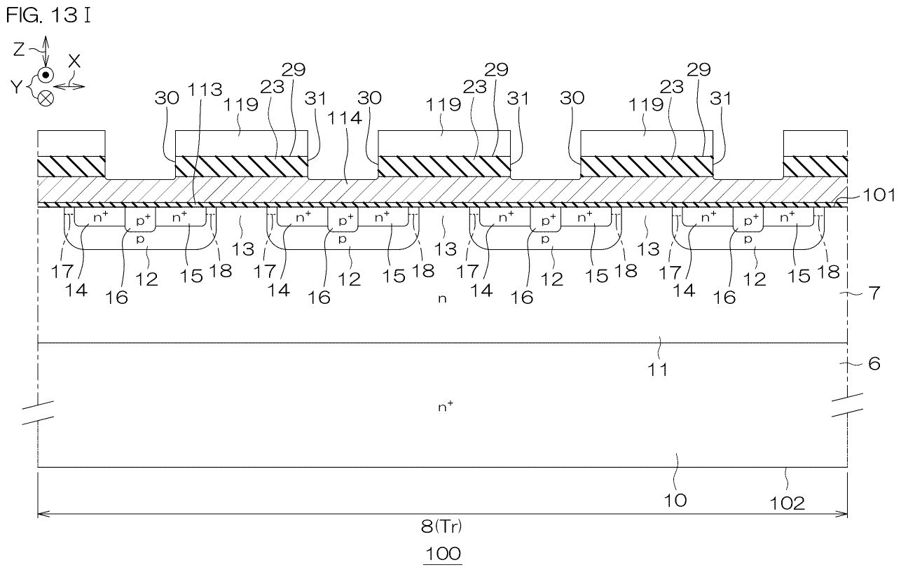

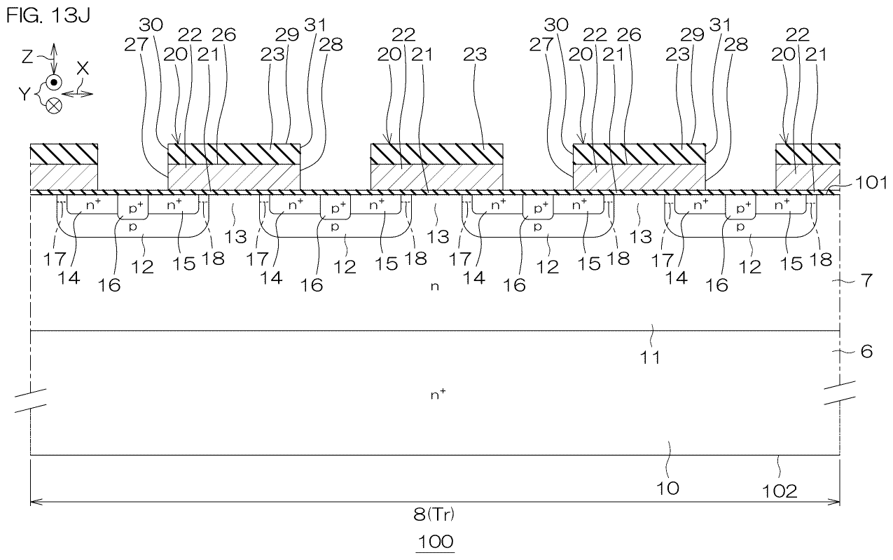

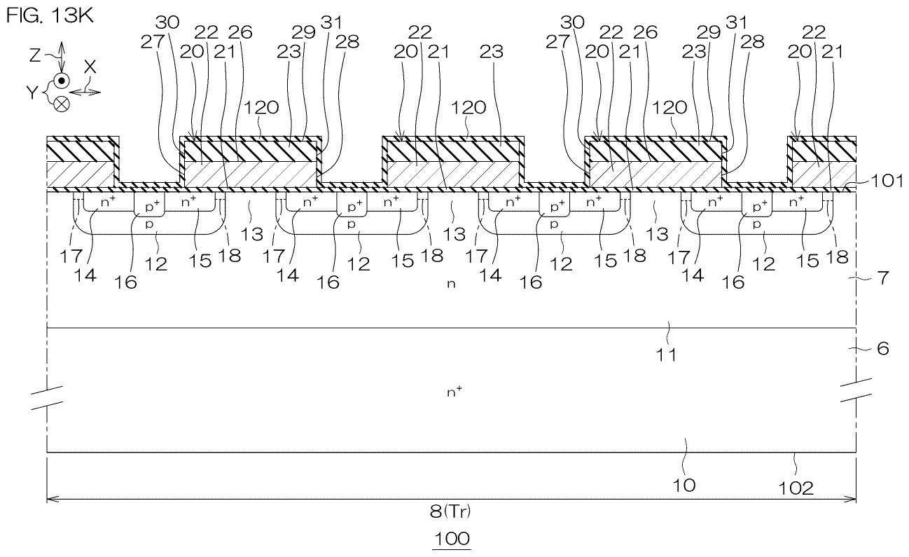

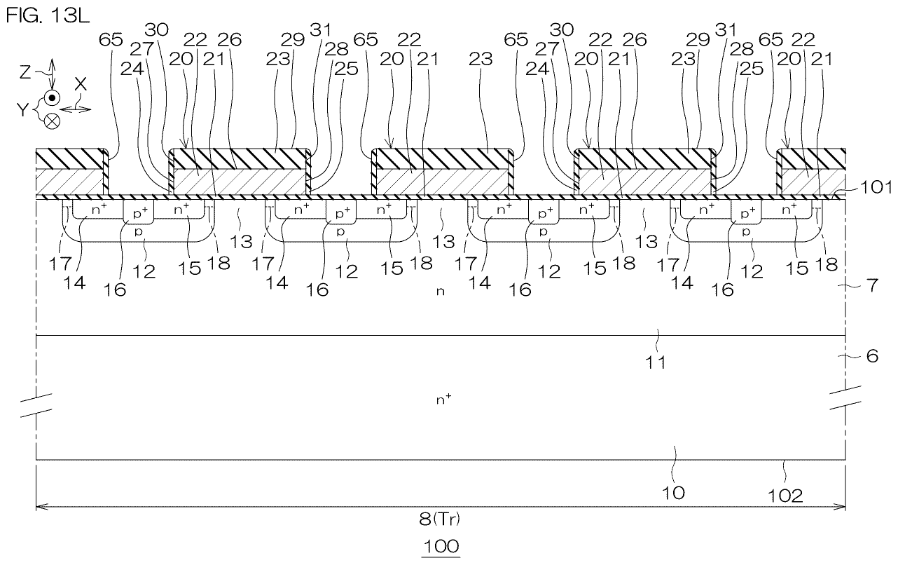

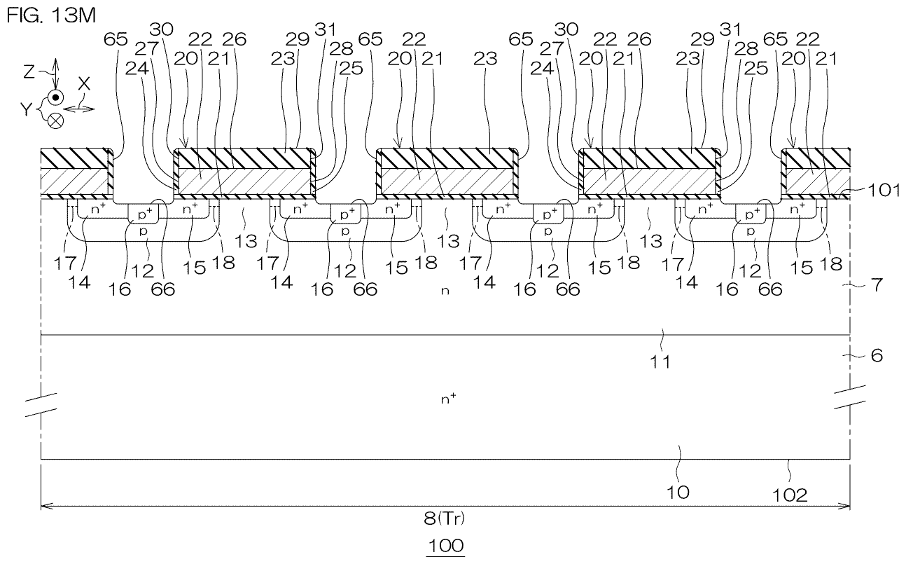

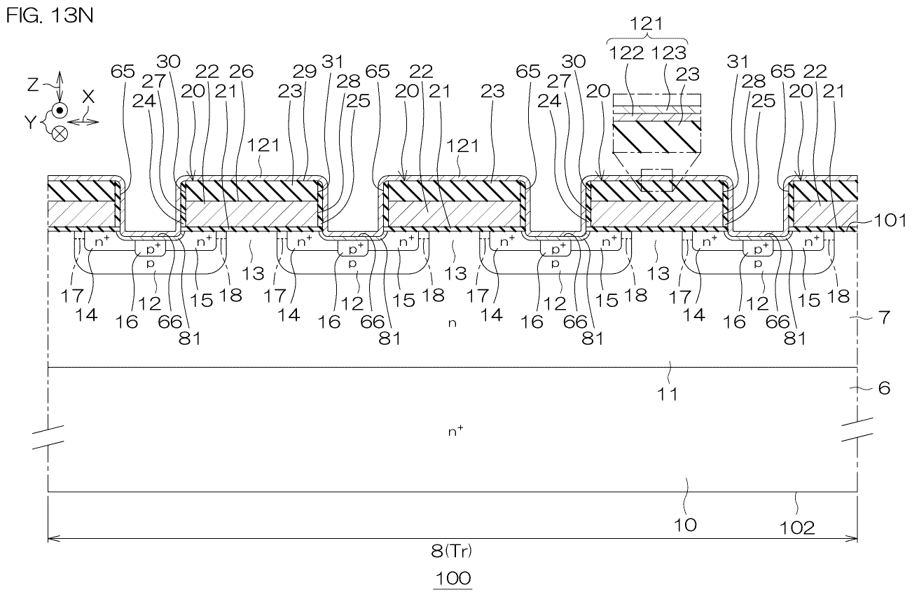

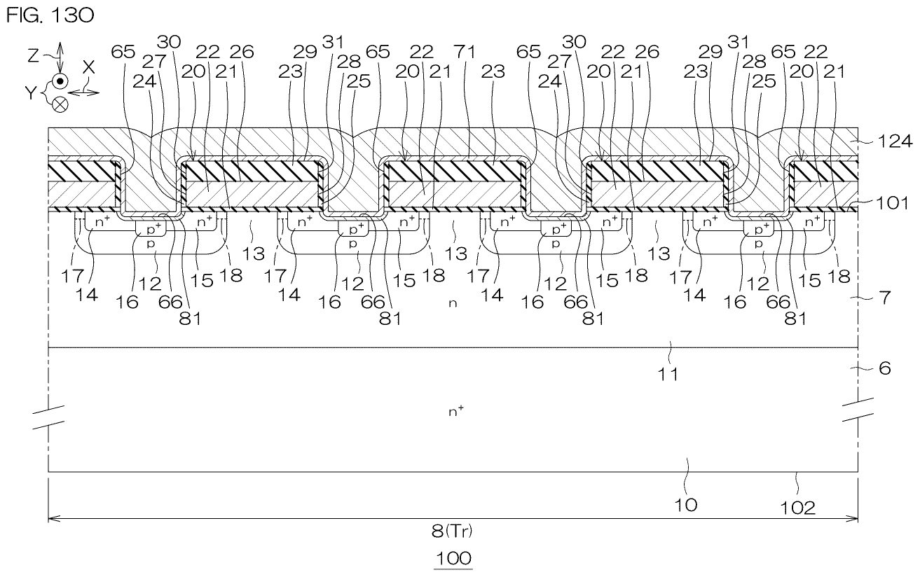

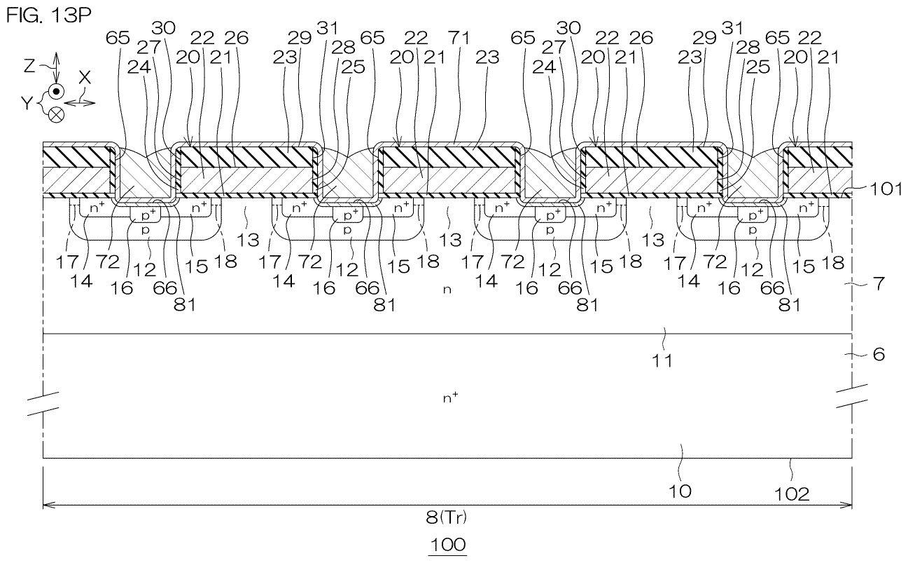

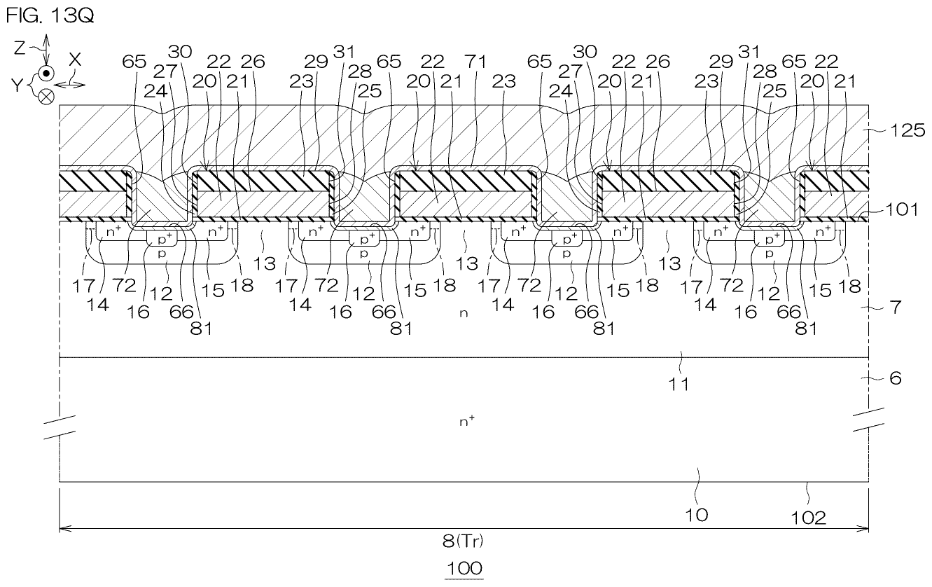

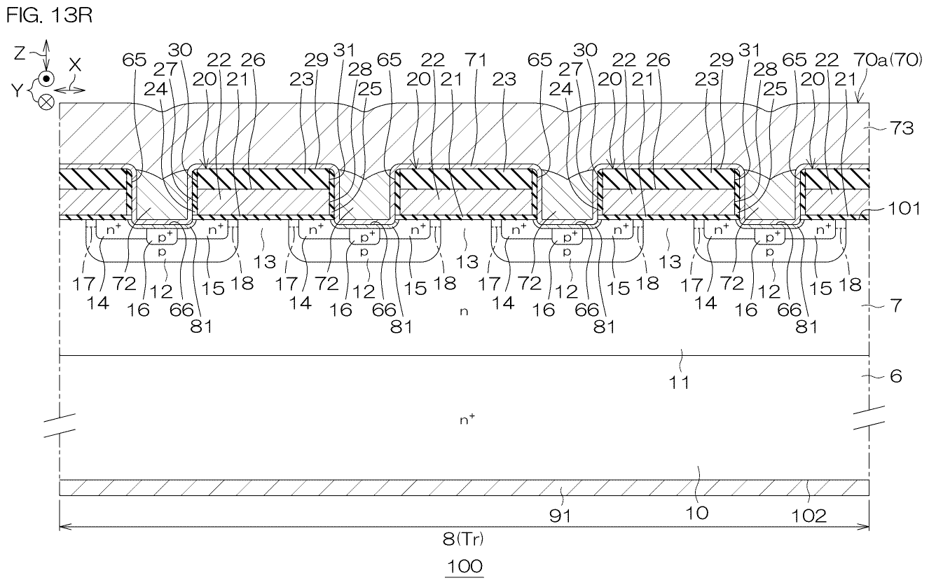

FIG. 13A to FIG. 13R are cross-sectional views showing a method for manufacturing the semiconductor device 1A. FIG. 13A to FIG. 13R are cross-sectional views of a region corresponding that in FIG. 6. With reference to FIG. 13A, first, a preparation step of the wafer 100 described above (see FIG. 12) is performed.

Next, with reference to FIG. 13B, a forming step of the plurality of body regions 12 and the outer body region 40 is performed. In this step, first, a first mask 110 having a predetermined layout is formed on the first wafer main surface 101.

The first mask 110 may include either or both of an inorganic mask (a so-called hard mask) and an organic mask (a so-called soft mask). The first mask 110 exposes regions in which the plurality of body regions 12 and the outer body region 40 are to be formed and covers regions other than these.

Next, the p-type impurities (the trivalent element) are implanted into the surface layer portion of the second semiconductor region 11 by an ion implantation method via the first mask 110. The p-type impurities (the trivalent element) are preferably aluminum. Thereby, the plurality of body regions 12 and the outer body region 40 are formed. Thereafter, the first mask 110 is removed.

Next, with reference to FIG. 13C, a forming step of the plurality of source regions 14 and 15 is performed. In this step, first, a second mask 111 having a predetermined layout is formed on the first wafer main surface 101. The second mask 111 may include either or both of an inorganic mask (a so-called hard mask) and an organic mask (a so-called soft mask). The second mask 111 exposes regions in which the plurality of source regions 14 and 15 are to be formed and covers regions other than these.

Next, the n-type impurities (the pentavalent element) are implanted into the surface layer portions of the body regions 12 by the ion implantation method via the second mask 111. The n-type impurities (the pentavalent element) are preferably phosphorus. Thereby, the plurality of source regions 14 and 15 are formed. Thereafter, the second mask 111 is removed.

Next, with reference to FIG. 13D, a forming step of the plurality of contact regions 16 is performed. In this step, first, a third mask 112 having a predetermined layout is formed on the first wafer main surface 101. The third mask 112 may include either or both of an inorganic mask (a so-called hard mask) and an organic mask (a so-called soft mask). The third mask 112 exposes regions in which the plurality of contact regions 16 are to be formed and covers regions other than these.

Next, the p-type impurities (the trivalent element) are implanted into the surface layer portion of the body regions 12 by the ion implantation method via the third mask 112. The p-type impurities (the trivalent element) are preferably aluminum. Thereby, the plurality of contact regions 16 is formed. After the forming step of the contact regions 16, the third mask 112 is removed.

Although specific illustration shall be omitted, the terminal region 41 is formed by introducing the p-type impurities (the trivalent element) into the surface layer portion of the second semiconductor region 11 by the ion implantation method via a mask (not shown) having a predetermined layout. A forming step of the terminal region 41 may be performed after the forming step of the body regions 12 (the outer body region 40) or may be performed before the forming step of the body regions 12 (the outer body region 40).

Similarly, the plurality of field regions 43 are formed by introducing the p-type impurities (the trivalent element) into the surface layer portion of the second semiconductor region 11 by the ion implantation method via a mask (not shown) having a predetermined layout. The forming step of the field regions 43 may be performed after the forming step of the body regions 12 (the outer body region 40) or may be performed before the forming step of the body regions 12 (the outer body region 40).

The order of the forming step of the body regions 12 (the outer body region 40), the forming step of the source regions 14 and 15, the forming step of the contact regions 16, the forming step of the terminal region 41, and the forming step of the field regions 43 is arbitrary and may be interchanged as appropriate.

Next, with reference to FIG. 13E, a forming step of a lower base insulating film 113 (a lower insulating film) is performed. The lower base insulating film 113 becomes a base of the plurality of gate insulating films 21 and the main surface insulating film 44. The lower base insulating film 113 is formed in a film shape on the first wafer main surface 101. The gate insulating film 21 may be formed by a CVD (chemical vapor deposition) method or an oxidation processing method (for example, a thermal oxidation processing method).

Next, with reference to FIG. 13F, a forming step of a base gate electrode 114 is performed. The base gate electrode 114 becomes a base of the plurality of gate electrodes 22. The base gate electrode 114 is formed in a film shape on the lower base insulating film 113. The base gate electrode 114 may be formed by the CVD method.

Next, with reference to FIG. 13G, a first patterning step (a preprocessing step) of the base gate electrode 114 is performed. In this step, first, a fourth mask 115 having a predetermined layout is formed on the base gate electrode 114. The fourth mask 115 covers a covering portion of the base gate electrode 114 with respect to the active region 8 and selectively exposes a covering portion of the base gate electrode 114 with respect to the outer peripheral region 9.

Next, unnecessary portions of the base gate electrode 114 (the covering portion with respect to the outer peripheral region 9) are removed by the etching method via the fourth mask 115. The unnecessary portions of the base gate electrode 114 are removed until the lower base insulating film 113 is exposed.

The etching method may be either or both of a wet etching method and a dry etching method. By this step, an outer edge portion of the base gate electrode 114 as the second wiring side wall 56 of the gate wiring 51 is formed on the outer peripheral region 9 (see also FIG. 8 and FIG. 9).

Next, with reference to FIG. 13H, a forming step of an upper base insulating film 116 (an upper insulating film) is performed. The upper base insulating film 116 is a base of the plurality of first planar insulating films 23, the second planar insulating film 52, and the outer insulating film 61.

In this embodiment, the upper base insulating film 116 includes a first base oxide film 117 and a second base oxide film 118. The first base oxide film 117 becomes a base of the plurality of first oxide films 32 and 59. The second base oxide film 118 becomes a base of the plurality of second oxide films 33 and 60.

In this embodiment, the first base oxide film 117 is constituted of the NSG film and is laminated in a film shape on the lower base insulating film 113 and the base gate electrode 114. The first base oxide film 117 may be formed by the CVD method.

The second base oxide film 118 includes a silicon oxide film containing phosphorus and is laminated in a film shape on the first base oxide film 117. The second base oxide film 118 is formed by the CVD method. After the forming step of the second base oxide film 118, a reflow step (a heat treatment step) is performed. Thereby, the upper base insulating film 116 is smoothened.

Next, with reference to FIG. 13I, a forming step of the plurality of first planar insulating films 23, the second planar insulating film 52, the outer insulating film 61, the plurality of outer openings 67, and the plurality of gate openings 69 is performed. This step is also a patterning step of the upper base insulating film 116.

In this step, first, a fifth mask 119 having a predetermined layout is formed on the upper base insulating film 116. The fifth mask 119 covers regions of the upper base insulating film 116 in which the plurality of first planar insulating films 23, the second planar insulating film 52, and the outer insulating film 61 are to be formed, and exposes regions in which the plurality of outer openings 67 and the plurality of gate openings 69 are to be formed.

Next, unnecessary portions of the upper base insulating film 116 are removed by the etching method via the fifth mask 119. The unnecessary portions of the upper base insulating film 116 are removed until the base gate electrode 114 is exposed. The etching method may be either or both of a wet etching method and a dry etching method.

The wet etching method may be isotropic or may be anisotropic. The dry etching method may be isotropic or may be anisotropic. By this step, the plurality of first planar insulating films 23, the second planar insulating film 52, the outer insulating film 61, the plurality of outer openings 67, and the plurality of gate openings 69 are formed.

An etching step performed on the plurality of outer openings 67 may include a step of digging a portion of the first wafer main surface 101 toward the second wafer main surface 102. In this step, the plurality of outer recesses 68 are formed in portions of the first wafer main surface 101 exposed from the plurality of outer openings 67. Thereafter, the fifth mask 119 is removed.

The arrangements of the first planar insulating films 23 according to the first to eleventh examples described above (see FIGS. 7 and 10A to 10J) and the arrangements of the second planar insulating films 52 according to the first to tenth examples described above (see FIG. 9 and FIG. 11A to FIG. 11I) are obtained by a step of adjusting, as appropriate, etching processing conditions for the upper base insulating film 116.

Next, with reference to FIG. 13J, a second patterning step (a post-processing step) of the base gate electrode 114 is performed. The second patterning step of the base gate electrode 114 is also a forming step of the plurality of gate electrodes 22 and the gate wiring 51. In this step, unnecessary portions of the base gate electrode 114 are removed by the etching method via the plurality of first planar insulating films 23, the second planar insulating film 52, and the outer insulating film 61.

That is, in this step, a plurality of exposed portions of the base gate electrode 114 which are demarcated by the plurality of first planar insulating films 23 and the second planar insulating film 52 are removed. The unnecessary portions of the base gate electrode 114 may be removed by the etching method via the fifth mask 119 above described.

The unnecessary portions of the base gate electrode 114 are removed until the lower base insulating film 113 is exposed. The etching method may be either or both of a wet etching method and a dry etching method. The wet etching method may be isotropic or may be anisotropic. The dry etching method may be isotropic or may be anisotropic.

By this step, the plurality of gate electrodes 22 and the gate wiring 51 are formed on the lower base insulating film 113 (see also FIG. 6 to FIG. 9). In this step, the plurality of gate electrodes 22 are formed self-aligningly with respect to the plurality of first planar insulating films 23.

Thereby, the plurality of gate electrodes 22 respectively covered with the plurality of first planar insulating films 23 are formed on the lower base insulating film 113. Also, in this step, the gate wiring 51 is formed self-aligningly with respect to the second planar insulating film 52. Thereby, the gate wiring 51 covered with the second planar insulating film 52 is formed on the lower base insulating film 113.

The arrangements of the gate electrodes 22 according to the first to eleventh examples described above (see FIGS. 7 and 10A to 10J) and the arrangements of the gate wiring 51 according to the first to tenth examples described above (see FIG. 9 and FIG. 11A to FIG. 11I) are obtained by a step of adjusting, as appropriate, etching processing conditions for the base gate electrode 114.

Next, with reference to FIG. 13K, a forming step of a base side wall insulating film 120 is performed. The base side wall insulating film 120 becomes a base of the plurality of first side wall insulating films 24, the plurality of second side wall insulating films 25, and the plurality of third side wall insulating films 53. The base side wall insulating film 120 may include at least one among a silicon oxide film, a silicon nitride film, and a silicon oxynitride film.

The base side wall insulating film 120 may have a single layer structure constituted of a single insulating film. The base side wall insulating film 120 may have a laminated structure including a plurality of insulating films. In this embodiment, the base side wall insulating film 120 is constituted of the TEOS film as an example of the NSG film. The base side wall insulating film 120 may be formed by the CVD method.

The base side wall insulating film 120 collectively covers the plurality of gate electrodes 22, the plurality of first planar insulating films 23, the gate wiring 51, the second planar insulating film 52, and the outer insulating film 61 on the lower base insulating film 113.

Specifically, the base side wall insulating film 120 covers, in a film shape, the lower base insulating film 113, the first side wall 27 and the second side wall 28 of the gate electrode 22, the first insulating side wall 30 and the second insulating side wall 31 of the first planar insulating film 23, the first wiring side wall 55 of the gate wiring 51, the third insulating side wall 58 of the second planar insulating film 52, and the outer insulating film 61.

Next, with reference to FIG. 13L, a forming step of the plurality of first side wall insulating films 24, the plurality of second side wall insulating films 25, and the plurality of third side wall insulating films 53 is performed. In this step, unnecessary portions of the base side wall insulating film 120 are selectively removed by the etching method (an etch back method). The unnecessary portions of the base side wall insulating film 120 are portions of the base side wall insulating film 120 which extend in the horizontal direction. That is, in the base side wall insulating film 120, portions extending along the horizontal direction is removed such that portions extending along the vertical direction Z remain.

Specifically, in this step, the covering portion of the base side wall insulating film 120 with respect to the first insulating surface 29, the covering portion thereof with respect to the second insulating surface 57, and the covering portion thereof with respect to the insulating surface of the outer insulating film 61 are removed such that the covering portion thereof with respect to the first side wall 27 and the second side wall 28 of the gate electrode 22, the covering portion thereof with respect to the first insulating side wall 30 and the second insulating side wall 31 of the first planar insulating film 23, the covering portion thereof with respect to the first wiring side wall 55 of the gate wiring 51, and the covering portion thereof with respect to the third insulating side wall 58 of the second planar insulating film 52 remain.

The etching method may be either or both of a wet etching method and a dry etching method. The wet etching method is preferably anisotropic. The dry etching method is preferably anisotropic. The etching method is particularly preferably an RIE method (reactive ion etching method).

By this step, the plurality of first side wall insulating films 24, the plurality of second side wall insulating films 25, and the plurality of third side wall insulating films 53 are formed. The plurality of first side wall insulating films 24 and the plurality of second side wall insulating films 25 are formed self-aligningly with respect to the plurality of gate electrodes 22 (the plurality of first planar insulating films 23), and the plurality of third side wall insulating films 53 are formed self-aligningly with respect to the gate wiring 51 (the second planar insulating film 52).

Next, with reference to FIG. 13M, a forming step of the plurality of gate insulating films 21, the main surface insulating film 44, and the plurality of source openings 65 is performed. In this step, a plurality of exposed portions of the lower base insulating film 113 which are demarcated by the plurality of first side wall insulating films 24, the plurality of second side wall insulating films 25, and the plurality of third side wall insulating films 53 are removed by the etching method.

In this step, hidden portions of the lower base insulating film 113 hidden by the plurality of gate electrodes 22 (the plurality of first planar insulating films 23) remain as the plurality of gate insulating films 21. Also, a hidden portion of the lower base insulating film 113 hidden by the gate wiring 51 (the second planar insulating film 52) and the outer insulating film 61 remains as the main surface insulating film 44.

The etching method may be either or both of a wet etching method and a dry etching method. The wet etching method is preferably anisotropic. The dry etching method is preferably anisotropic. The etching method is particularly preferably the RIE method.

The etching step performed on the base side wall insulating film 120 described above may serve in common as an etching step performed on the lower base insulating film 113. In this case, the unnecessary portions of the base side wall insulating film 120 are removed simultaneously with unnecessary portions of the lower base insulating film 113. The etching step performed on the lower base insulating film 113 may be performed separately from the etching step performed on the base side wall insulating film 120 described above.

Thereby, the plurality of gate insulating films 21 and the main surface insulating film 44 are formed. Also, the plurality of source openings 65 that expose the first wafer main surface 101 are thereby formed. The etching step performed on the plurality of source openings 65 may include the step of digging a portion of the first wafer main surface 101 toward the second wafer main surface 102. In this step, the plurality of source recesses 66 are formed in portions of the first wafer main surface 101 exposed from the plurality of source openings 65.

Next, with reference to FIG. 13N, a forming step of a base lower electrode film 121 is performed. The base lower electrode film 121 is a base of the first lower electrode film 71 and the second lower electrode film 84. The base lower electrode film 121 has a laminated structure including a first base lower electrode film 122 and a second base lower electrode film 123. The first base lower electrode film 122 is a base of the first electrode film 74 and the first electrode film 87. The second base lower electrode film 123 is a base of the second electrode film 75 and the second electrode film 88.

In this embodiment, the first base lower electrode film 122 includes the Ti film. The first base lower electrode film 122 may be formed by a sputtering method or a vapor deposition method. The first base lower electrode film 122 is formed in a film shape along the first insulating surface 29, the second insulating surface 57, wall surfaces of the plurality of source openings 65, the wall surfaces of the plurality of outer openings 67, and the wall surfaces of the plurality of gate openings 69.

In this embodiment, the second base lower electrode film 123 includes the TiN film. The second base lower electrode film 123 may be formed by the sputtering method or the vapor deposition method. The second base lower electrode film 123 is formed in a film shape along the first insulating surface 29, the second insulating surface 57, the wall surfaces of the plurality of source openings 65, the wall surfaces of the plurality of outer openings 67, and the wall surfaces of the plurality of gate openings 69.

After the forming step of the first base lower electrode film 122, the first base lower electrode film 122 reacts with SiC of the first wafer main surface 101 (silicide reaction) and the plurality of first silicide portions 81 and the plurality of second silicide portions 82 is formed. The silicide reaction may be performed by an annealing method such as an RTA method.

A forming step of the first silicide portions 81 (the second silicide portions 82) may be performed prior to a forming step of the second base lower electrode film 123. The forming step of the first silicide portions 81 (the second silicide portions 82) may be performed after the forming step of the second base lower electrode film 123.

The first silicide portions 81 (the second silicide portions 82) containing silicide other than titanium silicide may be formed. In this case, before the forming step of the first base lower electrode film 122, a step of siliciding the wafer 100 by a metal film (not shown) is performed. The metal film may include at least one among a nickel film, a cobalt film, a molybdenum film, a tungsten film, and a vanadium film.

Next, with reference to FIG. 13O, a forming step of a base intermediate electrode film 124 is performed. The base intermediate electrode film 124 is formed on the base lower electrode film 121. The base intermediate electrode film 124 contains at least one among tungsten, molybdenum, a tungsten alloy, and a molybdenum alloy. In this embodiment, the base intermediate electrode film 124 contains tungsten.

The base intermediate electrode film 124 may be formed by the CVD method (for example, a low pressure CVD method). The base intermediate electrode film 124 backfills the plurality of source openings 65, the plurality of outer openings 67, and the plurality of gate openings 69 and covers, in a film shape, the first insulating surface 29, the second insulating surface 57, and the insulating surface of the outer insulating film 61.

Next, with reference to FIG. 13P, a removing step of the base intermediate electrode film 124 is performed. In this step, unnecessary portions of the base intermediate electrode film 124 are removed by the etching method (the etch back method). The etching method may be a wet etching method and/or a dry etching method.

The unnecessary portions of the base intermediate electrode film 124 are removed until the base lower electrode film 121 is exposed. Thereby, the plurality of first embedded electrodes 72 are embedded in the plurality of source openings 65. Also, the plurality of first embedded electrodes 72 are embedded in the plurality of outer openings 67. Also, the plurality of second embedded electrodes 85 are embedded in the plurality of gate openings 69.

Next, with reference to FIG. 13Q, a forming step of a base upper electrode film 125 is performed. The base upper electrode film 125 is a base of the first upper electrode film 73 and the second upper electrode film 86. The base upper electrode film 125 is laminated in a film shape on the base lower electrode film 121, the plurality of first embedded electrodes 72, and the plurality of second embedded electrodes 85.

The base upper electrode film 125 may include at least one among an Al film, an Al alloy film, a Cu film, and a Cu alloy film. The base upper electrode film 125 may include at least one of an AlSi alloy film, an AlCu alloy film, and an AlSiCu alloy film. The base upper electrode film 125 may be formed by the sputtering method or the vapor deposition method.

Next, the base upper electrode film 125 is divided into the source main electrode 70, the source finger electrode 80, the gate finger electrode 83, and the gate main electrode 90. In this step, a mask (not shown) having a predetermined layout is formed on the base upper electrode film 125. The mask (not shown) covers regions in which the source main electrode 70, the source finger electrode 80, the gate finger electrode 83, and the gate main electrode 90 are to be formed, and exposes regions other than these.

Next, unnecessary portions of the base upper electrode film 125 are removed by the etching method via the mask (not shown). The unnecessary portions of the base upper electrode film 125 are removed until the base lower electrode film 121 is exposed. The etching method may be a wet etching method and/or a dry etching method. After an etching step of the base upper electrode film 125, the mask (not shown) is removed.

Next, unnecessary portions of the base lower electrode film 121 are removed by the etching method via the base upper electrode film 125. The unnecessary portions of the base lower electrode film 121 are removed until the second planar insulating film 52 and the outer insulating film 61 are exposed.

The removing step of the base lower electrode film 121 includes a step of removing the second base lower electrode film 123 by the etching method and a step of removing the first base lower electrode film 122 by the etching method. The etching method may be a wet etching method and/or a dry etching method.

The unnecessary portions of the base lower electrode film 121 may be removed by the etching method via the mask (not shown) related to the etching step of the base upper electrode film 125. Thereby, the source main electrode 70, the source finger electrode 80, the gate finger electrode 83, and the gate main electrode 90 are formed.

Next, with reference to FIG. 13R, the drain main electrode 91 is formed on the second wafer main surface 102. The drain main electrode 91 may be formed by the sputtering method or the vapor deposition method. Thereafter, the wafer 100 is cut along the intended cutting lines 106, and a plurality of the semiconductor devices 1A are cut out. The semiconductor devices 1A are manufactured through steps including the steps described above.

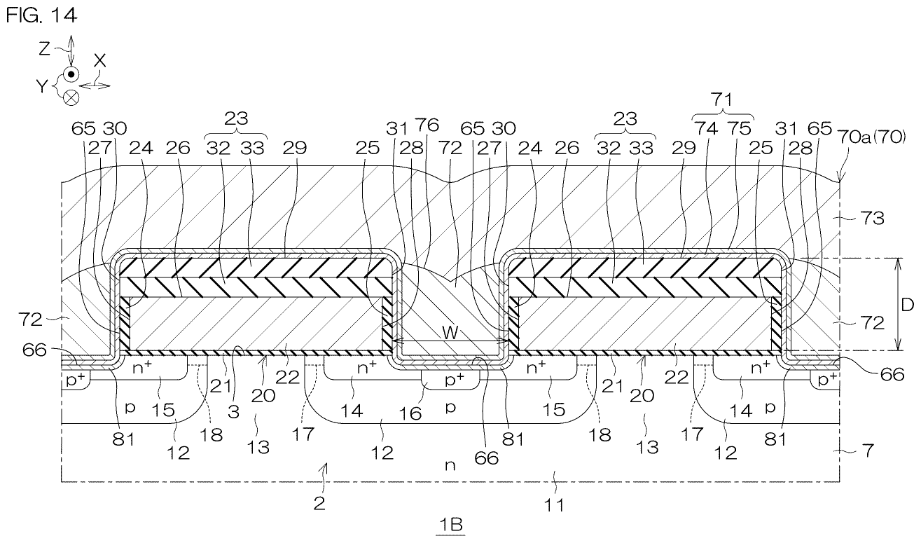

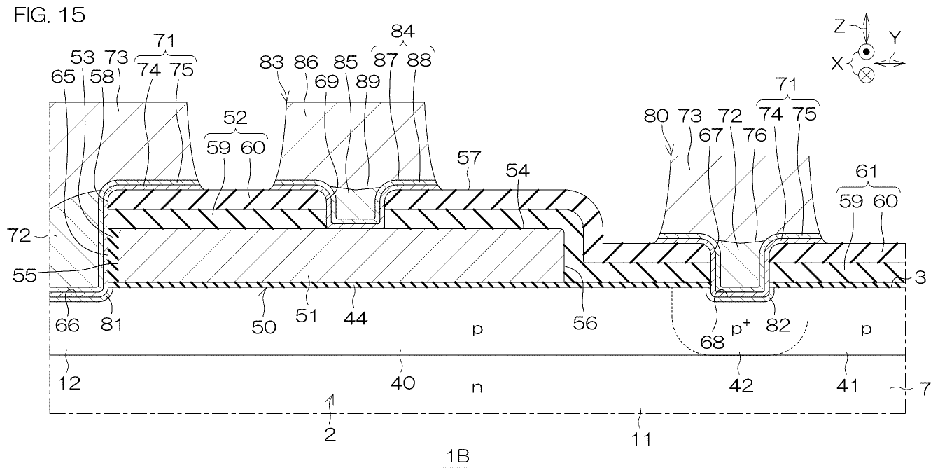

FIG. 14 is an enlarged cross-sectional view showing the gate structure 20 of a semiconductor device 1B according to a second embodiment. FIG. 15 is an enlarged cross-sectional view showing the wiring structure 50 of the semiconductor device 1B shown in FIG. 14. With reference to FIG. 14, similarly to the semiconductor device 1A, the semiconductor device 1B includes the first side wall insulating film 24 covering the first side wall 27 and the second side wall insulating film 25 covering the second side wall 28.

In this embodiment, the first side wall insulating film 24 has a single layer structure constituted of the silicon oxide film. The first side wall insulating film 24 is preferably constituted of a silicon oxide film containing an oxide of the gate electrode 22 (polysilicon).

In this embodiment, the first side wall insulating film 24 covers the first side wall 27 in a region between the gate insulating film 21 and the first planar insulating film 23. The first side wall insulating film 24 covers the first side wall 27 and exposes the first insulating side wall 30. Specifically, the first side wall insulating film 24 covers the entire first side wall 27 and exposes the entire first insulating side wall 30.

That is, the first side wall insulating film 24 has a lower end portion connected to the gate insulating film 21 and an upper end portion connected to the first planar insulating film 23. The first side wall insulating film 24 covers the first side wall 27 in a film shape conforming to the inclination angle of the first side wall 27. The first side wall insulating film 24 has a film surface extending at an inclination angle substantially equal to the inclination angle of the first side wall 27 and extending substantially parallel to the first side wall 27.

In this embodiment, the first side wall insulating film 24 extends substantially vertically in a region between the gate insulating film 21 and the first planar insulating film 23. In a case where the gate electrode 22 is formed in a tapered shape (a tapered shape), and the first side wall 27 is inclined obliquely, the first side wall insulating film 24 may have a film surface inclined obliquely with respect to the vertical line in a covering portion with respect to the first side wall 27.

In this embodiment, the second side wall insulating film 25 has a single layer structure constituted of the silicon oxide film. The second side wall insulating film 25 is preferably constituted of the silicon oxide film containing the oxide of the gate electrode 22 (polysilicon).

In this embodiment, the second side wall insulating film 25 covers the second side wall 28 in a region between the gate insulating film 21 and the first planar insulating film 23. The second side wall insulating film 25 covers the second side wall 28 and exposes the second insulating side wall 31. Specifically, the second side wall insulating film 25 covers the entire second side wall 28 and exposes the entire second insulating side wall 31.

The second side wall insulating film 25 has a lower end portion connected to the gate insulating film 21 and an upper end portion connected to the first planar insulating film 23. The second side wall insulating film 25 covers the second side wall 28 in a film shape conforming to the inclination angle of the second side wall 28. The second side wall insulating film 25 has a film surface extending at an inclination angle substantially equal to the inclination angle of the second side wall 28 and extending substantially parallel to the second side wall 28.

In this embodiment, the second side wall insulating film 25 extends substantially vertically in a region between the gate insulating film 21 and the first planar insulating film 23. In a case where the gate electrode 22 is formed in a tapered shape (a tapered shape), and the second side wall 28 is inclined obliquely, the second side wall insulating film 25 may have a film surface inclined obliquely with respect to the vertical line in a covering portion with respect to the second side wall 28.

With reference to FIG. 15, similarly to the semiconductor device 1A, the semiconductor device 1B includes the third side wall insulating film 53 covering the first wiring side wall 55. In this embodiment, the third side wall insulating film 53 has a single layer structure constituted of the silicon oxide film. The third side wall insulating film 53 is preferably constituted of a silicon oxide film containing an oxide of the gate wiring 51 (polysilicon).

In this embodiment, the third side wall insulating film 53 covers the first wiring side wall 55 in a region between the main surface insulating film 44 and the second planar insulating film 52. The third side wall insulating film 53 covers the first wiring side wall 55 and exposes the third insulating side wall 58. Specifically, the third side wall insulating film 53 covers the entire first wiring side wall 55 and exposes the entire third insulating side wall 58.

That is, the third side wall insulating film 53 has a lower end portion connected to the main surface insulating film 44 and an upper end portion connected to the second planar insulating film 52. The third side wall insulating film 53 covers the first wiring side wall 55 in a film shape conforming to the inclination angle of the first wiring side wall 55. The third side wall insulating film 53 has a film surface extending at an inclination angle substantially equal to the inclination angle of the first wiring side wall 55 and extending substantially parallel to the first wiring side wall 55.

In this embodiment, the third side wall insulating film 53 extends substantially vertically in a region between the main surface insulating film 44 and the second planar insulating film 52. In a case where the gate wiring 51 is formed in a tapered shape (a tapered shape), and the first wiring side wall 55 is inclined obliquely, the third side wall insulating film 53 may have a film surface inclined obliquely with respect to the vertical line in a covering portion with respect to the first wiring side wall 55.

Similarly to the case of the semiconductor device 1A, the plurality of source openings 65 are respectively demarcated in regions surrounded by the plurality of gate structures 20 and the wiring structure 50. In this embodiment, the plurality of source openings 65 are respectively demarcated by the first planar insulating film 23 and the first side wall insulating film 24 of one of the gate structures 20 and the first planar insulating film 23 and the second side wall insulating film 25 of the other gate structure 20 in the first direction X. Each of the plurality of source openings 65 has both end portions demarcated by the second planar insulating film 52 and the third side wall insulating film 53 of the wiring structure 50 in the second direction Y.

In this embodiment, the first lower electrode film 71 of the source main electrode 70 has portions directly covering both the exposed portion of the first insulating side wall 30 and the exposed portion of the second insulating side wall 31. Specifically, the first electrode film 74 directly covers the entire first insulating side wall 30 and the entire second insulating side wall 31. That is, the first electrode film 74 directly covers both the first oxide film 32 and the second oxide film 33 on the first insulating side wall 30, and directly covers both the first oxide film 32 and the second oxide film 33 on the second insulating side wall 31.

On the other hand, the second electrode film 75 covers the entire first insulating side wall 30 and the entire second insulating side wall 31 across the first electrode film 74. That is, the second electrode film 75 covers both the first oxide film 32 and the second oxide film 33 across the first electrode film 74 on the first insulating side wall 30 side, and covers both the first oxide film 32 and the second oxide film 33 across the first electrode film 74 on the second insulating side wall 31 side.

The arrangements of the side wall insulating films 24 and 25 according to the semiconductor device 1B may be applied to any one of the gate structures 20 (the gate electrodes 22) according to the first to eleventh examples described above (FIG. 7 and FIG. 10A to FIG. 10J). The arrangements of the side wall insulating films 24 and 25 according to the semiconductor device 1B may be applied to any one of the wiring structures 50 (the gate wirings 51) according to the first to tenth examples described above (FIG. 9 and FIG. 11A to FIG. 11I).

The arrangements of the third side wall insulating film 53 according to the semiconductor device 1B may be applied to any one of the gate structures 20 (the gate electrodes 22) according to the first to eleventh examples described above (FIG. 7 and FIG. 10A to FIG. 10J). The arrangement of the third side wall insulating film 53 according to the semiconductor device 1B may be applied to any one of the wiring structures 50 (the gate wirings 51) according to the first to tenth examples described above (FIG. 9 and FIG. 11A to FIG. 11I).

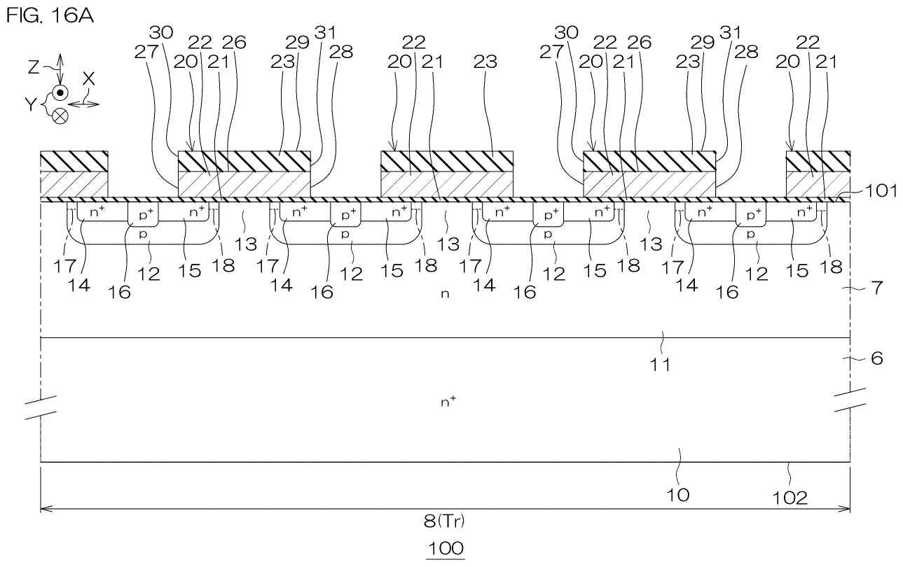

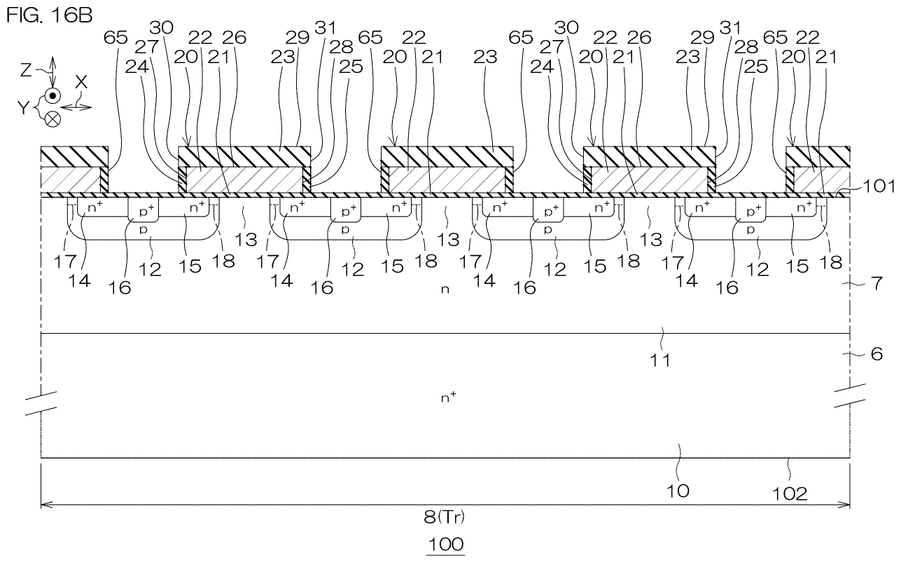

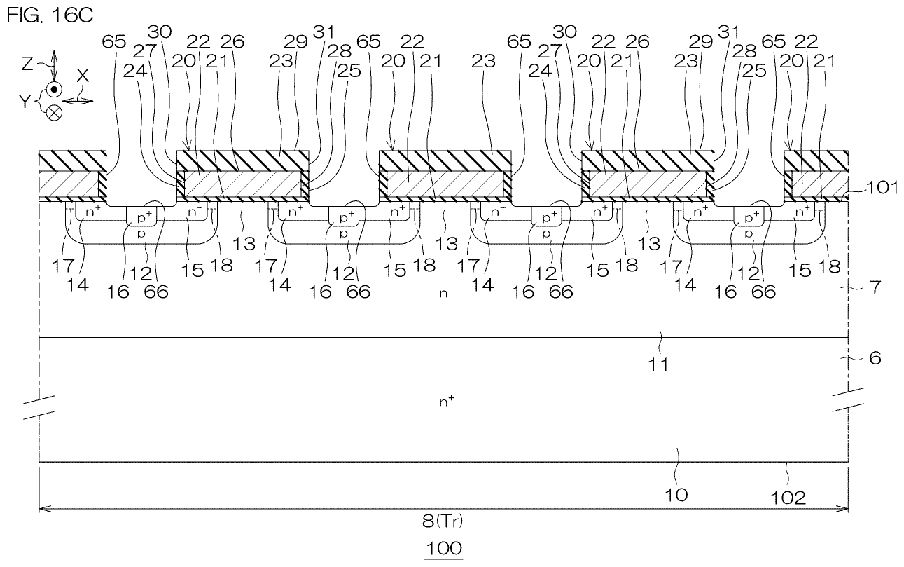

FIG. 16A to FIG. 16C are cross-sectional views showing a method for manufacturing the semiconductor device 1B shown in FIG. 14. With reference to FIG. 16A, in the method for manufacturing the semiconductor device 1, the wafer 100 after the second patterning step (see FIG. 13J) of the base gate electrode 114 described above is prepared.

Next, with reference to FIG. 16B, a forming step of the plurality of first side wall insulating films 24, the plurality of second side wall insulating films 25, and the plurality of third side wall insulating films 53 is performed. In this step, instead of the forming step of the base side wall insulating film 120, an oxidation processing step of the plurality of gate electrodes 22 and the plurality of gate wirings 51 is performed. The oxidation processing step may be either or both of a thermal oxidation processing step and a wet oxidation processing step.

By this step, portions (that is, the first side wall 27 and the second side wall 28) of the plurality of gate electrodes 22 exposed from the plurality of first planar insulating films 23 are oxidized, and the portion (that is, the first wiring side wall 55) of the gate wiring 51 exposed from the second planar insulating film 52 is oxidized. Thereby, the plurality of first side wall insulating films 24, the plurality of second side wall insulating films 25, and the plurality of third side wall insulating films 53 are formed.

Next, with reference to FIG. 16C, a forming step of the plurality of gate insulating films 21, the main surface insulating film 44, and the plurality of source openings 65 is performed. In this step, a plurality of exposed portions of the lower base insulating film 113 which are demarcated by the plurality of first side wall insulating films 24, the plurality of second side wall insulating films 25, and the plurality of third side wall insulating films 53 are removed by the etching method.

In this step, hidden portions of the lower base insulating film 113 hidden by the plurality of gate electrodes 22 (the plurality of first planar insulating films 23) remain as the plurality of gate insulating films 21. Also, a hidden portion of the lower base insulating film 113 hidden by the gate wiring 51 (the second planar insulating film 52) and the outer insulating film 61 remains as the main surface insulating film 44.

The etching method may be either or both of a wet etching method and a dry etching method. The wet etching method is preferably anisotropic. The dry etching method is preferably anisotropic. The etching method is particularly preferably the RIE method.

Through this step, the plurality of gate insulating films 21, the main surface insulating film 44, and the plurality of source openings 65 are formed. Thereafter, the semiconductor device 1B is manufactured through the same steps as in FIG. 13N to FIG. 13R.

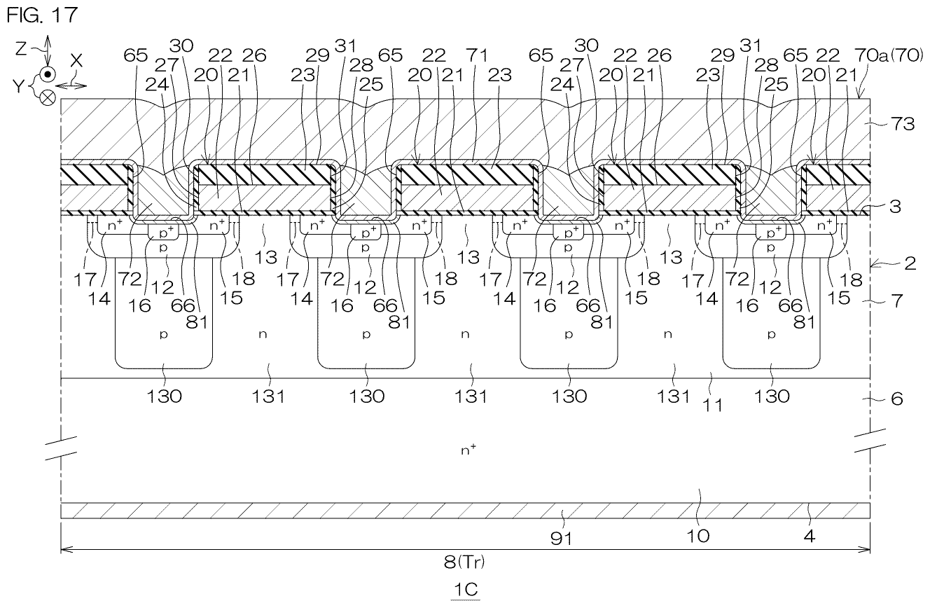

FIG. 17 is a cross-sectional view showing a semiconductor device 1C according to a third embodiment. The semiconductor device 1C includes a plurality of column regions 130 of the p-type formed in a thickness range below the plurality of body regions 12 in the second semiconductor region 11.

The plurality of column regions 130 have a p-type impurity concentration lower than the p-type impurity concentration of the contact region 16. The p-type impurity concentration of the plurality of column regions 130 may be higher than the p-type impurity concentration of the body region 12. The p-type impurity concentration of the plurality of column regions 130 may be lower than the p-type impurity concentration of the body region 12.

The plurality of column regions 130 are aligned at intervals in the first direction X and are each formed as a band extending in the second direction Y. That is, the plurality of column regions 130 are formed as stripes extending in the second direction Y along the plurality of body regions 12. Also, an extension direction of the plurality of body regions 12 coincides with the off direction of the SiC monocrystal.

The plurality of column regions 130 are each formed in a columnar shape extending in the thickness direction in cross-sectional view and overlap the plurality of body regions 12 in one-to-one correspondence. The plurality of column regions 130 may have a single layer structure constituted of a single impurity region of the p-type or may have a laminated structure in which a plurality of impurity regions of the p-type are laminated in the thickness direction. Hereinafter, an arrangement of one of the column regions 130 shall be described specifically.

The column region 130 may cross the intermediate portion of the second semiconductor region 11 in the thickness direction. The column region 130 has a lower end portion and an upper end portion. The lower end portion of the column region 130 is positioned on the bottom portion side of the second semiconductor region 11 with respect to the intermediate portion of the second semiconductor region 11. The lower end portions of the column regions 130 may be formed at an interval to the body region 12 side from the bottom portion of the second semiconductor region 11. The lower end portions of the column regions 130 may cross the bottom portion of the second semiconductor region 11 and may be positioned in the surface layer portion of the first semiconductor region 10.

The upper end portions of the column regions 130 are positioned on the bottom portion (the lower end portion) side of the body regions 12 with respect to the intermediate portion of the second semiconductor region 11. The upper end portions of the column regions 130 are preferably connected to the bottom portions of the body regions 12.

That is, the column regions 130 are preferably electrically connected to the body regions 12. The upper end portions of the column regions 130 may be formed at an interval to the bottom portion side of the second semiconductor region 11 from the bottom portions of the body regions 12 and may face the body regions 12 with a portion of the second semiconductor region 11 interposed therebetween.

The column region 130 has a width less than the width of the body region 12 and is formed at intervals inward from the peripheral edge portion of the body region 12. The width of the column region 130 may be larger than the width of the contact region 16. The column region 130 has a thickness larger than the thickness of the body region 12. The thickness of the column region 130 may be less than the thickness of the second semiconductor region 11. The thickness of the column region 130 may be larger than the thickness of the second semiconductor region 11.

The semiconductor device 1C includes a plurality of intermediate drift regions 131 of the n-type formed in the second semiconductor region 11. The plurality of intermediate drift regions 131 are respectively constituted of a region of the second semiconductor region 11 demarcated between the plurality of column regions 130.

The intermediate drift region 131 may have an n-type impurity concentration higher than the n-type impurity concentration of the second semiconductor region 11 or may have an n-type impurity concentration lower than the n-type impurity concentration of the second semiconductor region 11. The intermediate drift region 131 may have an n-type impurity concentration higher than the n-type impurity concentration of the surface layer drift region 13 or may have an n-type impurity concentration lower than the n-type impurity concentration of the surface layer drift region 13.

The plurality of intermediate drift regions 131 and the plurality of column regions 130 are aligned alternately in the first direction X, and the intermediate drift regions 131 are each formed as a band extending in the second direction Y. That is, the plurality of intermediate drift regions 131 are formed as stripes extending in the second direction Y along the plurality of column regions 130. Also, an extension direction of the plurality of intermediate drift regions 131 coincides with the off direction of the SiC monocrystal.

The plurality of intermediate drift regions 131 are each formed in a columnar shape extending in the thickness direction in cross-sectional view and are connected to the plurality of surface layer drift regions 13 in one-to-one correspondence. Each of the plurality of intermediate drift regions 131 has a width larger than the width of each of the plurality of surface layer drift regions 13 and has both end portions connected to the two body regions 12 adjacent in the first direction X.

The plurality of intermediate drift regions 131, together with the plurality of column regions 130, form a plurality of pn junction portions having a charge balance in a thickness range below the body region 12. A state of having the charge balance means a state in which, regarding the plurality of column regions 130 adjacent to each other, a depletion layer expanding from one pn junction portion and a depletion layer expanding from the other pn junction portion are connected in the plurality of intermediate drift regions 131. Thereby, the plurality of intermediate drift regions 131 constitute a super junction structure with the plurality of column regions 130 in a region below the body regions 12.

The forming step of the plurality of column regions 130 includes a forming step of a mask and an implantation step of a p-type impurity. In the forming step of a mask, a mask having openings from which regions, in which the plurality of column regions 130 are to be formed are exposed, is formed on the first wafer main surface 101. In the implantation step of a p-type impurity, a p-type impurity is implanted into the second semiconductor region 11 by the ion implantation method via the mask.

The ion implantation method is preferably a channeling ion implantation method. In a channeling ion implantation step, a p-type impurity is implanted along a channel axis (for example, a c-axis) having sparse atomic rows, among crystal axes of the wafer 100 (the second semiconductor layer 7). The p-type impurity is implanted into a deep region of the second semiconductor region 11 while small-angle scattering due to a channeling effect is repeated. That is, in the case of the channeling ion implantation method, a collision probability of the trivalent element with respect to the atomic rows of the SiC monocrystal is reduced. Thereby, the plurality of column regions 130 are formed.

The forming step of the column region 130 may be performed after a forming step of the body region 12. In this case, the column region 130 is formed inside the second semiconductor region 11 such as to be connected to the body region 12 in the thickness direction. The forming step of the column region 130 may be performed before the forming step of the body region 12. In this case, in the forming step of the body region 12, the body region 12 is formed in the surface layer portion of the second semiconductor region 11 such as to be connected to the column region 130 in the thickness direction.

As described above, the semiconductor device 1C includes the column region 130 of the p-type, in addition to the arrangement of the semiconductor device 1A. The column region 130 is formed in a thickness range below the body region 12 in the second semiconductor region 11. According to this arrangement, the super junction type semiconductor device 1C is provided. In a case where the chip 2 includes an SiC monocrystal, a super junction type SiC semiconductor device having a novel arrangement regarding the body region 12 is provided.

In this embodiment, an example has been described, in which the plurality of column regions 130 (the plurality of intermediate drift regions 131) are formed as stripes extending in the second direction Y along the plurality of body regions 12. However, the plurality of column regions 130 may each be formed as a band extending in the first direction X and may be aligned at intervals in the second direction Y. That is, an extension direction of the plurality of column regions 130 may intersect (specifically, be orthogonal to) the off direction of the SiC monocrystal. In this case, the plurality of column regions 130 intersect (specifically, are orthogonal to) the plurality of body regions 12.

The plurality of column regions 130 (the plurality of intermediate drift regions 131) may be aligned at intervals in an intersection direction intersecting both the first direction X and the second direction Y and may each be formed as a band extending in an orthogonal direction orthogonal to the intersection direction. That is, the extension direction of the plurality of column regions 130 may intersect the off-direction of the SiC monocrystal. In this case, the plurality of column regions 130 intersect the plurality of body regions 12.

In this embodiment, an example has been described, in which the plurality of body regions 12 (the surface layer drift regions 13) are formed as stripes extending in the second direction Y. However, the plurality of body regions 12 may each be formed as a band extending in the first direction X and may be aligned at intervals in the second direction Y. That is, the plurality of body regions 12 may be formed as stripes extending in the first direction X. Also, the extension direction of the plurality of body regions 12 may intersect (specifically, be orthogonal to) the off direction of the SiC monocrystal.

In this case, the plurality of column regions 130 (the plurality of intermediate drift regions 131) may each be formed as a band extending in the first direction X and may be aligned at intervals in the second direction Y. That is, the plurality of column regions 130 (the plurality of intermediate drift regions 131) may be formed as stripes extending in the first direction X along the plurality of body regions 12.

The plurality of column regions 130 may be aligned at intervals in the first direction X and may each be formed as a band extending in the second direction Y. That is, the plurality of column regions 130 may be formed as stripes extending in the second direction Y. Also, the extension direction of the plurality of column regions 130 may coincide with the off-direction of the SiC monocrystal.

In this case, the plurality of column regions 130 intersect (specifically, are orthogonal to) the plurality of body regions 12. The plurality of column regions 130 (the plurality of intermediate drift regions 131) may be aligned at intervals in an intersection direction intersecting both the first direction X and the second direction Y and may each be formed as a band extending in an orthogonal direction orthogonal to the intersection direction.

In this embodiment, an example has been described, in which the plurality of column regions 130 (the plurality of intermediate drift regions 131) are applied to the arrangement of the semiconductor device 1A. However, the plurality of column regions 130 (the plurality of intermediate drift regions 131) may be applied to the semiconductor device 1B according to the second embodiment.

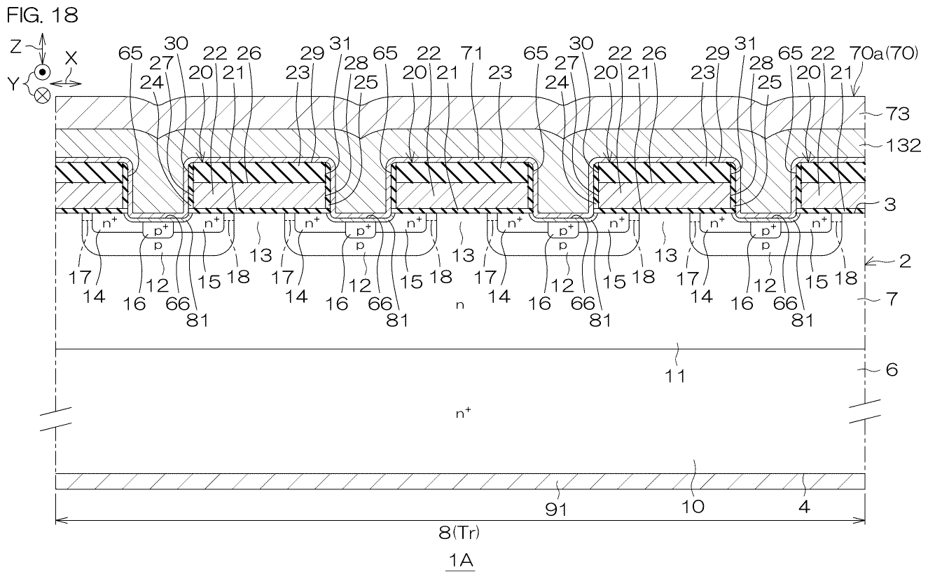

Hereinafter, modification examples applied to the semiconductor devices 1A to 1C according to the first to third embodiments shall be described. FIG. 18 is a cross-sectional view showing a first modification example of the source main electrode 70. FIG. 18 illustrates an arrangement in which the source main electrode 70 according to the modification example is applied to the semiconductor device 1A. The source main electrode 70 according to the first modification example can be applied to the semiconductor device 1B and the semiconductor device 1C.

In each of the embodiments described above, the source main electrode 70 includes the plurality of first embedded electrodes 72. However, as shown in FIG. 18, the source main electrode 70 may include an intermediate electrode film 132 instead of the plurality of first embedded electrodes 72.

The intermediate electrode film 132 contains a conductive material different from the conductive material of the first lower electrode film 71. The intermediate electrode film 132 includes at least one among a tungsten film, a molybdenum film, a tungsten alloy film, and a molybdenum alloy film. In this embodiment, the intermediate electrode film 132 includes the tungsten film.

The intermediate electrode film 132 is laminated as an intermediate layer of the source main electrode 70 on the first lower electrode film 71 and collectively covers, in a film shape, the plurality of gate structures 20 in the active region 8. The intermediate electrode film 132 is mechanically and electrically connected to the first lower electrode film 71 on the first insulating surface 29 and the second insulating surface 57.

Specifically, the intermediate electrode film 132 covers the plurality of first planar insulating films 23 in a film shape across the first lower electrode film 71. The intermediate electrode film 132 has a peripheral edge portion covering the wiring structure 50 in a film shape across the first lower electrode film 71. The peripheral edge portion of the intermediate electrode film 132 covers the second planar insulating film 52 across the peripheral edge portion of the first lower electrode film 71.

The intermediate electrode film 132 enters the plurality of source openings 65 from above the first insulating surface 29 and the second insulating surface 57. The intermediate electrode film 132 is mechanically connected to the plurality of first side wall insulating films 24, the plurality of second side wall insulating films 25, and the plurality of third side wall insulating films 53 in the plurality of source openings 65 and is electrically connected to the first main surface 3 via the first lower electrode film 71 in the plurality of source openings 65.

Specifically, the source main electrode 70 is electrically connected to the plurality of body regions 12, the plurality of source regions 14 and 15, the plurality of contact regions 16, etc., via the first lower electrode film 71 in the plurality of source openings 65. That is, the intermediate electrode film 132 is electrically connected to the plurality of body regions 12, etc., via the first lower electrode film 71 inside and outside the plurality of source openings 65.

The intermediate electrode film 132 faces the plurality of gate electrodes 22 and the plurality of first planar insulating films 23 in the horizontal direction with the plurality of side wall insulating films 24 and 25 interposed therebetween. In this embodiment, the intermediate electrode film 132 faces the first oxide film 32 and the second oxide film 33 in the horizontal direction with the plurality of side wall insulating films 24 and 25 interposed therebetween.

The intermediate electrode film 132 faces the gate wiring 51 and the second planar insulating film 52 in the horizontal direction with the third side wall insulating film 53 interposed therebetween. In this embodiment, the intermediate electrode film 132 faces the first oxide film 32 and the second oxide film 33 in the horizontal direction with the plurality of side wall insulating films 24 and 25 interposed therebetween.

In this embodiment, the first upper electrode film 73 is laminated in a film shape on the intermediate electrode film 132 and is mechanically and electrically connected to the intermediate electrode film 132. The first upper electrode film 73 covers the first insulating surface 29, the second insulating surface 57, and the plurality of source openings 65 across the intermediate electrode film 132. The first upper electrode film 73 is connected to the intermediate electrode film 132 at a position higher than the plurality of source openings 65. In this embodiment, the first upper electrode film 73 does not have a mechanical connection portion with respect to the first lower electrode film 71.

The source finger electrode 80 may include the intermediate electrode film 132 instead of the plurality of first embedded electrodes 72. Similarly, the source finger electrode 80 may include the intermediate electrode film 132 instead of the plurality of second embedded electrodes 85. Similarly, the gate main electrode 90 may include the intermediate electrode film 132.

The intermediate electrode film 132 is formed by adjusting an etching amount with respect to the base intermediate electrode film 124 in the forming step of the base intermediate electrode film 124 described above (see FIG. 13O). For example, the intermediate electrode film 132 is formed by omitting the etching processing with respect to the base intermediate electrode film 124. For example, the intermediate electrode film 132 is also formed by finishing the etching processing with respect to the base intermediate electrode film 124 before a base underlying electrode film is exposed.

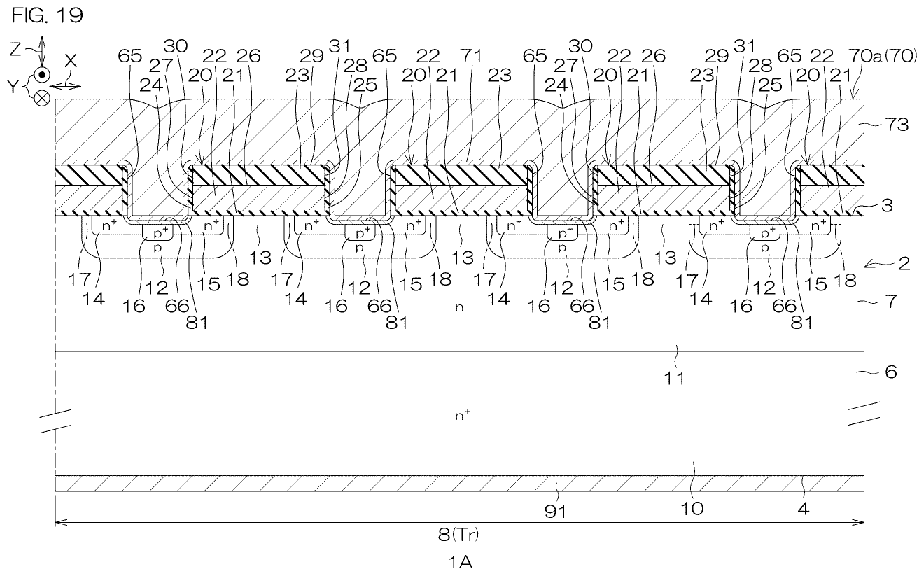

FIG. 19 is a cross-sectional view showing a second modification example of the source main electrode 70. FIG. 19 illustrates an arrangement in which the source main electrode 70 according to the modification example is applied to the semiconductor device 1A. The source main electrode 70 according to the second modification example can be applied to the semiconductor device 1B and the semiconductor device 1C.

In the embodiments described above, the source main electrode 70 includes the plurality of first embedded electrodes 72. However, as shown in FIG. 19, the source main electrode 70 does not necessarily have to have the first embedded electrodes 72. In this case, the first upper electrode film 73 of the source main electrode 70 enters the plurality of source openings 65 from above the first planar insulating film 23 (the first insulating surface 29) and the second planar insulating film 52 (the second insulating surface 57) and is electrically connected to the body regions 12, etc., in the plurality of source openings 65.

Similarly, the source finger electrode 80 does not necessarily have to have the first embedded electrodes 72. In this case, the first upper electrode film 73 of the source finger electrode 80 enters the plurality of outer openings 67 from above the outer insulating film 61 and is electrically connected to the terminal region 41 (the overlap region 42) in the plurality of outer openings 67.

Similarly, the gate finger electrode 83 does not necessarily have to have the second embedded electrodes 85. In this case, the second upper electrode film 86 of the gate finger electrode 83 enters the plurality of gate openings 69 from above the second planar insulating film 52 (the second insulating surface 57) and is electrically connected to the gate wiring 51 in the plurality of gate openings 69.

The semiconductor device 1A, while having the first embedded electrodes 72 related to the source main electrode 70, does not have to have the first embedded electrodes 72 related to the source finger electrode 80. The semiconductor device 1A, while having the first embedded electrodes 72 related to the source finger electrode 80, does not have to have the first embedded electrode 72 related to the source main electrode 70.

The semiconductor device 1A, while having the first embedded electrodes 72 related to the source main electrode 70, does not have to have the second embedded electrodes 85 related to the gate finger electrode 83. The semiconductor device 1A, while having the second embedded electrodes 85 related to the gate finger electrode 83, does not have to have the first embedded electrode 72 related to the source main electrode 70.

The semiconductor device 1A, while having the first embedded electrodes 72 related to the source finger electrode 80, does not have to have the second embedded electrodes 85 related to the gate finger electrode 83. The semiconductor device 1A, while having the second embedded electrodes 85 related to the gate finger electrode 83, does not have to have the first embedded electrodes 72 related to the source finger electrode 80.

The embodiments (including the modification examples) described above can be implemented in still other embodiments. For example, in the embodiments described above, a structure may be adopted, in which the conductivity type of the semiconductor region of the “n-type” is inverted to the “p-type,” and the conductivity type of the semiconductor region of the “p-type” is inverted to the “n-type.” A specific arrangement in this case can be obtained by replacing the “n-type” with the “p-type” at the same time as replacing the “p-type” with the “n-type” in the above descriptions and the attached drawings.

In each of the embodiments described above, the chip 2 containing the SiC monocrystal is adopted. However, the chip 2 may contain a monocrystal of a wide bandgap semiconductor other than the SiC monocrystal. The wide bandgap semiconductor is a semiconductor having a bandgap greater than a bandgap of silicon. As examples of the monocrystal of the wide bandgap semiconductor, gallium nitride, gallium oxide, and diamond, etc., can be cited. The chip 2 may contain a silicon monocrystal.

Similarly, the first semiconductor layer 6 may contain the monocrystal of the wide bandgap semiconductor other than the SiC monocrystal. The first semiconductor layer 6 may contain gallium nitride, gallium oxide, diamond, etc. The first semiconductor layer 6 may contain a silicon monocrystal.

Similarly, the second semiconductor layer 7 may contain the monocrystal of the wide bandgap semiconductor other than the SiC monocrystal. The second semiconductor layer 7 may contain gallium nitride, gallium oxide, diamond, etc. The second semiconductor layer 7 may contain a silicon monocrystal.

In each of the embodiment described above, the first semiconductor region 10 of the n-type was described. However, instead of the first semiconductor region 10 of the n-type, the first semiconductor region 10 of the p-type may be adopted as a collector region. In this case, the transistor structure Tr includes an IGBT (insulated gate bipolar transistor) structure instead of the MISFET structure.

A specific arrangement in this case is obtained by replacing the “source” of the MISFET structure with an “emitter” of the IGBT structure and replacing the “drain” of the MISFET structure with a “collector” of the IGBT structure in the above descriptions and the attached drawings. The collector region of the p-type may be an impurity region that contains a p-type impurity introduced into the surface layer portion of the second main surface 4 of the chip 2 by the ion implantation method.

Hereinafter, examples of features extracted from this Description and the attached drawings shall be indicated. Hereinafter, the alphanumeric characters, etc., in parentheses represent the corresponding components, etc., in the embodiments described above, but are not intended to limit the scope of each clause to the embodiments. The “semiconductor device” in the following clauses may be replaced with an “SiC semiconductor device,” a “wide bandgap semiconductor device,” a “semiconductor switching device,” a “MISFET device,” an “IGBT device,” etc., as needed.

[A1]A semiconductor device (1A, 1B, 1C) comprising: a chip (2) having a main surface (3); gate structures (20) of a planar type each including a gate insulating film (21) covering the main surface (3), a gate electrode (22) arranged on the gate insulating film (21), and a side wall insulating film (24, 25) covering a side wall (27, 28) of the gate electrode (22), the gate structures (20) being arranged at intervals on the main surface (3); an opening (65) that is demarcated by the side wall insulating films (24, 25) in a region between the gate structures (20) and exposes the main surface (3); and a main electrode (70) that is mechanically connected to the side wall insulating films (24, 25) in the opening (65) and is electrically connected to the main surface (3) in the opening (65).

[A2] The semiconductor device (1A, 1B, 1C) according to A1, wherein the chip (2) contains SiC.

[A3] The semiconductor device (1A, 1B, 1C) according to A1 or A2, wherein the side wall insulating film (24, 25) covers the side wall (27, 28) of the gate electrode (22) in a film shape and has a film surface extending along the side wall (27, 28) of the gate electrode (22) in cross-sectional view.

[A4] The semiconductor device (1A, 1B, 1C) according to any one of A1 to A3, wherein the side wall insulating film (24, 25) covers the side wall (27, 28) of the gate electrode (22) on the gate insulating film (21).

[A5] The semiconductor device (1A, 1B, 1C) according to A1 to A4, wherein the side wall insulating film (24, 25) has a thickness less than a thickness of the gate electrode (22).

[A6] The semiconductor device (1A, 1B, 1C) according to any one of A1 to A5, wherein the side wall insulating film (24, 25) has a single layer structure constituted of a single insulating film.

[A7] The semiconductor device (1A, 1B, 1C) according to A6, wherein the single insulating film is constituted of an undoped oxide film.

[A8] The semiconductor device (1A, 1B, 1C) according to any one of A1 to A7, wherein the gate structures (20) respectively include a planar insulating film (23) arranged on the gate electrode (22), and the side wall insulating film (24, 25) covering the side wall (27, 28) of the gate electrode (22) and a side wall (30, 31) of the planar insulating film (23), and the main electrode (70) has a portion facing the gate electrode (22) in a lamination direction (Z) with the planar insulating film (23) interposed therebetween and is electrically disconnected from the gate electrode (22) by the planar insulating film (23).

[A9] The semiconductor device (1A, 1B, 1C) according to A8, wherein the planar insulating film (23) has a laminated structure including insulating films (32, 33).

[A10] The semiconductor device (1A, 1B, 1C) according to A9, wherein the side wall insulating film (24, 25) covers the insulating films (32, 33) on the side wall (30, 31) of the planar insulating film (23).

[A11] The semiconductor device (1A, 1B, 1C) according to A9 or A10, wherein the insulating films (32, 33) include an undoped first oxide film (32) covering the gate electrode (22), and a second oxide film (33) that contains phosphorus and covers the first oxide film (32).

[A12] The semiconductor device (1A, 1B, 1C) according to A1 to A11, wherein the opening (65) has a width (W) of not less than a thickness of the side wall insulating film (24, 25) and not more than a width of the gate electrode (22).

[A13] The semiconductor device (1A, 1B, 1C) according to A12, wherein the thickness of the side wall insulating film (24, 25) is not less than 0.05 μm and not more than 0.5 μm, and the width (W) of the opening (65) is not less than 0.2 μm and not more than 0.6 μm.

[A14] The semiconductor device (1A, 1B, 1C) according to any one of A1 to A13, wherein the main electrode (70) has a laminated structure including an embedded electrode (72) electrically connected to the main surface (3) in the opening (65), and an upper electrode (73) that is electrically connected to the main surface (3) via the embedded electrode (72) on the embedded electrode (72).

[A15] The semiconductor device (1A, 1B, 1C) according to any one of A1 to A14, further comprising: a silicide portion (81) that is formed in a portion of the main surface (3) exposed from the opening (65) and that electrically connects the main electrode (70) to the chip (2).

[A16] The semiconductor device (1A, 1B, 1C) according to any one of A1 to A15, further comprising: a semiconductor region (11) of a first conductivity type (n-type) formed in a surface layer portion of the main surface (3); a body region (12) of a second conductivity type (p-type) formed in a surface layer portion of the semiconductor region (11); an impurity region (14, 15) of the first conductivity type (n-type) formed in a surface layer portion of the body region (12); and a channel (17, 18) formed in a region between the semiconductor region (11) and the impurity region (14, 15) in the surface layer portion of the body region (12); and wherein the gate insulating film (21) covers the channel (17, 18), the gate electrode (22) faces the channel (17, 18) with the gate insulating film (21) interposed therebetween, the opening (65) exposes the impurity region (14, 15), and the main electrode (70) is electrically connected to the impurity region (14, 15) in the opening (65).

[A17] The semiconductor device (1A, 1B, 1C) according to A16, further comprising: a contact region (16) of the second conductivity type (p-type) formed in a region different from the impurity region (14, 15) in the surface layer portion of the body region (12); and wherein the opening (65) exposes the impurity region (14, 15) and the contact region (16), and the main electrode (70) is electrically connected to the impurity region (14, 15) and the contact region (16) in the opening (65).

[A18]A method for manufacturing a semiconductor device (1A, 1B, 1C), comprising: a step of forming a lower insulating film (113) on a main surface (101) of a wafer (100); a step of forming gate electrodes (22) on the lower insulating film (113); a step of forming, on the lower insulating film (113), a base insulating film (120) covering the gate electrodes (22); a step of forming side wall insulating films (24, 25) respectively covering a side wall (27, 28) of the gate electrodes (22) by selectively removing the base insulating film (120) such that a covering portion of the base insulating film (120) with respect to the side wall (27, 28) of the gate electrodes (22) remains; a step of forming an opening (65) exposing the main surface (101) by removing an exposed portion in the lower insulating film (113) demarcated by the side wall insulating films (24, 25) such that a hidden portion of the lower insulating film (113) hidden by the gate electrodes (22) remains as gate insulating films (21); and a step of forming a main electrode (70) on the main surface (101) such as to be mechanically connected to the side wall insulating films (24, 25) in the opening (65) and be electrically connected to the main surface (101) in the opening (65).

[A19] The method for manufacturing a semiconductor device (1A, 1B, 1C) according to A18, wherein the wafer (100) contains SiC.

[A20] The method for manufacturing a semiconductor device (1A, 1B, 1C) according to A18 or A19, further comprising: a step of forming a base gate electrode (114) on the lower insulating film (113); a step of forming an upper insulating film (116) on the base gate electrode (114); and a step of forming planar insulating films (23) on the base gate electrode (114) by selectively removing the upper insulating film (116); and wherein the forming step of the gate electrode (22) includes a step of forming, on the lower insulating film (113), the gate electrodes (22) respectively covered with the planar insulating films (23) by removing an exposed portion of the base gate electrode (114) demarcated by the planar insulating films (23), the forming step of the base insulating film (120) includes a step of forming the base insulating film (120) that collectively covers the gate electrodes (22) and the planar insulating films (23), and the forming step of the side wall insulating film (24, 25) includes a step of forming the side wall insulating films (24, 25) respectively covering the side wall (27, 28) of the gate electrodes (22) and a side wall (30, 31) of the planar insulating films (23) by selectively removing the base insulating film (120) such that a covering portion of the base insulating film (120) with respect to the side wall (27, 28) of the gate electrodes (22) and the side wall (30, 31) of the planar insulating films (23) remains.

While specific embodiments have been described in detail above, these are merely specific examples used to clarify the technical contents. The various technical ideas extracted from this Description can be combined as appropriate with each other without being limited by the order of description, the order of configuration examples, the order of modification examples, etc., in this Description.

What is claimed is:

1. A semiconductor device comprising:
a chip having a main surface;
gate structures of a planar type each including a gate insulating film covering the main surface, a gate electrode arranged on the gate insulating film, and a side wall insulating film covering a side wall of the gate electrode, the gate structures being arranged at intervals on the main surface;
an opening that is demarcated by the side wall insulating films in a region between the gate structures; and
a main electrode that is mechanically connected to the side wall insulating films in the opening and is electrically connected to the main surface.

2. The semiconductor device according to claim 1,
wherein the chip contains SiC.

3. The semiconductor device according to claim 1,
wherein the side wall insulating film covers the side wall of the gate electrode in a film shape and has a film surface extending along the side wall of the gate electrode in cross-sectional view.

4. The semiconductor device according to claim 1,
wherein the side wall insulating film covers the side wall of the gate electrode on the gate insulating film.

5. The semiconductor device according to claim 1,
wherein the side wall insulating film has a thickness less than a thickness of the gate electrode.

6. The semiconductor device according to claim 1,
wherein the side wall insulating film has a single layer structure constituted of a single insulating film.

7. The semiconductor device according to claim 6,
wherein the single insulating film is constituted of an undoped oxide film.

8. The semiconductor device according to claim 1,
wherein the gate structures respectively include a planar insulating film arranged on the gate electrode, and the side wall insulating film covering the side wall of the gate electrode and a side wall of the planar insulating film, and
the main electrode has a portion facing the gate electrode in a lamination direction with the planar insulating film interposed therebetween and is electrically disconnected from the gate electrode by the planar insulating film.

9. The semiconductor device according to claim 8,
wherein the planar insulating film has a laminated structure including insulating films.

10. The semiconductor device according to claim 9,
wherein the side wall insulating film covers the insulating films on the side wall of the planar insulating film.

11. The semiconductor device according to claim 9,
wherein the insulating films include an undoped first oxide film covering the gate electrode, and a second oxide film that contains phosphorus and covers the first oxide film.

12. The semiconductor device according to claim 1,
wherein the opening has a width of not less than a thickness of the side wall insulating film and not more than a width of the gate electrode.

13. The semiconductor device according to claim 12,
wherein the thickness of the side wall insulating film is not less than 0.05 μm and not more than 0.5 μm, and
the width of the opening is not less than 0.2 μm and not more than 0.6 μm.

14. The semiconductor device according to claim 1,
wherein the main electrode has a laminated structure including an embedded electrode electrically connected to the main surface in the opening, and an upper electrode that is electrically connected to the main surface via the embedded electrode on the embedded electrode.

15. The semiconductor device according to claim 1, further comprising:
a silicide portion that electrically connects the main electrode to the chip in the opening.

16. The semiconductor device according to claim 1, further comprising:
a semiconductor region of a first conductivity type formed in a surface layer portion of the main surface;
a body region of a second conductivity type formed in a surface layer portion of the semiconductor region;
an impurity region of the first conductivity type formed in a surface layer portion of the body region; and
a channel formed in a region between the semiconductor region and the impurity region in the surface layer portion of the body region; and
wherein the gate insulating film covers the channel,
the gate electrode faces the channel with the gate insulating film interposed therebetween,
the opening is formed along the impurity region, and
the main electrode is electrically connected to the impurity region in the opening.

17. The semiconductor device according to claim 16, further comprising:
a contact region of the second conductivity type formed in a region different from the impurity region in the surface layer portion of the body region; and
wherein the opening is formed along the impurity region and the contact region, and
the main electrode is electrically connected to the impurity region and the contact region in the opening.

18. A method for manufacturing a semiconductor device, comprising:
a step of forming a lower insulating film on a main surface of a wafer;
a step of forming gate electrodes on the lower insulating film;
a step of forming, on the lower insulating film, a base insulating film covering the gate electrodes;
a step of forming side wall insulating films respectively covering a side wall of the gate electrodes by selectively removing the base insulating film such that a covering portion of the base insulating film with respect to the side wall of the gate electrodes remains;
a step of forming an opening exposing the main surface by removing an exposed portion in the lower insulating film demarcated by the side wall insulating films such that a hidden portion of the lower insulating film hidden by the gate electrodes remains as gate insulating films; and
a step of forming a main electrode on the main surface such as to be mechanically connected to the side wall insulating films in the opening and be electrically connected to the main surface.

19. The method for manufacturing a semiconductor device according to claim 18,
wherein the wafer contains SiC.

20. The method for manufacturing a semiconductor device according to claim 18, further comprising:
a step of forming a base gate electrode on the lower insulating film;
a step of forming an upper insulating film on the base gate electrode; and
a step of forming planar insulating films on the base gate electrode by selectively removing the upper insulating film; and
wherein the forming step of the gate electrode includes a step of forming, on the lower insulating film, the gate electrodes respectively covered with the planar insulating films by removing an exposed portion of the base gate electrode demarcated by the planar insulating films,
the forming step of the base insulating film includes a step of forming the base insulating film that collectively covers the gate electrodes and the planar insulating films, and
the forming step of the side wall insulating film includes a step of forming the side wall insulating films respectively covering the side wall of the gate electrodes and a side wall of the planar insulating films by selectively removing the base insulating film such that a covering portion of the base insulating film with respect to the side wall of the gate electrodes and the side wall of the planar insulating films remains.
